(19) United States
(12) Patent Application Publication
(10) Pub. No.: US 2023/0403926 A1
(43) Pub. Date: Dec. 14, 2023

(54) ORGANIC LIGHT-EMITTING DEVICE WITH IMPROVED LIFESPAN CHARACTERISTICS

(71) Applicant: UNIVERSITY-INDUSTRY COOPERATION GROUP OF KYUNG HEE UNIVERSITY, Yongin-si, Gyeonggi-do (KR)

(72) Inventors: Jang Hyuk KWON, Seongnam-si (KR); Ju Young LEE, Suwon-si (KR); Hyuna LEE, Seoul (KR); Dae AHN, Daejeon (KR)

(73) Assignee: UNIVERSITY-INDUSTRY COOPERATION GROUP OF KYUNG HEE UNIVERSITY, Yongsin-si, Gyeonggi-do (KR)

(21) Appl. No.: 18/035,874

(22) PCT Filed: Mar. 19, 2021
(86) PCT No.: PCT/KR2021/003456

§ 371 Date: Jun. 22, 2023

(30) Foreign Application Priority Data
Nov. 11, 2020 (KR) 10-2020-0150022

(51) Int. Cl. H10K 85/30; C07F 5/02; C09K 11/06

(52) U.S. Cl. CPC H10K 85/322; C07F 5/027; C09K 11/06; H10K 50/12

(57) ABSTRACT

The present specification relates to: a delayed fluorescence organic light-emitting device that comprises a light-emitting layer comprising a first compound which has a LUMO energy level of EL₁ and which is a delayed fluorescence dopant, and a second compound which has a LUMO energy level of EL₂ and which is a host, and that satisfies |E_{L1}|−|EL₂|≤0.2 eV, the binding energy of the first compound in an anion state being lower than the binding energy of the second compound in an anion state; and a delayed fluorescence sensitized hyperfluorescence device further comprising a third compound, which is a delayed fluorescence or fluorescent compound. A host, which has excellent electron transport capacity to have a LUMO energy level similar to that of a delayed fluorescence dopant, is used to delay the deterioration of a delayed fluorescent compound, and thus the lifespan of a delayed fluorescence organic light-emitting device or a hyperfluorescence organic light-emitting device can be remarkably improved.

### TECHNICAL FIELD

The present specification relates to an organic light-emitting device, and more specifically, to an organic light-emitting device including a thermally activated delayed fluorescence (TADF) dopant or a hyperfluorescence dopant, which is vulnerable to electrons, and having excellent lifespan characteristics.

### BACKGROUND ART

Organic luminescence refers to a phenomenon in which electrical energy is converted into light energy using organic materials. An organic light-emitting device (OLED) is manufactured by interposing an organic material between an anode and a cathode using such organic luminescence, and has a characteristic of emitting light when electrical energy is applied. An organic light-emitting device includes multiple organic layers to improve efficiency and stability, and generally includes a hole injection layer (HIL), a hole transport layer (HTL), a light-emitting layer, and an electron transport layer (ETL) and an electron injection layer (EIL).

Materials used in organic layers may be classified into light-emitting materials and charge transfer materials according to their functions, and the light-emitting materials may be classified into fluorescent materials using a fluorescence phenomenon derived from a singlet excited state of electrons and phosphorescent materials using a phosphorescence phenomenon derived from a triplet excited state of electrons according to light-emitting mechanism. In addition, the light-emitting material may be divided into blue, green, and red light-emitting materials according to the light-emitting color, and phosphorescent materials of all colors except for blue have been developed and used in the industry. However, in the case of blue materials, only fluorescent materials are used due to limitations in lifetime and color properties, and a blue phosphorescent material using a triplet using a heavy metal such as iridium or platinum, and a delayed fluorescence material using a triplet only as pure organic materials by making the energy difference between a singlet and triplet small are being developed. When a phosphorescent material using heavy metals is used, although high efficiency can be achieved, it is disadvantageous in terms of cost due to heavy metals for implementing phosphorescence, and mining of heavy metals may cause various social problems.

Therefore, interest in delayed fluorescence materials is increasing, and research is underway on various color gamuts such as green, yellow, orange, and red, not limited to blue. Unlike existing fluorescence in which 75% of the triplet energy is lost using only singlet energy, in delayed fluorescence, molecules are designed to reduce the singlet-triplet energy gap, inducing reverse intersystem crossing (RISC) converting a triplet to a singlet using only thermal energy at room temperature, so that both the singlet and the triplet can be utilized. Therefore, since the triplet can be utilized without a heavy metal substance like a phosphorescent material, the efficiency is higher than that of the fluorescent material, and because fluorescence light emission is realized via the triplet, it is called delayed fluorescence.

The characteristics of the organic light-emitting device may depend on a dopant material of a light-emitting layer, and in a delayed fluorescent dopant, overlap between the highest occupied molecular orbital (HOMO) and the lowest unoccupied molecular orbital (LUMO) needs to be small in order to minimize the energy gap between the singlet and triplet. To this end, a donor-acceptor structure is mainly used, and a dopant is formed by combining nitrogen of the donor and carbon of the acceptor. At this time, it is known that a structure having a large angle between the donor and the receiver is advantageous. However, such an angle close to a vertical angle may weaken bonding strength, and is particularly vulnerable to electrons, thereby reducing the lifetime of the device.

### Technical Problem

The present specification is intended to solve the problems of the related art described above, and an aspect of the present specification is to provide an organic light-emitting device that controls the LUMO energy level of a host and a delayed fluorescent dopant constituting a light-emitting layer so that electrons flow toward the host, thereby improving the lifetime characteristics of a delayed fluorescent dopant and a hyperfluorescence dopant which are vulnerable to electrons.

### Technical Solution

An aspect of the present specification provides an organic light-emitting device having a light-emitting layer which includes a first compound having a lowest unoccupied molecular orbital (LUMO) energy level of EL₁ and being a delayed fluorescent dopant, and a second compound having a LUMO energy level of EL₂ and being a host, and which satisfies |EL₁|−|EL₂|≤0.2 eV, where the binding energy of the first compound in an anion state is lower than the binding energy of the second compound in an anion state. In an embodiment, the first compound may be represented by a structure of the following Formula 1:

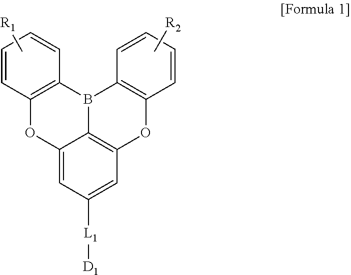

in Formula 1, D₁ is represented by one of the following Formulas 2 to 4,

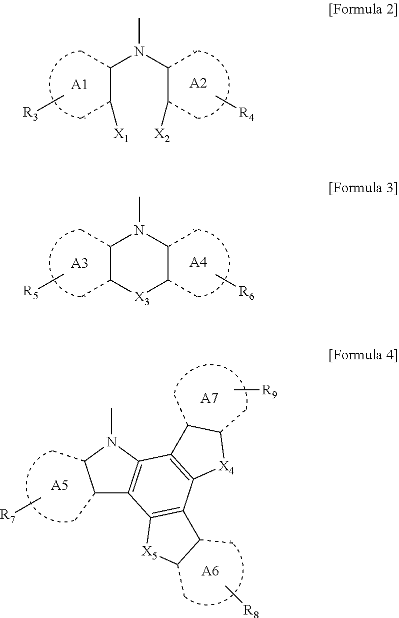

where A₁ to A₇ each independently represent a ring structure selected from a substituted or unsubstituted C₅ to C₆₀ carbocyclic group or a substituted or unsubstituted C₂ to C₆₀ heterocyclic group; L₁ is a single bond or C₆ to C₆₀ arylene; X₁ and X₂ each represent hydrogen or are mutually bonded to form a ring, X₃ is O, N—R₂₆, S or C—(R₂₇)₂; X₄ and X₅ each independently represent O, N—R₂₈, S or C—(R₂₉)₂; R₁ to R₉ are each independently selected from hydrogen, deuterium, —F, —Cl, —Br, —I, a hydroxyl group, a cyano group, a nitro group, an amino group, an amidino group, a hydrazino group, a hydrazono group, a substituted or unsubstituted C₁ to C₆₀ alkyl group, a substituted or unsubstituted C₂ to C₆₀ alkenyl group, a substituted or unsubstituted C₂ to C₆₀ alkynyl group, a substituted or unsubstituted C₁ to C₆₀ alkoxy group, a substituted or unsubstituted C₃ to C₁₀ cycloalkyl group, a substituted or unsubstituted C₂ to C₁₀ heterocycloalkyl group, a substituted or unsubstituted C₃ to C₁₀ cycloalkenyl group, a substituted or unsubstituted C₂ to C₁₀ heterocycloalkenyl group, a substituted or unsubstituted C₆ to C₆₀ aryl group, a substituted or unsubstituted C₆ to C₆₀ aryloxy group, a substituted or unsubstituted C₆ to C₆₀ arylthio group, a substituted or unsubstituted C₁ to C₆₀ heteroaryl group, a substituted or unsubstituted C₁ to C₆₀ heteroaryloxy group, a substituted or unsubstituted monovalent non-aromatic condensed polycyclic group and a substituted or unsubstituted monovalent non-aromatic heterocondensed polycyclic group, R₂₆ to R₂₉ are each independently selected from hydrogen, deuterium, a C₁ to C₆₀ alkyl group, a C₃ to C₁₀ cycloalkyl group, a C₆ to C₆₀ aryl group, or a C₁ to C₆₀ heteroaryl group.

In an embodiment, the second compound may be represented by a structure selected from the following Formulas 5 and 6:

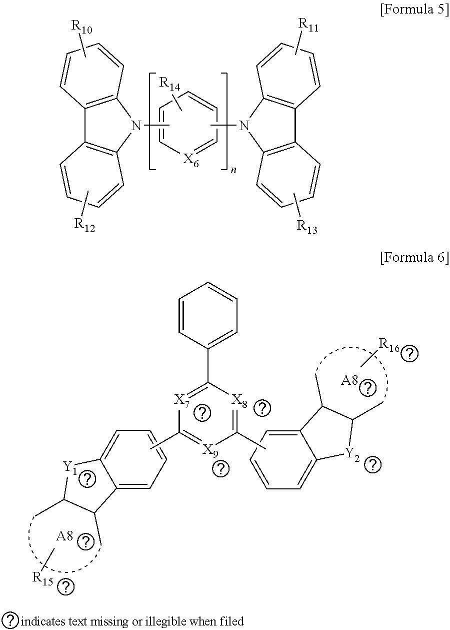

[symbol]

where A₈ to A₉ each independently represent a ring structure selected from a substituted or unsubstituted C₅ to C₆₀ carbocyclic group or a C₂ to C₆₀ heterocyclic group; X₆ is N or C—H; X₇ to X₉ are each independently selected from N or C—H and at least one of X₇ to X₉ is N, Y₁ to Y₂ are each independently selected from N—R₃₀, O or S; R₁₀ to R₁₄ are each independently selected from hydrogen, deuterium, a silyl group, a cyano group, a C₁ to C₆₀ alkyl group, a C₃ to C₁₀ cycloalkyl group, a C₆ to C₆₀ aryl group, a C₁ to C₆₀ heteroaryl group, a C₆ to C₃₀ diarylamino group, a C₂ to C₄₀ diheteroarylamino group, and a C₁₀ to C₄₀ arylheteroarylamino group; R₁₅ to R₁₆ are each independently selected from hydrogen, deuterium, a silyl group, a cyano group, a C₁ to C₆₀ alkyl group, a C₃ to C₁₀ cycloalkyl group, a C₆ to C₆₀ aryl group, a C₁ to C₆₀ heteroaryl group, a C₆ to C₃₀ diarylamino group, a C₂ to C₄₀ diheteroarylamino group, and a C₁₀ to C₄₀ arylheteroarylamino group; R₃₀ is selected from hydrogen, deuterium, a C₁ to C₆₀ alkyl group, a C₃ to C₁₀ cycloalkyl group, a C₆ to C₆₀ aryl group, or a C₁ to C₆₀ heteroaryl group; n is 1 or 2; and a compound of Formula 5 or 6 includes at least one nitrogen-containing benzene or benzene to which a cyano group is bonded.

In an embodiment, the light-emitting layer may be represented by a structure selected from the following Formulas 7 and 8 and further include a third compound having fluorescence or delayed fluorescence characteristics, and the organic light-emitting device may be a delayed fluorescence photosensitive hyperfluorescence device:

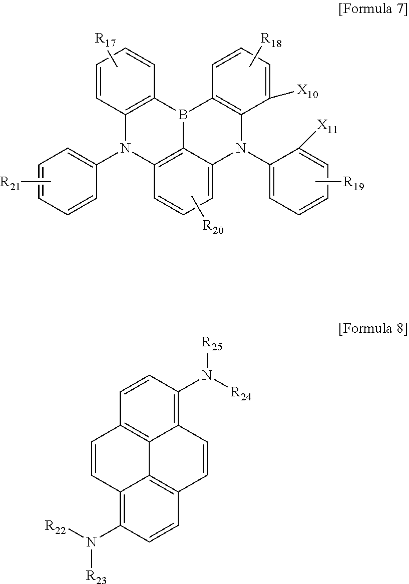

where X₁₀ to X₁₁ each independently represent hydrogen or are mutually bonded to form a ring; R₁₇ to R₂₁ are each independently selected from hydrogen, deuterium, —F, —Cl, —Br, —I, a hydroxyl group, a cyano group, a nitro group, an amino group, an amidino group, a hydrazino group, a hydrazono group, a substituted group or unsubstituted C₁ to C₆₀ alkyl group, a substituted or unsubstituted C₂ to C₆₀ alkenyl group, a substituted or unsubstituted C₂ to C₆₀ alkynyl group, a substituted or unsubstituted C₁ to C₆₀ alkoxy group, a substituted or unsubstituted C₃ to C₁₀ cycloalkyl group, a substituted or unsubstituted C₂ to C₁₀ heterocycloalkyl group, a substituted or unsubstituted C₃ to C₁₀ cycloalkenyl group, a substituted or unsubstituted C₂ to C₁₀ heterocycloalkenyl group, a substituted or unsubstituted C₆ to C₆₀ aryl group, a substituted or unsubstituted C₆ to C₆₀ aryloxy group, a substituted or unsubstituted C₆ to C₆₀ arylthio group, a substituted or unsubstituted C₁ to C₆₀ heteroaryl group, a substituted or unsubstituted C₁ to C₆₀ heteroaryloxy group, a substituted or unsubstituted monovalent non-aromatic condensed polycyclic group, and a substituted or unsubstituted monovalent non-aromatic heterocondensed polycyclic group, R₂₂ to R₂₅ are each independently selected from hydrogen, deuterium, —F, —Cl, —Br, —I, a hydroxyl group, a cyano group, a nitro group, an amino group, an amidino group, a hydrazino group, a hydrazono group, a substituted or unsubstituted C₁ to C₆₀ alkyl group, a substituted or unsubstituted C₂ to C₆₀ alkenyl group, a substituted or unsubstituted C₂ to C₆₀ alkynyl group, a substituted or unsubstituted C₁ to C₆₀ alkoxy group, a substituted or unsubstituted C₃ to C₁₀ cycloalkyl group, a substituted or unsubstituted C₂ to C₁₀ heterocycloalkyl group, a substituted or unsubstituted C₃ to C₁₀ cycloalkenyl group, a substituted or unsubstituted C₂ to C₁₀ heterocycloalkenyl group, a substituted or unsubstituted C₆ to C₆₀ aryl group, a substituted or unsubstituted C₆ to C₆₀ aryloxy group, a substituted or unsubstituted C₆ to C₆₀ arylthio group, a substituted or unsubstituted C₁ to C₆₀ heteroaryl group, a substituted or unsubstituted C₁ to C₆₀ heteroaryloxy group, a substituted or unsubstituted monovalent non-aromatic condensed polycyclic group and a substituted or unsubstituted monovalent non-aromatic heterocondensed polycyclic group.

In an embodiment, the first compound may have a structure of one of the following Compounds T-1 to T-82:

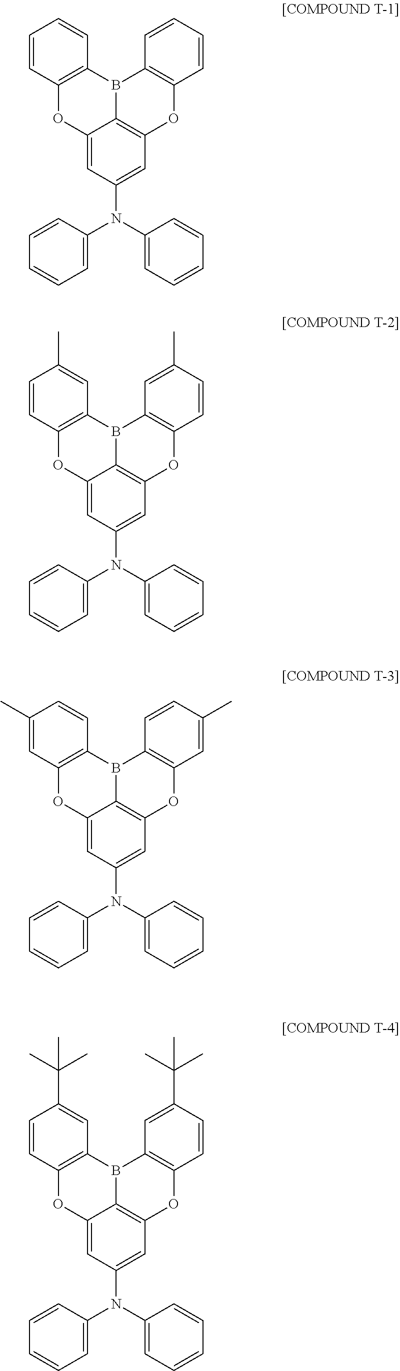

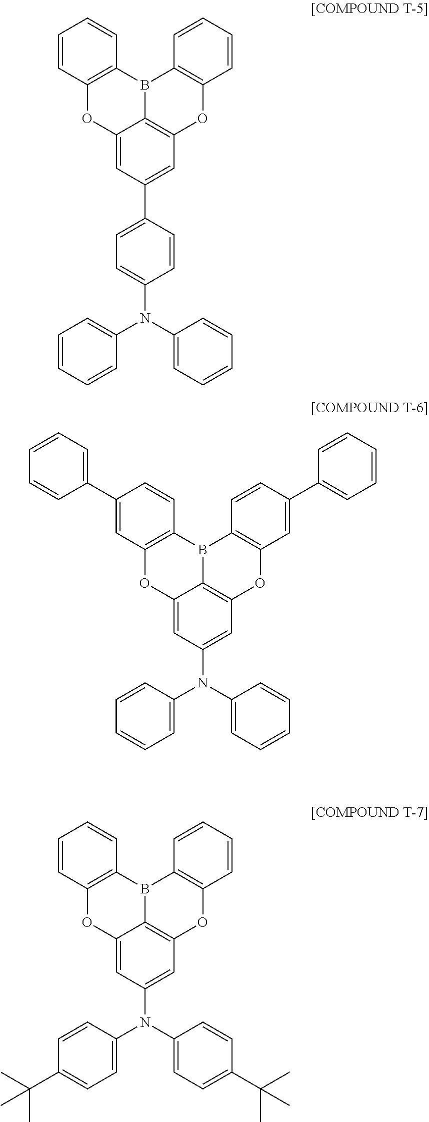 [SMILES: c1ccc(N(c2ccccc2)c2ccc(-c3cc4c5c(c3)Oc3ccccc3B5c3ccccc3O4)cc2)cc1 ; c1ccc(-c2ccc3c(c2)Oc2cc(N(c4ccccc4)c4ccccc4)cc4c2B3c2ccc(-c3ccccc3)cc2O4)cc1 ; CC(C)(C)c1ccc(N(c2ccc(C(C)(C)C)cc2)c2cc3c4c(c2)Oc2ccccc2B4c2ccccc2O3)cc1]

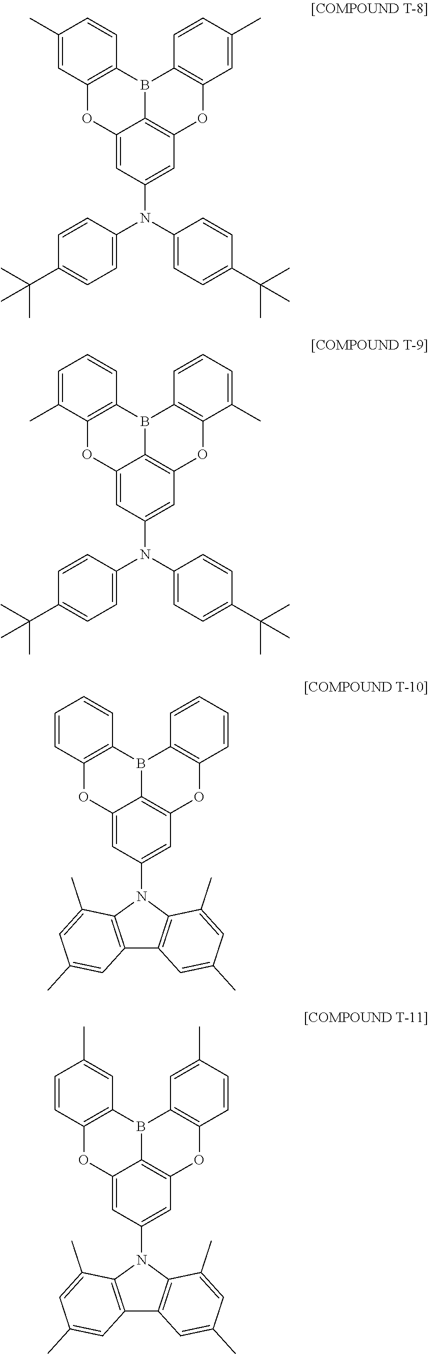

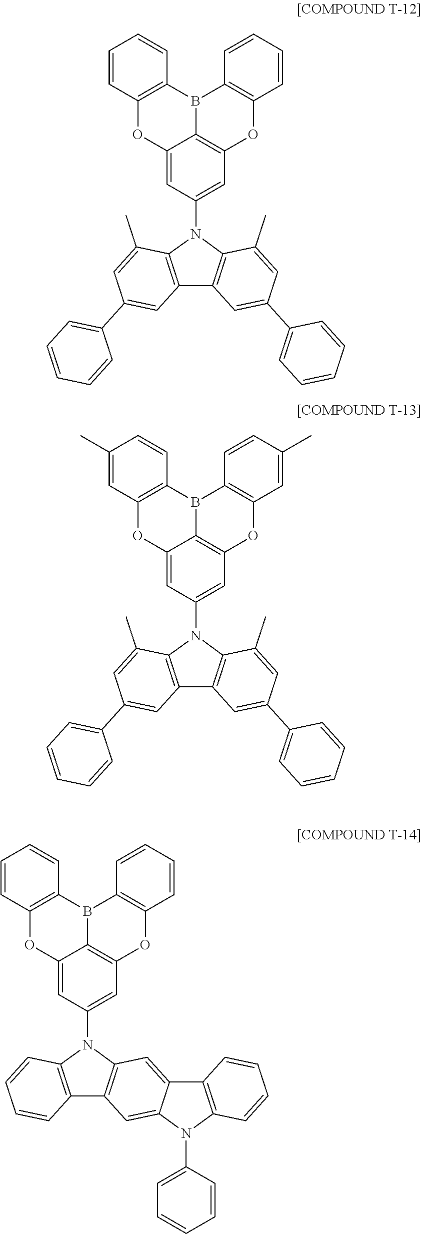 [SMILES: Cc1cc(-c2ccccc2)cc2c3cc(-c4ccccc4)cc(C)c3n(-c3cc4c5c(c3)Oc3ccccc3B5c3ccccc3O4)c12 ; Cc1ccc2c(c1)Oc1cc(-n3c4c(C)cc(-c5ccccc5)cc4c4cc(-c5ccccc5)cc(C)c43)cc3c1B2c1ccc(C)cc1O3 ; c1ccc(-n2c3ccccc3c3cc4c(cc32)c2ccccc2n4-c2cc3c4c(c2)Oc2ccccc2B4c2ccccc2O3)cc1]

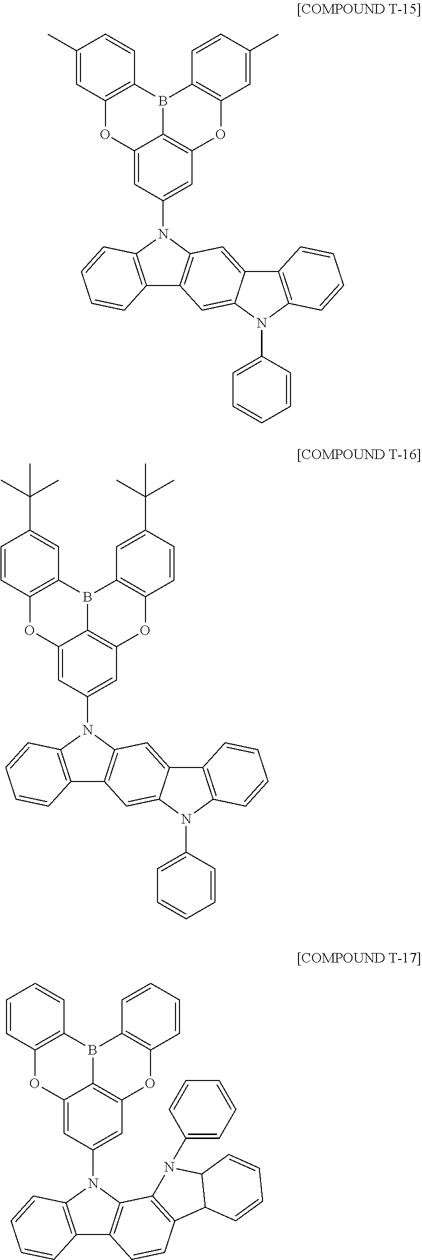 [SMILES: Cc1ccc2c(c1)Oc1cc(-n3c4ccccc4c4cc5c(cc43)c3ccccc3n5-c3ccccc3)cc3c1B2c1ccc(C)cc1O3 ; CC(C)(C)c1ccc2c(c1)B1c3cc(C(C)(C)C)ccc3Oc3cc(-n4c5ccccc5c5cc6c(cc54)c4ccccc4n6-c4ccccc4)cc(c31)O2 ; C1=CC2c3ccc4c5ccccc5n(-c5cc6c7c(c5)Oc5ccccc5B7c5ccccc5O6)c4c3N(c3ccccc3)C2C=C1]

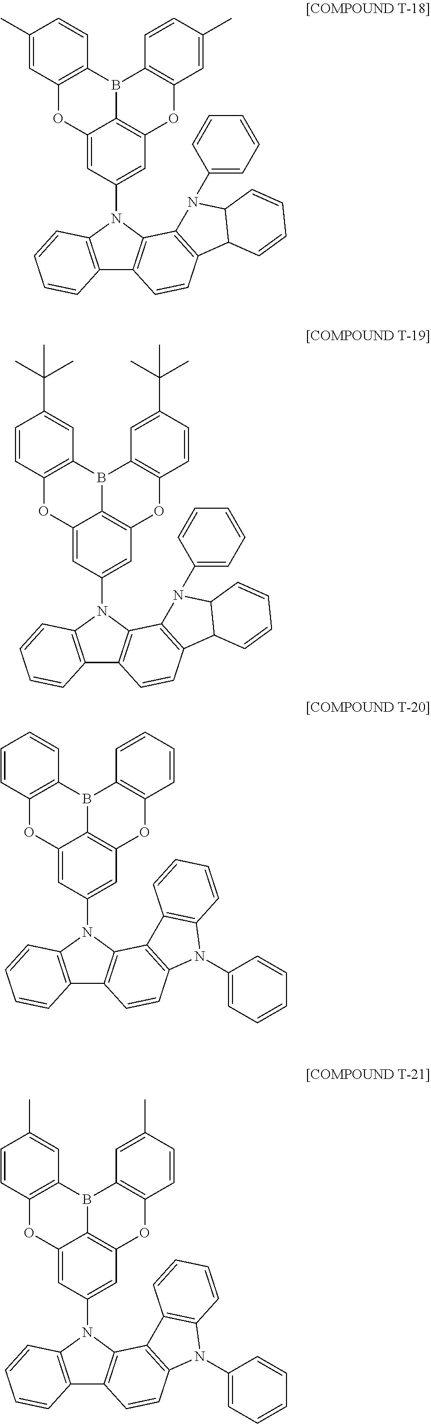

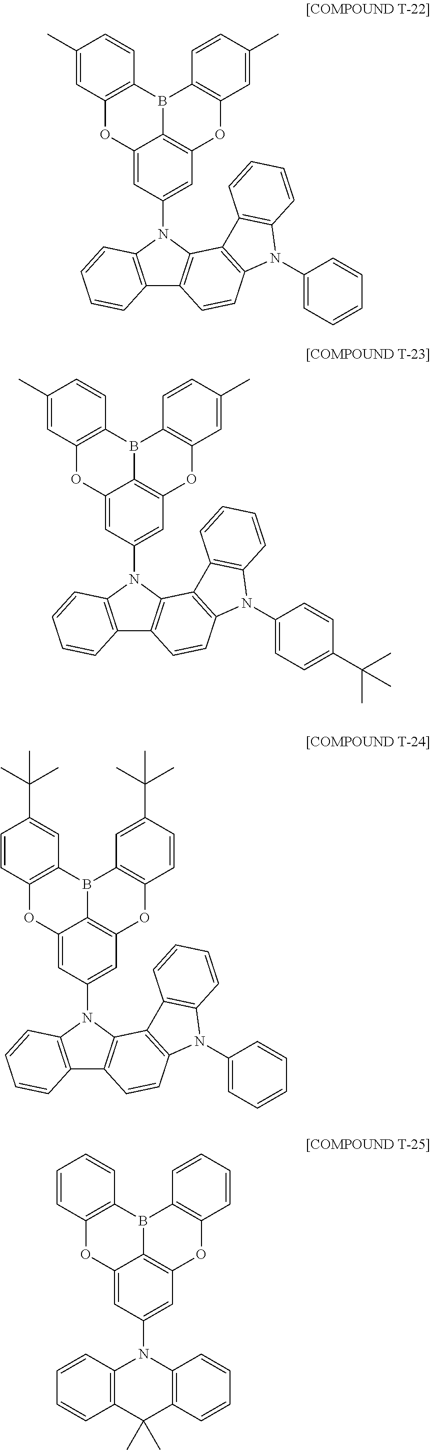 [SMILES: Cc1ccc2c(c1)Oc1cc(-n3c4ccccc4c4ccc5c(c6ccccc6n5-c5ccccc5)c43)cc3c1B2c1ccc(C)cc1O3 ; Cc1ccc2c(c1)Oc1cc(-n3c4ccccc4c4ccc5c(c6ccccc6n5-c5ccc(C(C)(C)C)cc5)c43)cc3c1B2c1ccc(C)cc1O3 ; CC(C)(C)c1ccc2c(c1)B1c3cc(C(C)(C)C)ccc3Oc3cc(-n4c5ccccc5c5ccc6c(c7ccccc7n6-c6ccccc6)c54)cc(c31)O2 ; CC1(C)c2ccccc2N(c2cc3c4c(c2)Oc2ccccc2B4c2ccccc2O3)c2ccccc21]

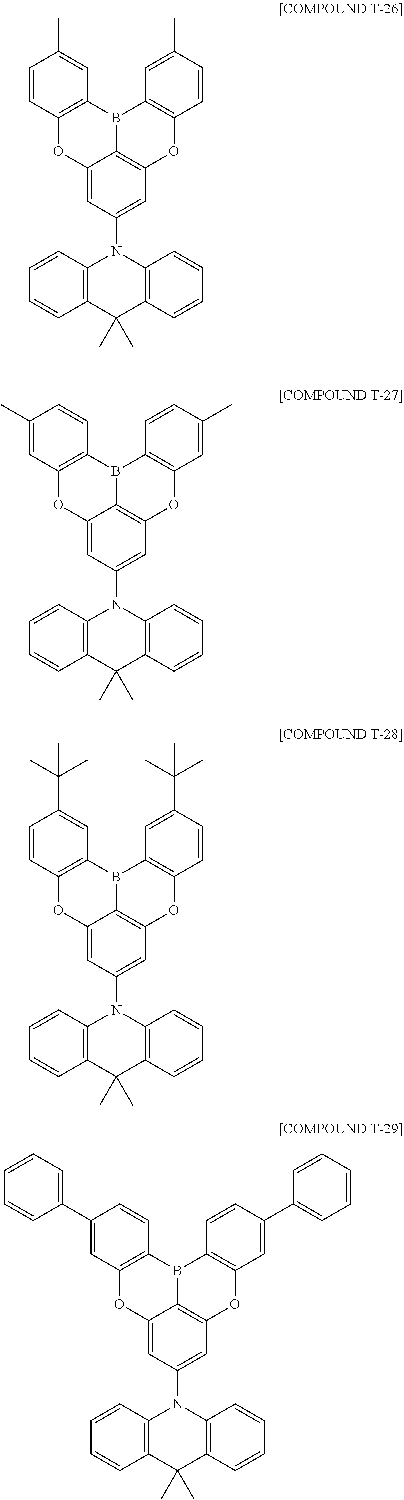

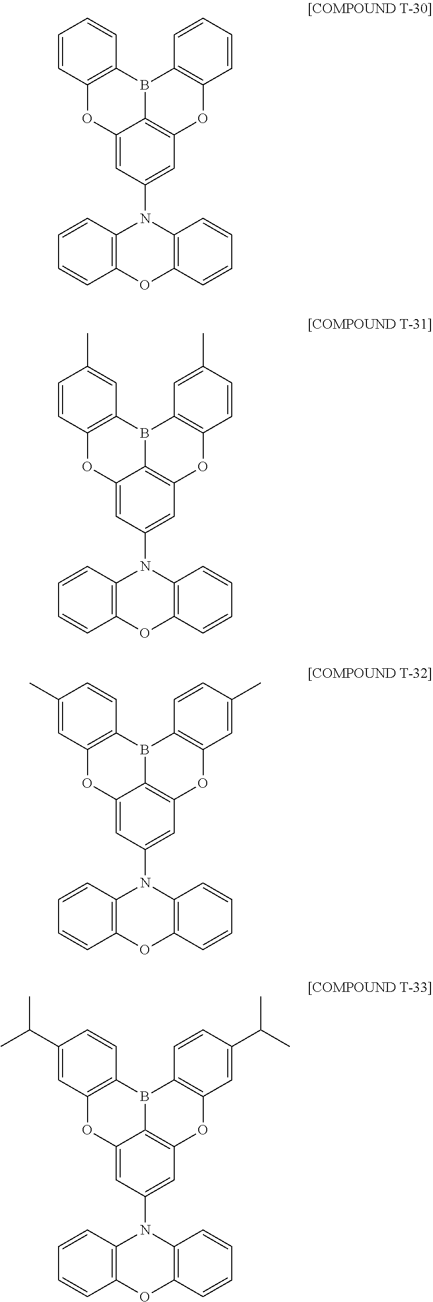

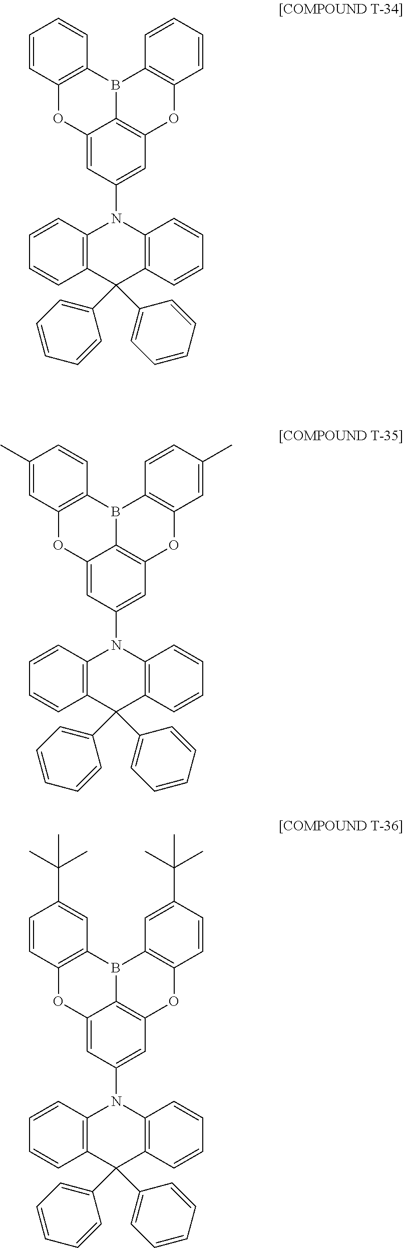

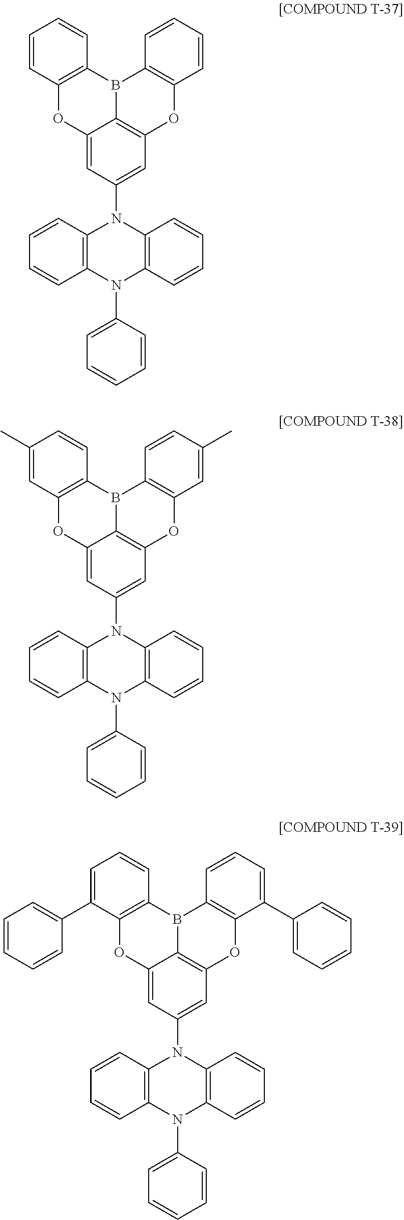

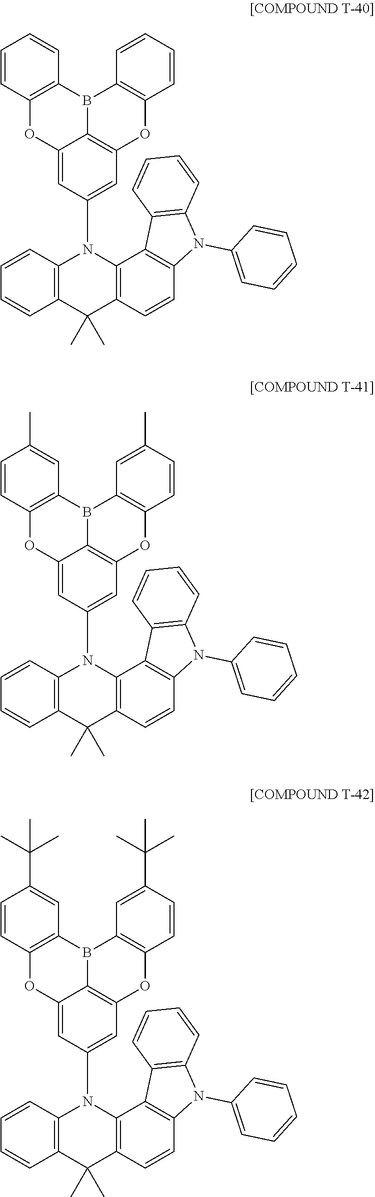 [SMILES: CC1(C)c2ccccc2N(c2cc3c4c(c2)Oc2ccccc2B4c2ccccc2O3)c2c1ccc1c2c2ccccc2n1-c1ccccc1 ; Cc1ccc2c(c1)B1c3cc(C)ccc3Oc3cc(N4c5ccccc5C(C)(C)c5ccc6c(c54)c4ccccc4n6-c4ccccc4)cc(c31)O2 ; CC(C)(C)c1ccc2c(c1)B1c3cc(C(C)(C)C)ccc3Oc3cc(N4c5ccccc5C(C)(C)c5ccc6c(c54)c4ccccc4n6-c4ccccc4)cc(c31)O2]

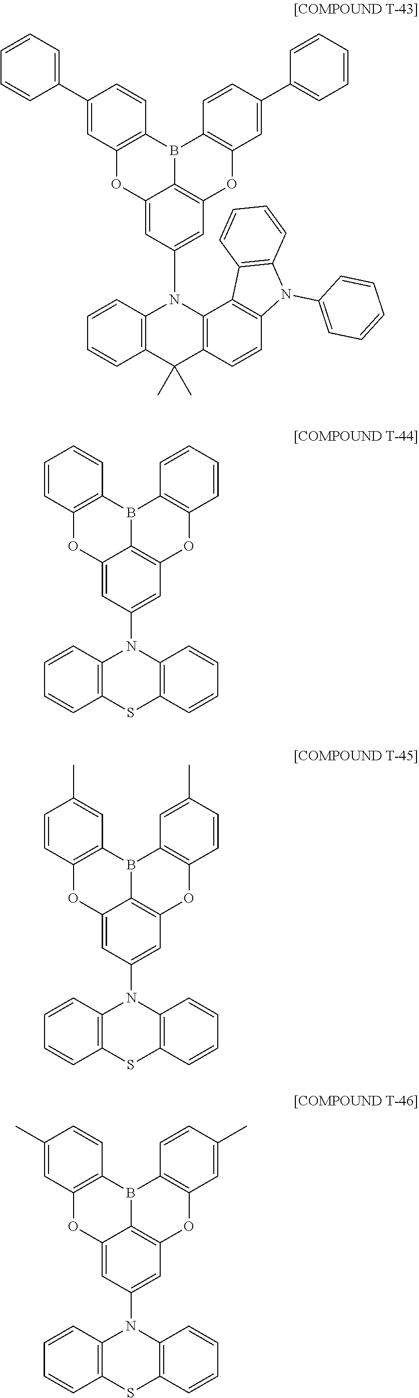

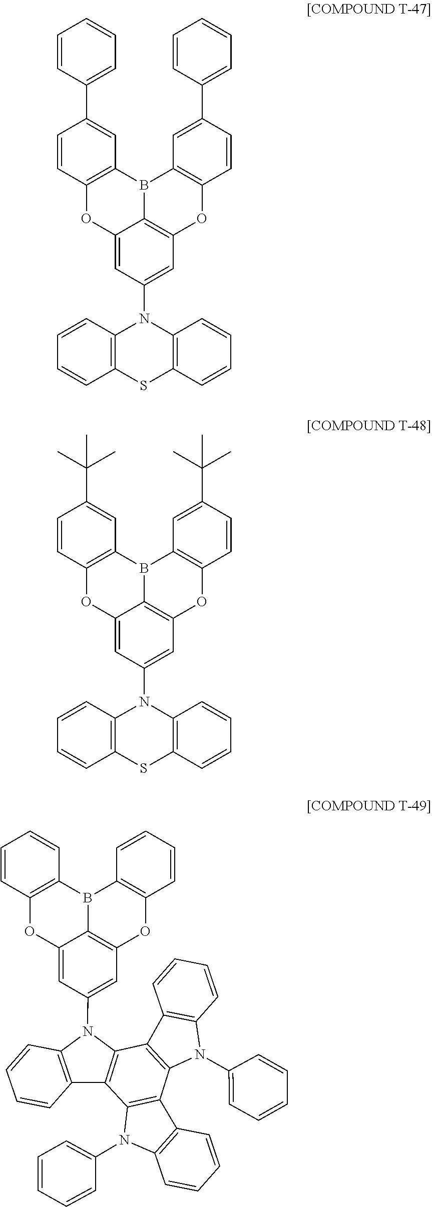 [SMILES: c1ccc(-c2ccc3c(c2)B2c4cc(-c5ccccc5)ccc4Oc4cc(N5c6ccccc6Sc6ccccc65)cc(c42)O3)cc1 ; CC(C)(C)c1ccc2c(c1)B1c3cc(C(C)(C)C)ccc3Oc3cc(N4c5ccccc5Sc5ccccc54)cc(c31)O2 ; c1ccc(-n2c3ccccc3c3c2c2c4ccccc4n(-c4cc5c6c(c4)Oc4ccccc4B6c4ccccc4O5)c2c2c4ccccc4n(-c4ccccc4)c32)cc1]

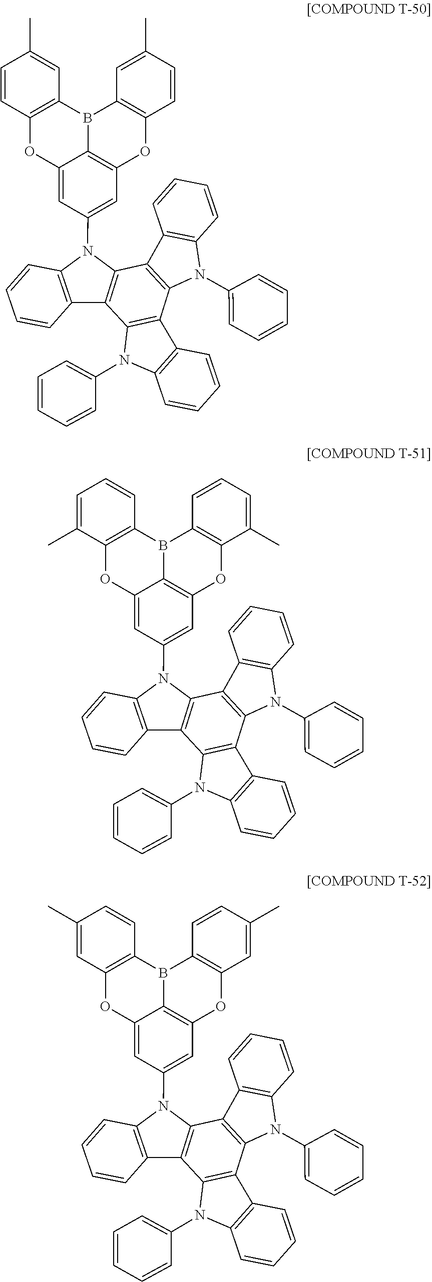 [SMILES: Cc1ccc2c(c1)B1c3cc(C)ccc3Oc3cc(-n4c5ccccc5c5c6c(c7ccccc7n6-c6ccccc6)c6c(c7ccccc7n6-c6ccccc6)c54)cc(c31)O2 ; Cc1cccc2c1Oc1cc(-n3c4ccccc4c4c5c(c6ccccc6n5-c5ccccc5)c5c(c6ccccc6n5-c5ccccc5)c43)cc3c1B2c1cccc(C)c1O3 ; Cc1ccc2c(c1)Oc1cc(-n3c4ccccc4c4c5c(c6ccccc6n5-c5ccccc5)c5c(c6ccccc6n5-c5ccccc5)c43)cc3c1B2c1ccc(C)cc1O3]

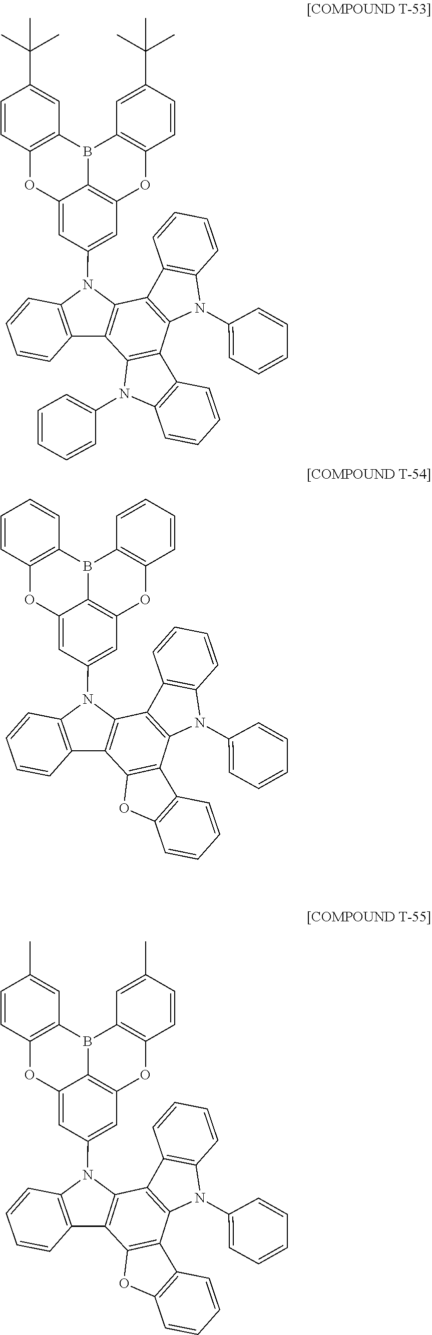 [SMILES: CC(C)(C)c1ccc2c(c1)B1c3cc(C(C)(C)C)ccc3Oc3cc(-n4c5ccccc5c5c6c(c7ccccc7n6-c6ccccc6)c6c(c7ccccc7n6-c6ccccc6)c54)cc(c31)O2 ; c1ccc(-n2c3ccccc3c3c4c(c5ccccc5n4-c4cc5c6c(c4)Oc4ccccc4B6c4ccccc4O5)c4oc5ccccc5c4c32)cc1 ; Cc1ccc2c(c1)B1c3cc(C)ccc3Oc3cc(-n4c5ccccc5c5c6oc7ccccc7c6c6c(c7ccccc7n6-c6ccccc6)c54)cc(c31)O2]

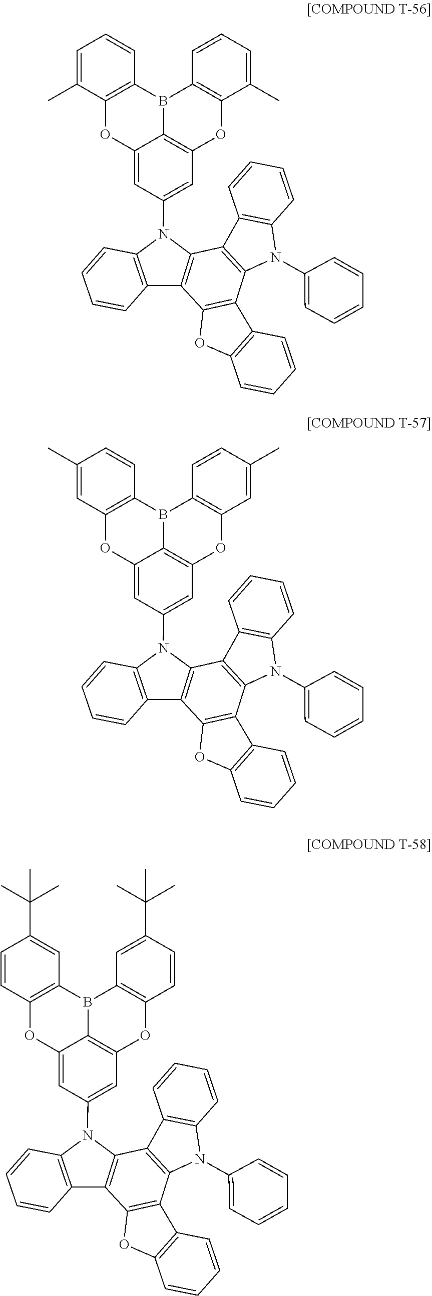 [SMILES: Cc1cccc2c1Oc1cc(-n3c4ccccc4c4c5oc6ccccc6c5c5c(c6ccccc6n5-c5ccccc5)c43)cc3c1B2c1cccc(C)c1O3 ; Cc1ccc2c(c1)Oc1cc(-n3c4ccccc4c4c5oc6ccccc6c5c5c(c6ccccc6n5-c5ccccc5)c43)cc3c1B2c1ccc(C)cc1O3 ; CC(C)(C)c1ccc2c(c1)B1c3cc(C(C)(C)C)ccc3Oc3cc(-n4c5ccccc5c5c6oc7ccccc7c6c6c(c7ccccc7n6-c6ccccc6)c54)cc(c31)O2]

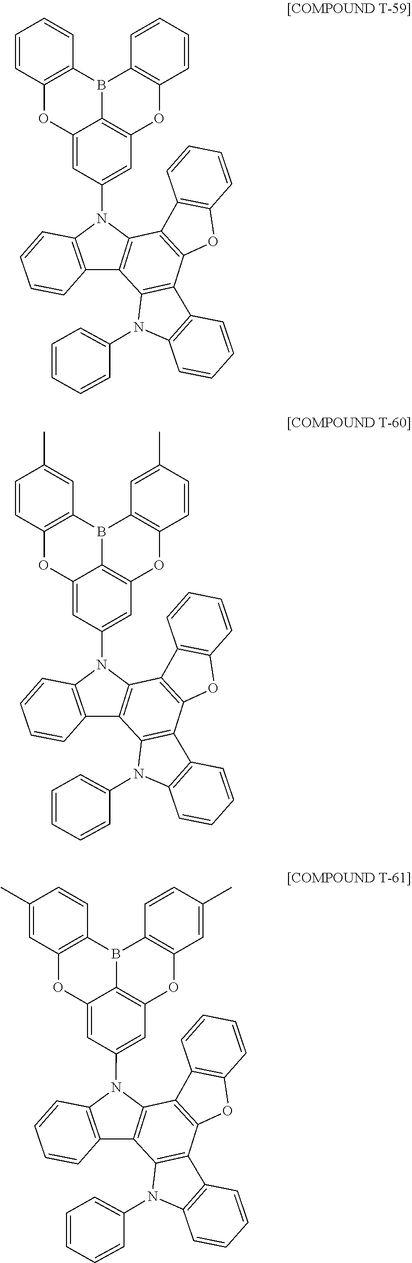 [SMILES: c1ccc(-n2c3ccccc3c3c4oc5ccccc5c4c4c(c5ccccc5n4-c4cc5c6c(c4)Oc4ccccc4B6c4ccccc4O5)c32)cc1 ; Cc1ccc2c(c1)B1c3cc(C)ccc3Oc3cc(-n4c5ccccc5c5c6c(c7ccccc7n6-c6ccccc6)c6oc7ccccc7c6c54)cc(c31)O2 ; Cc1ccc2c(c1)Oc1cc(-n3c4ccccc4c4c5c(c6ccccc6n5-c5ccccc5)c5oc6ccccc6c5c43)cc3c1B2c1ccc(C)cc1O3]

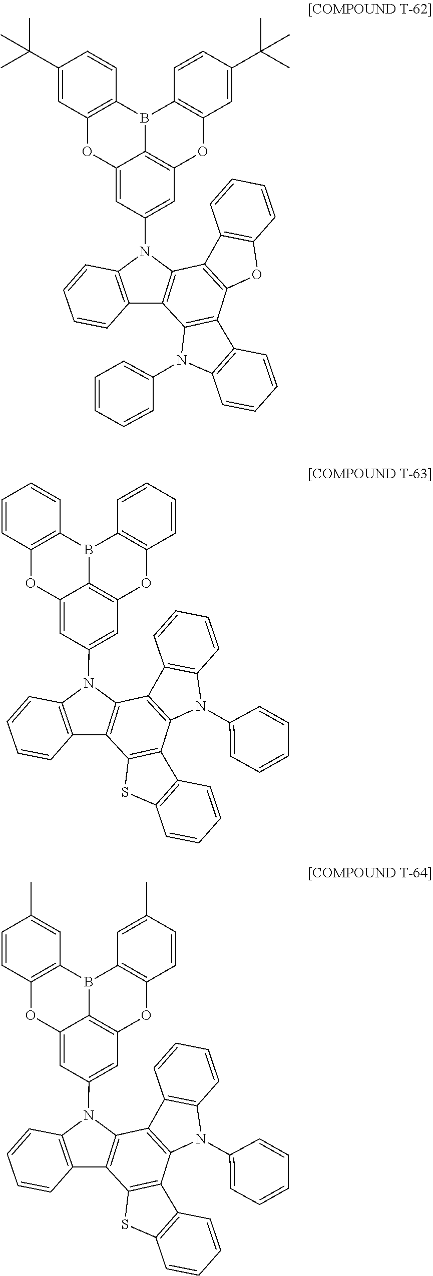 [SMILES: CC(C)(C)c1ccc2c(c1)Oc1cc(-n3c4ccccc4c4c5c(c6ccccc6n5-c5ccccc5)c5oc6ccccc6c5c43)cc3c1B2c1ccc(C(C)(C)C)cc1O3 ; c1ccc(-n2c3ccccc3c3c4c(c5ccccc5n4-c4cc5c6c(c4)Oc4ccccc4B6c4ccccc4O5)c4sc5ccccc5c4c32)cc1 ; Cc1ccc2c(c1)B1c3cc(C)ccc3Oc3cc(-n4c5ccccc5c5c6sc7ccccc7c6c6c(c7ccccc7n6-c6ccccc6)c54)cc(c31)O2]

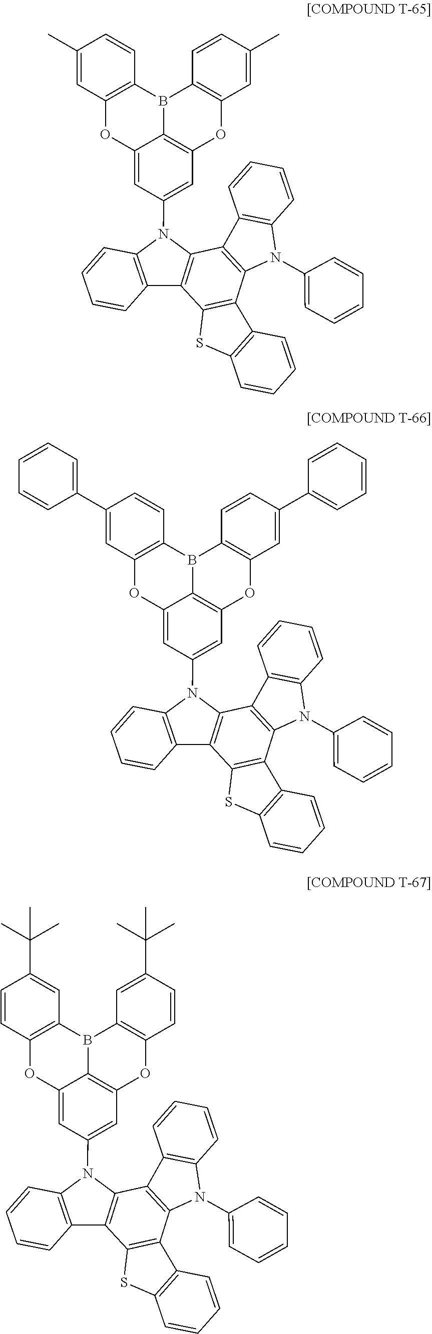 [SMILES: Cc1ccc2c(c1)Oc1cc(-n3c4ccccc4c4c5sc6ccccc6c5c5c(c6ccccc6n5-c5ccccc5)c43)cc3c1B2c1ccc(C)cc1O3 ; c1ccc(-c2ccc3c(c2)Oc2cc(-n4c5ccccc5c5c6sc7ccccc7c6c6c(c7ccccc7n6-c6ccccc6)c54)cc4c2B3c2ccc(-c3ccccc3)cc2O4)cc1 ; CC(C)(C)c1ccc2c(c1)B1c3cc(C(C)(C)C)ccc3Oc3cc(-n4c5ccccc5c5c6sc7ccccc7c6c6c(c7ccccc7n6-c6ccccc6)c54)cc(c31)O2]

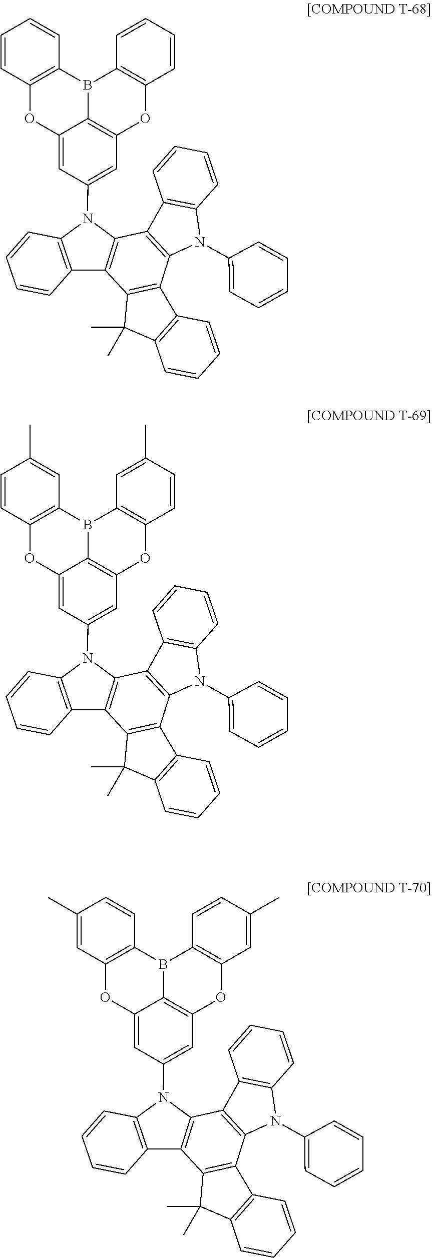 [SMILES: CC1(C)c2ccccc2-c2c1c1c3ccccc3n(-c3cc4c5c(c3)Oc3ccccc3B5c3ccccc3O4)c1c1c3ccccc3n(-c3ccccc3)c21 ; Cc1ccc2c(c1)B1c3cc(C)ccc3Oc3cc(-n4c5ccccc5c5c6c(c7c(c8ccccc8n7-c7ccccc7)c54)-c4ccccc4C6(C)C)cc(c31)O2 ; Cc1ccc2c(c1)Oc1cc(-n3c4ccccc4c4c5c(c6c(c7ccccc7n6-c6ccccc6)c43)-c3ccccc3C5(C)C)cc3c1B2c1ccc(C)cc1O3]

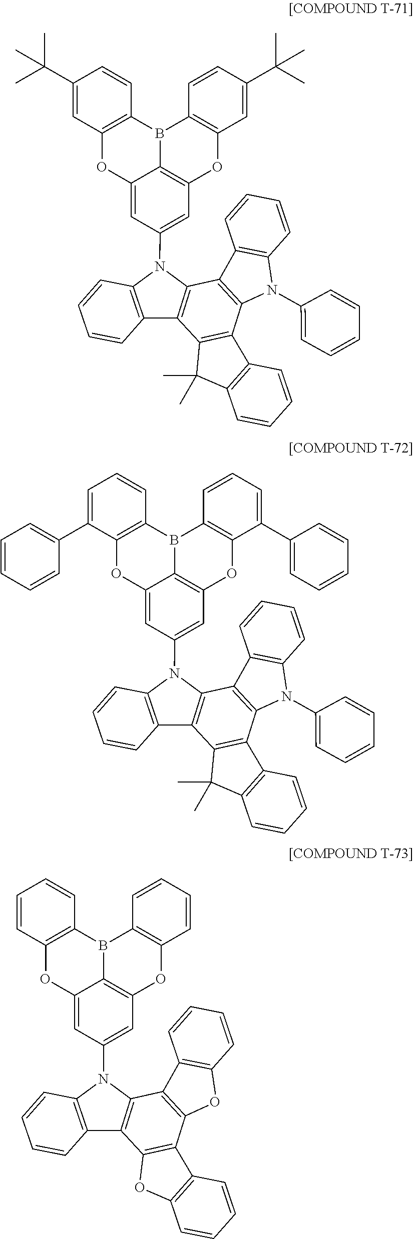 [SMILES: CC(C)(C)c1ccc2c(c1)Oc1cc(-n3c4ccccc4c4c5c(c6c(c7ccccc7n6-c6ccccc6)c43)-c3ccccc3C5(C)C)cc3c1B2c1ccc(C(C)(C)C)cc1O3 ; CC1(C)c2ccccc2-c2c1c1c3ccccc3n(-c3cc4c5c(c3)Oc3c(cccc3-c3ccccc3)B5c3cccc(-c5ccccc5)c3O4)c1c1c3ccccc3n(-c3ccccc3)c21 ; c1ccc2c(c1)Oc1cc(-n3c4ccccc4c4c5oc6ccccc6c5c5oc6ccccc6c5c43)cc3c1B2c1ccccc1O3]

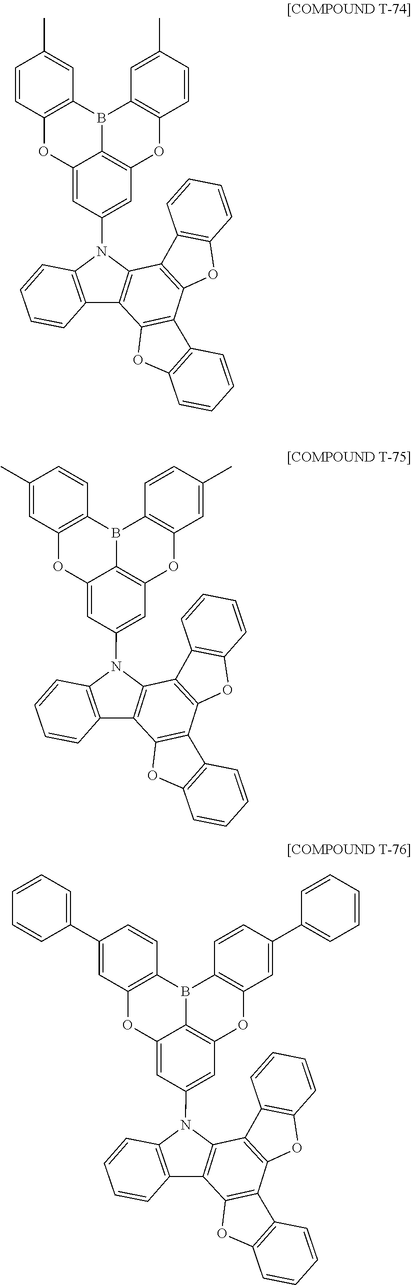 [SMILES: Cc1ccc2c(c1)B1c3cc(C)ccc3Oc3cc(-n4c5ccccc5c5c6oc7ccccc7c6c6oc7ccccc7c6c54)cc(c31)O2 ; Cc1ccc2c(c1)Oc1cc(-n3c4ccccc4c4c5oc6ccccc6c5c5oc6ccccc6c5c43)cc3c1B2c1ccc(C)cc1O3 ; c1ccc(-c2ccc3c(c2)Oc2cc(-n4c5ccccc5c5c6oc7ccccc7c6c6oc7ccccc7c6c54)cc4c2B3c2ccc(-c3ccccc3)cc2O4)cc1]

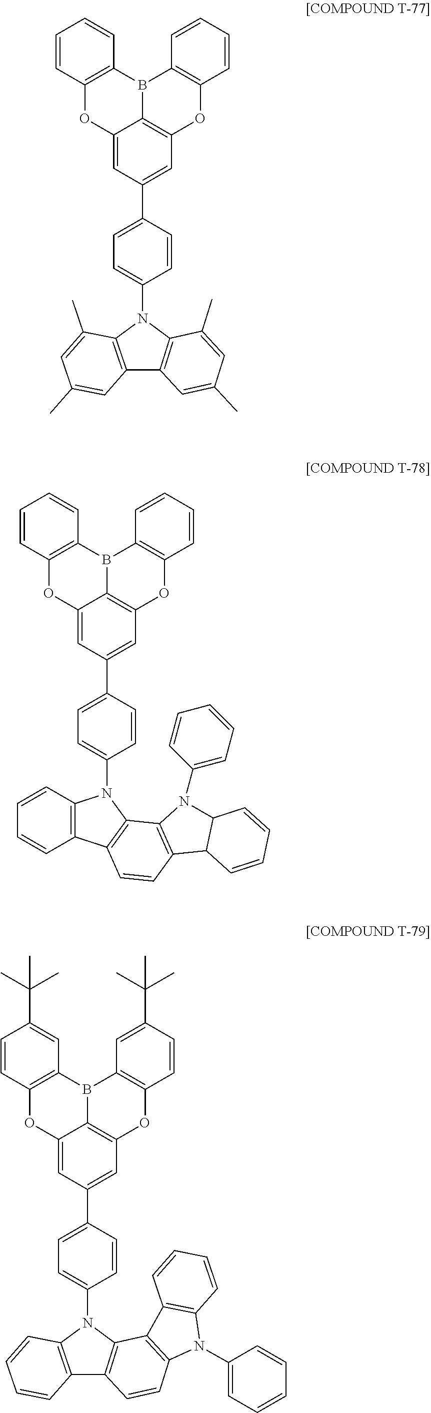

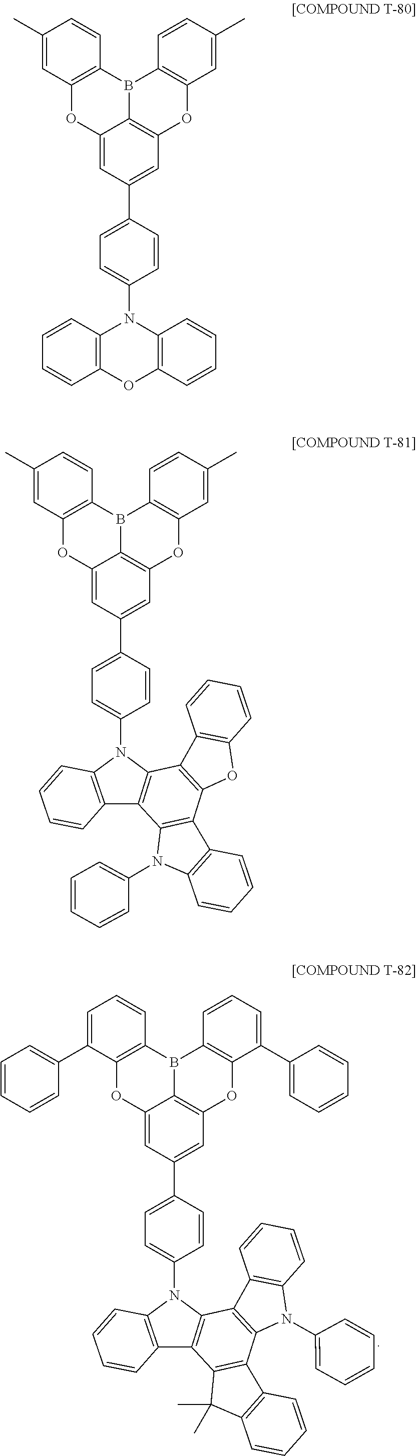

In an embodiment, the second compound may have a structure of one of the following Compounds H-1 to H-35:

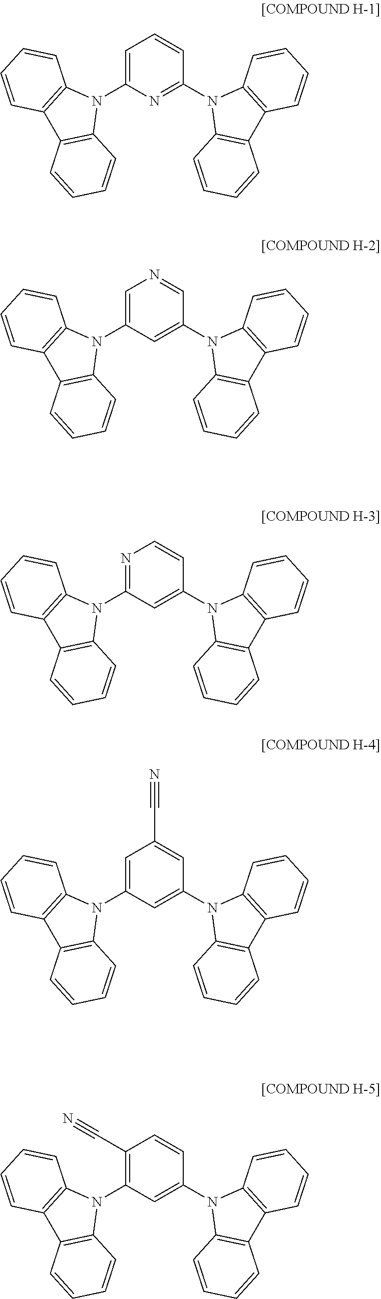 [SMILES: c1cc(-n2c3ccccc3c3ccccc32)nc(-n2c3ccccc3c3ccccc32)c1 ; c1ccc2c(c1)c1ccccc1n2-c1cncc(-n2c3ccccc3c3ccccc32)c1 ; c1ccc2c(c1)c1ccccc1n2-c1ccnc(-n2c3ccccc3c3ccccc32)c1 ; N#Cc1cc(-n2c3ccccc3c3ccccc32)cc(-n2c3ccccc3c3ccccc32)c1 ; N#Cc1ccc(-n2c3ccccc3c3ccccc32)cc1-n1c2ccccc2c2ccccc21]

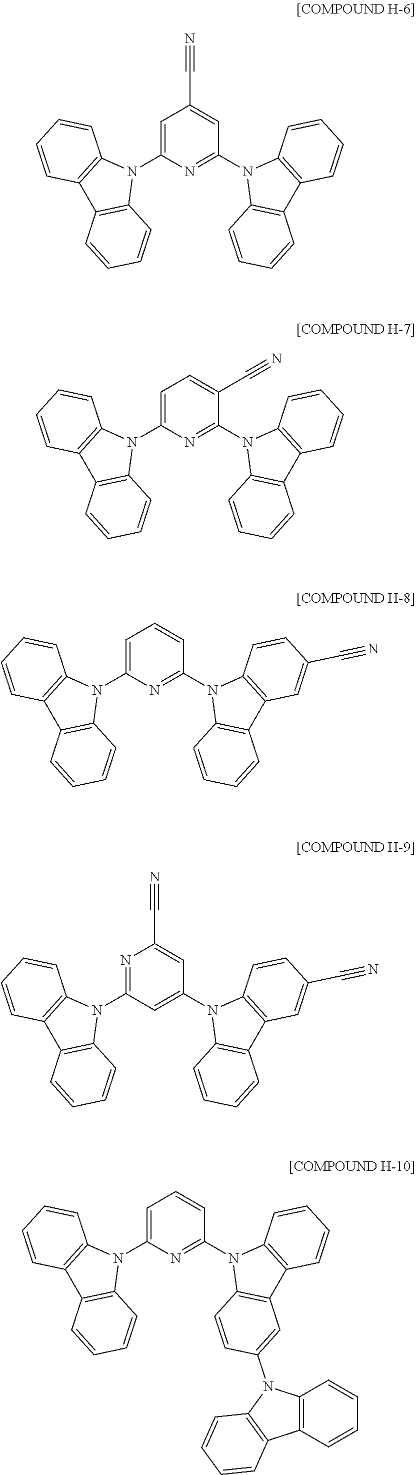 [SMILES: N#Cc1cc(-n2c3ccccc3c3ccccc32)nc(-n2c3ccccc3c3ccccc32)c1 ; N#Cc1ccc(-n2c3ccccc3c3ccccc32)nc1-n1c2ccccc2c2ccccc21 ; N#Cc1ccc2c(c1)c1ccccc1n2-c1cccc(-n2c3ccccc3c3ccccc32)n1 ; N#Cc1ccc2c(c1)c1ccccc1n2-c1cc(C#N)nc(-n2c3ccccc3c3ccccc32)c1 ; c1cc(-n2c3ccccc3c3ccccc32)nc(-n2c3ccccc3c3cc(-n4c5ccccc5c5ccccc54)ccc32)c1]

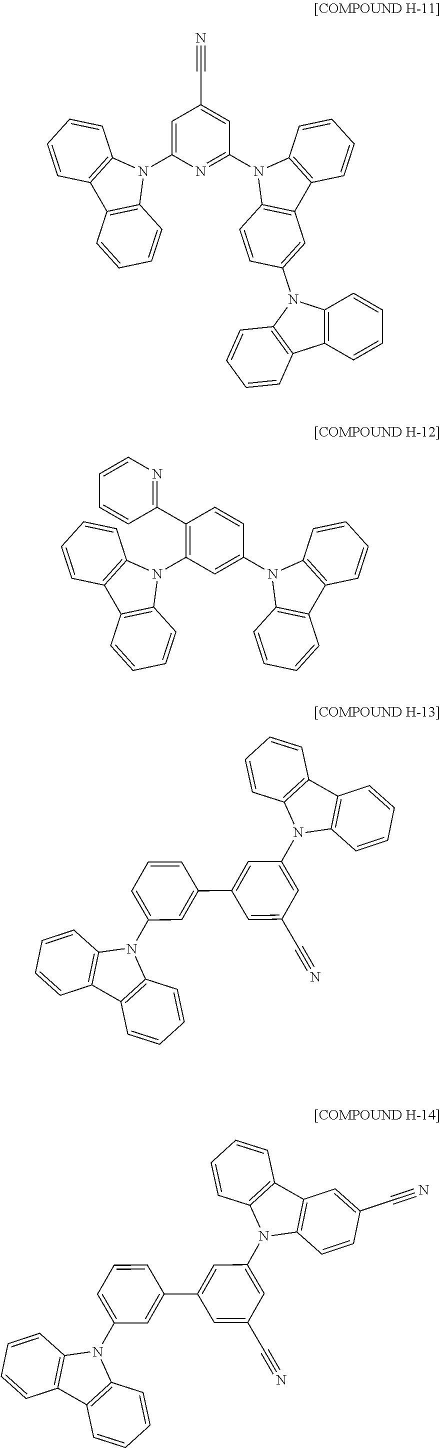 [SMILES: N#Cc1cc(-n2c3ccccc3c3ccccc32)nc(-n2c3ccccc3c3cc(-n4c5ccccc5c5ccccc54)ccc32)c1 ; c1ccc(-c2ccc(-n3c4ccccc4c4ccccc43)cc2-n2c3ccccc3c3ccccc32)nc1 ; N#Cc1cc(-c2cccc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

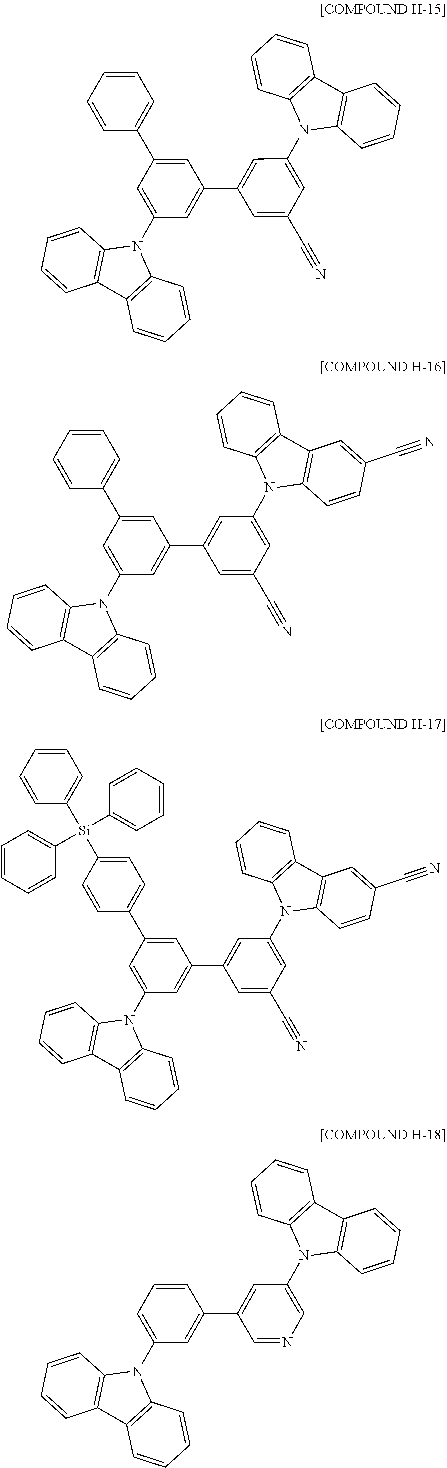 [SMILES: N#Cc1cc(-c2cc(-c3ccccc3)cc(-n3c4ccccc4c4ccccc43)c2)cc(-n2c3ccccc3c3ccccc32)c1 ; N#Cc1cc(-c2cc(-c3ccccc3)cc(-n3c4ccccc4c4ccccc43)c2)cc(-n2c3ccccc3c3cc(C#N)ccc32)c1 ; N#Cc1cc(-c2cc(-c3ccc([Si](c4ccccc4)(c4ccccc4)c4ccccc4)cc3)cc(-n3c4ccccc4c4ccccc43)c2)cc(-n2c3ccccc3c3cc(C#N)ccc32)c1 ; c1cc(-c2cncc(-n3c4ccccc4c4ccccc43)c2)cc(-n2c3ccccc3c3ccccc32)c1]

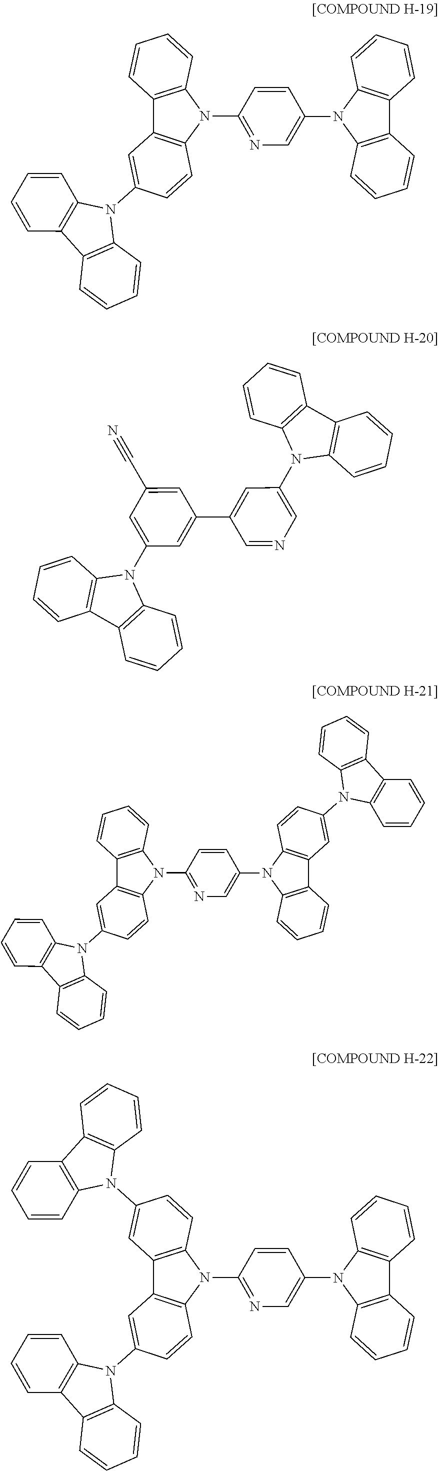 [SMILES: c1ccc2c(c1)c1ccccc1n2-c1ccc(-n2c3ccccc3c3cc(-n4c5ccccc5c5ccccc54)ccc32)nc1 ; N#Cc1cc(-c2cncc(-n3c4ccccc4c4ccccc43)c2)cc(-n2c3ccccc3c3ccccc32)c1 ; c1ccc2c(c1)c1ccccc1n2-c1ccc2c(c1)c1ccccc1n2-c1ccc(-n2c3ccccc3c3cc(-n4c5ccccc5c5ccccc54)ccc32)nc1 ; c1ccc2c(c1)c1ccccc1n2-c1ccc(-n2c3ccc(-n4c5ccccc5c5ccccc54)cc3c3cc(-n4c5ccccc5c5ccccc54)ccc32)nc1]

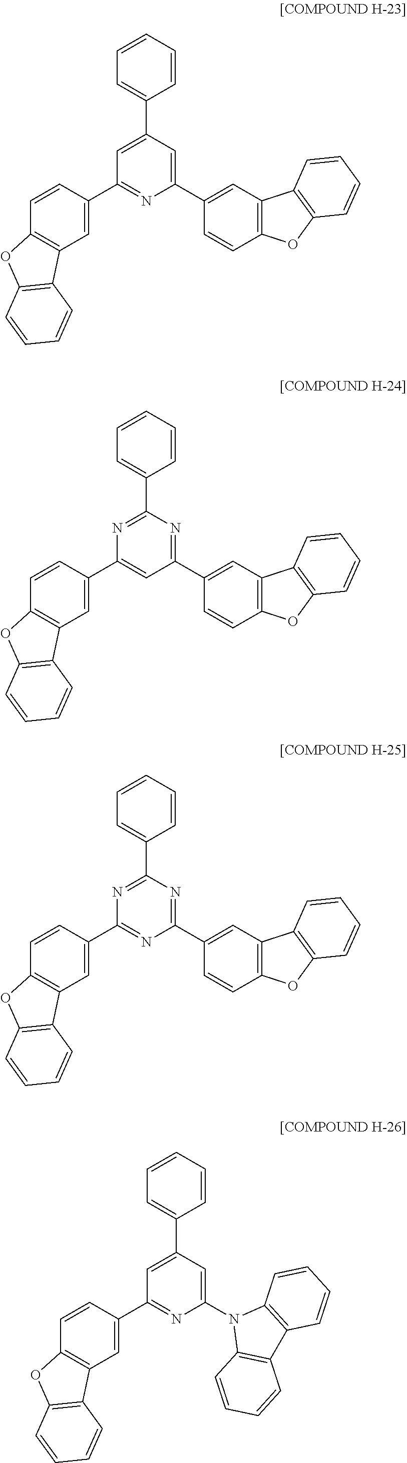 [SMILES: c1ccc(-c2cc(-c3ccc4oc5ccccc5c4c3)nc(-c3ccc4oc5ccccc5c4c3)c2)cc1 ; c1ccc(-c2nc(-c3ccc4oc5ccccc5c4c3)cc(-c3ccc4oc5ccccc5c4c3)n2)cc1 ; c1ccc(-c2nc(-c3ccc4oc5ccccc5c4c3)nc(-c3ccc4oc5ccccc5c4c3)n2)cc1 ; c1ccc(-c2cc(-c3ccc4oc5ccccc5c4c3)nc(-n3c4ccccc4c4ccccc43)c2)cc1]

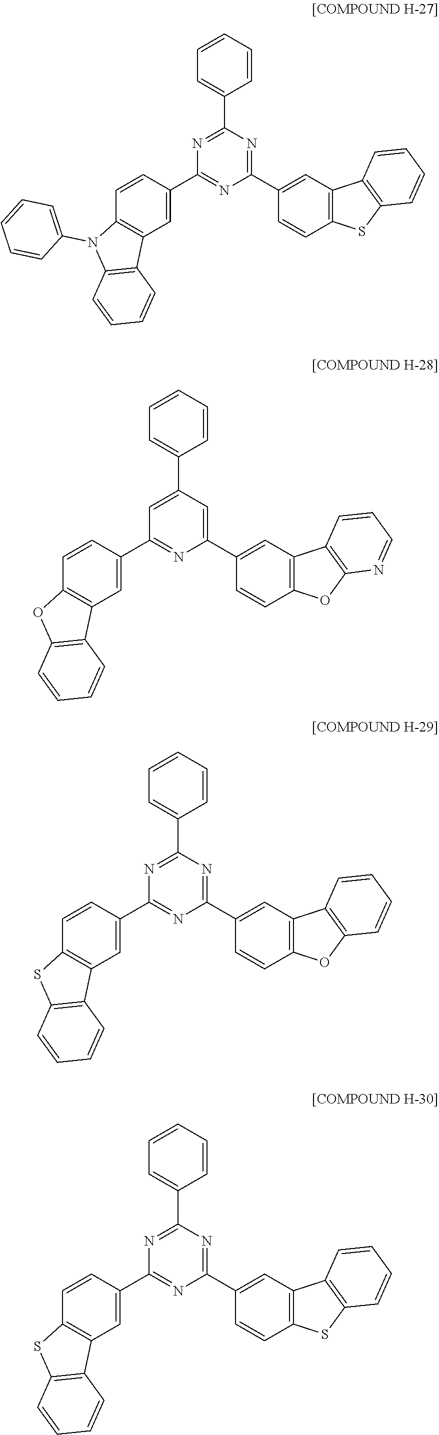 [SMILES: c1ccc(-c2nc(-c3ccc4sc5ccccc5c4c3)nc(-c3ccc4c(c3)c3ccccc3n4-c3ccccc3)n2)cc1 ; c1ccc(-c2cc(-c3ccc4oc5ccccc5c4c3)nc(-c3ccc4oc5ncccc5c4c3)c2)cc1 ; c1ccc(-c2nc(-c3ccc4oc5ccccc5c4c3)nc(-c3ccc4sc5ccccc5c4c3)n2)cc1 ; c1ccc(-c2nc(-c3ccc4sc5ccccc5c4c3)nc(-c3ccc4sc5ccccc5c4c3)n2)cc1]

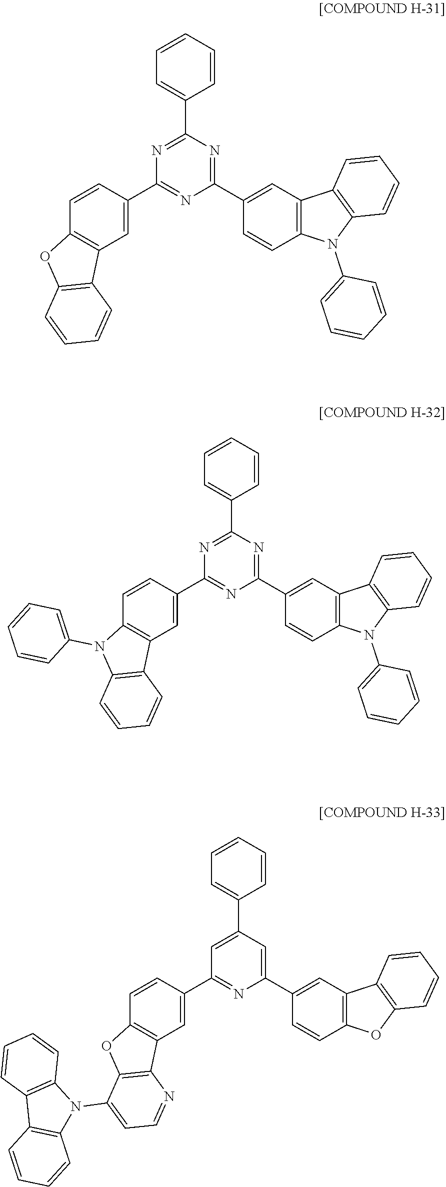 [SMILES: c1ccc(-c2nc(-c3ccc4oc5ccccc5c4c3)nc(-c3ccc4c(c3)c3ccccc3n4-c3ccccc3)n2)cc1 ; c1ccc(-c2nc(-c3ccc4c(c3)c3ccccc3n4-c3ccccc3)nc(-c3ccc4c(c3)c3ccccc3n4-c3ccccc3)n2)cc1 ; c1ccc(-c2cc(-c3ccc4oc5ccccc5c4c3)nc(-c3ccc4oc5c(-n6c7ccccc7c7ccccc76)ccnc5c4c3)c2)cc1]

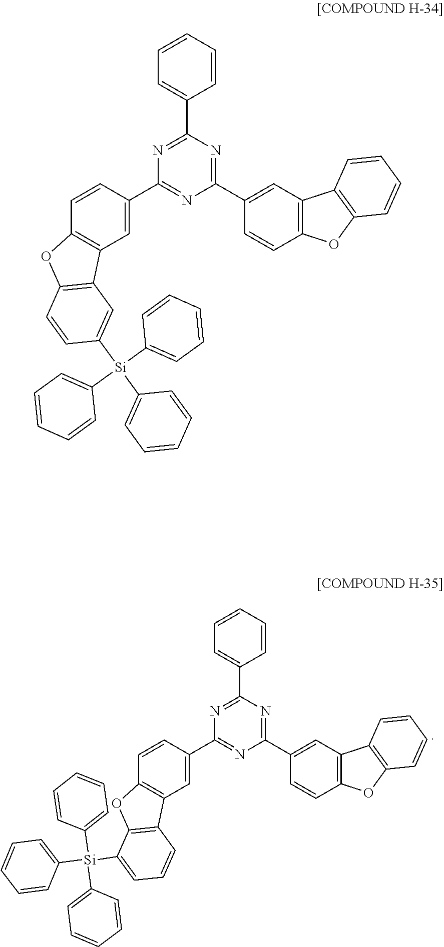 [SMILES: c1ccc(-c2nc(-c3ccc4oc5ccccc5c4c3)nc(-c3ccc4oc5ccc([Si](c6ccccc6)(c6ccccc6)c6ccccc6)cc5c4c3)n2)cc1 ; c1ccc(-c2nc(-c3ccc4oc5ccccc5c4c3)nc(-c3ccc4oc5c([Si](c6ccccc6)(c6ccccc6)c6ccccc6)cccc5c4c3)n2)cc1]

In an embodiment, the third compound may have a structure of one of the following Compounds F-1 to F-51:

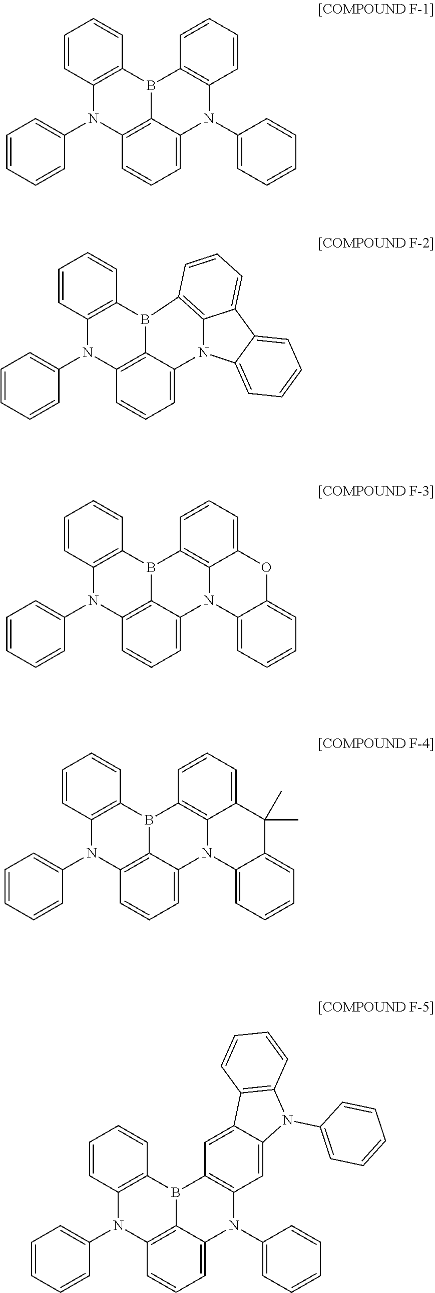 [SMILES: c1ccc(N2c3ccccc3B3c4ccccc4N(c4ccccc4)c4cccc2c43)cc1 ; c1ccc(N2c3ccccc3B3c4c2cccc4-n2c4ccccc4c4cccc3c42)cc1 ; c1ccc(N2c3ccccc3B3c4cccc5c4N(c4ccccc4O5)c4cccc2c43)cc1 ; CC1(C)c2ccccc2N2c3cccc4c3B(c3ccccc3N4c3ccccc3)c3cccc1c32 ; c1ccc(N2c3ccccc3B3c4cc5c6ccccc6n(-c6ccccc6)c5cc4N(c4ccccc4)c4cccc2c43)cc1]

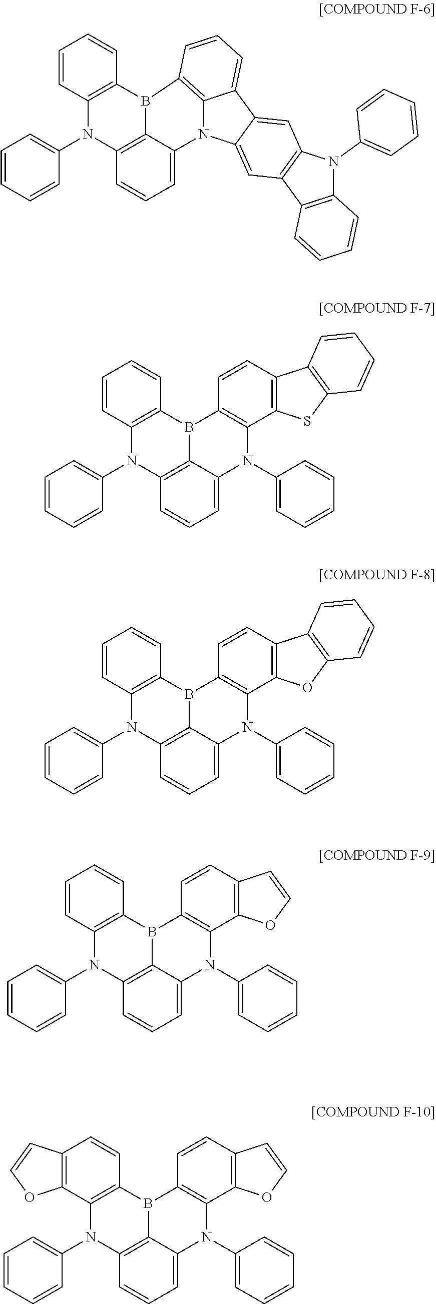 [SMILES: c1ccc(N2c3ccccc3B3c4c2cccc4-n2c4cc5c6ccccc6n(-c6ccccc6)c5cc4c4cccc3c42)cc1 ; c1ccc(N2c3ccccc3B3c4ccc5c(sc6ccccc65)c4N(c4ccccc4)c4cccc2c43)cc1 ; c1ccc(N2c3ccccc3B3c4ccc5c(oc6ccccc65)c4N(c4ccccc4)c4cccc2c43)cc1 ; c1ccc(N2c3ccccc3B3c4ccc5ccoc5c4N(c4ccccc4)c4cccc2c43)cc1 ; c1ccc(N2c3cccc4c3B(c3ccc5ccoc5c32)c2ccc3ccoc3c2N4c2ccccc2)cc1]

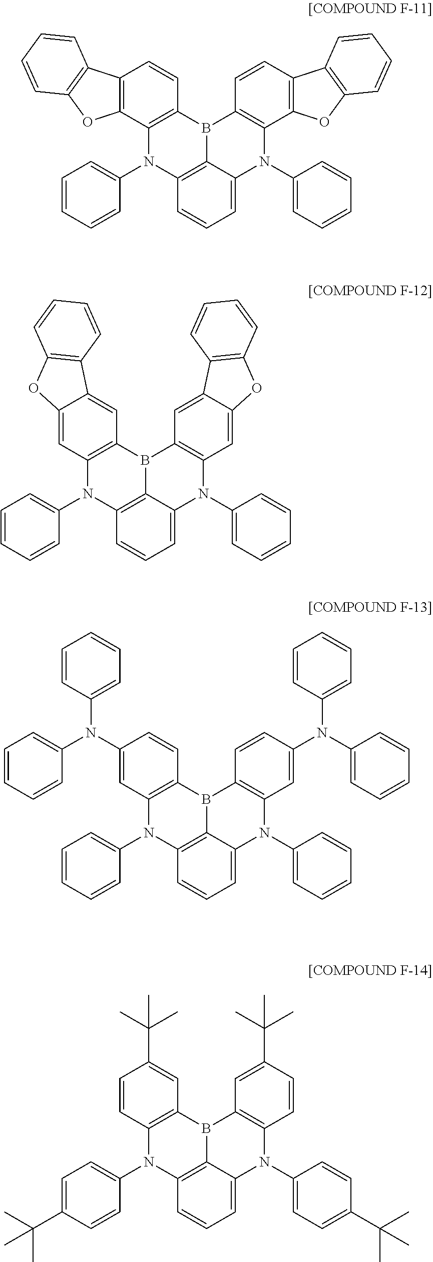 [SMILES: c1ccc(N2c3cccc4c3B(c3ccc5c(oc6ccccc65)c32)c2ccc3c(oc5ccccc53)c2N4c2ccccc2)cc1 ; c1ccc(N2c3cc4oc5ccccc5c4cc3B3c4cc5c(cc4N(c4ccccc4)c4cccc2c43)oc2ccccc25)cc1 ; c1ccc(N(c2ccccc2)c2ccc3c(c2)N(c2ccccc2)c2cccc4c2B3c2ccc(N(c3ccccc3)c3ccccc3)cc2N4c2ccccc2)cc1 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1]

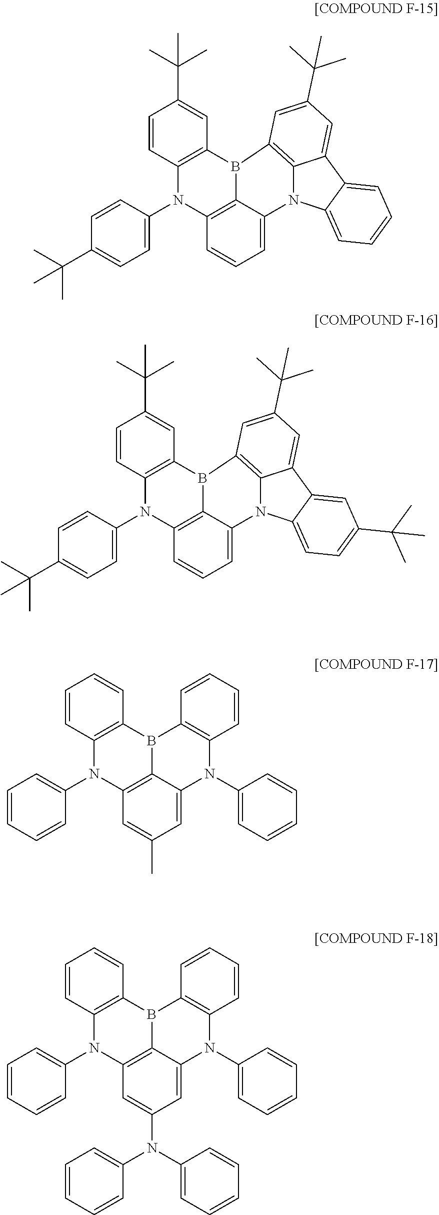 [SMILES: CC(C)(C)c1ccc(N2c3ccc(C(C)(C)C)cc3B3c4c2cccc4-n2c4ccccc4c4cc(C(C)(C)C)cc3c42)cc1 ; CC(C)(C)c1ccc(N2c3ccc(C(C)(C)C)cc3B3c4c2cccc4-n2c4ccc(C(C)(C)C)cc4c4cc(C(C)(C)C)cc3c42)cc1 ; Cc1cc2c3c(c1)N(c1ccccc1)c1ccccc1B3c1ccccc1N2c1ccccc1 ; c1ccc(N(c2ccccc2)c2cc3c4c(c2)N(c2ccccc2)c2ccccc2B4c2ccccc2N3c2ccccc2)cc1]

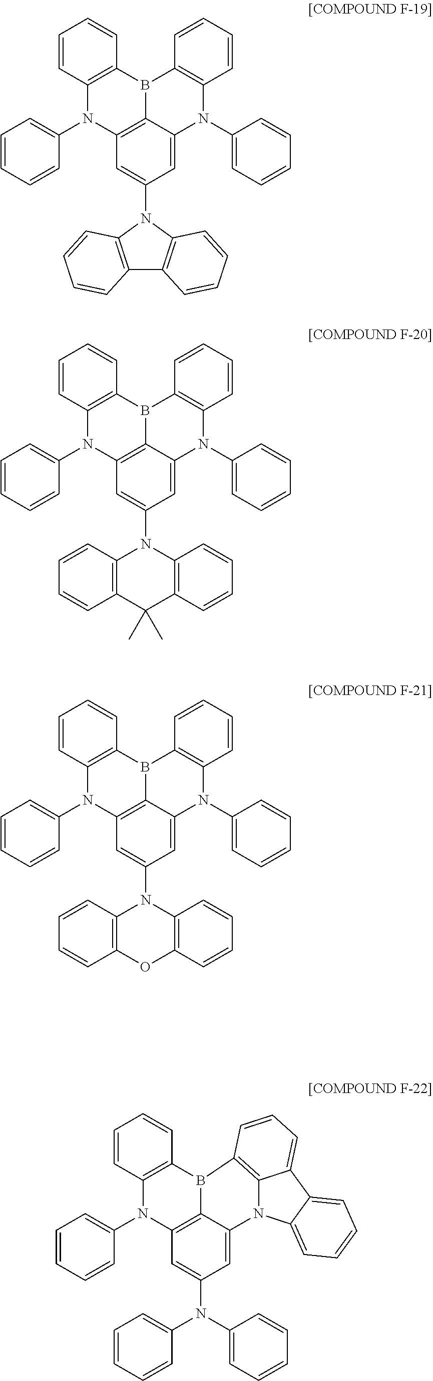 [SMILES: c1ccc(N2c3ccccc3B3c4ccccc4N(c4ccccc4)c4cc(-n5c6ccccc6c6ccccc65)cc2c43)cc1 ; CC1(C)c2ccccc2N(c2cc3c4c(c2)N(c2ccccc2)c2ccccc2B4c2ccccc2N3c2ccccc2)c2ccccc21 ; c1ccc(N2c3ccccc3B3c4ccccc4N(c4ccccc4)c4cc(N5c6ccccc6Oc6ccccc65)cc2c43)cc1 ; c1ccc(N(c2ccccc2)c2cc3c4c(c2)-n2c5ccccc5c5cccc(c52)B4c2ccccc2N3c2ccccc2)cc1]

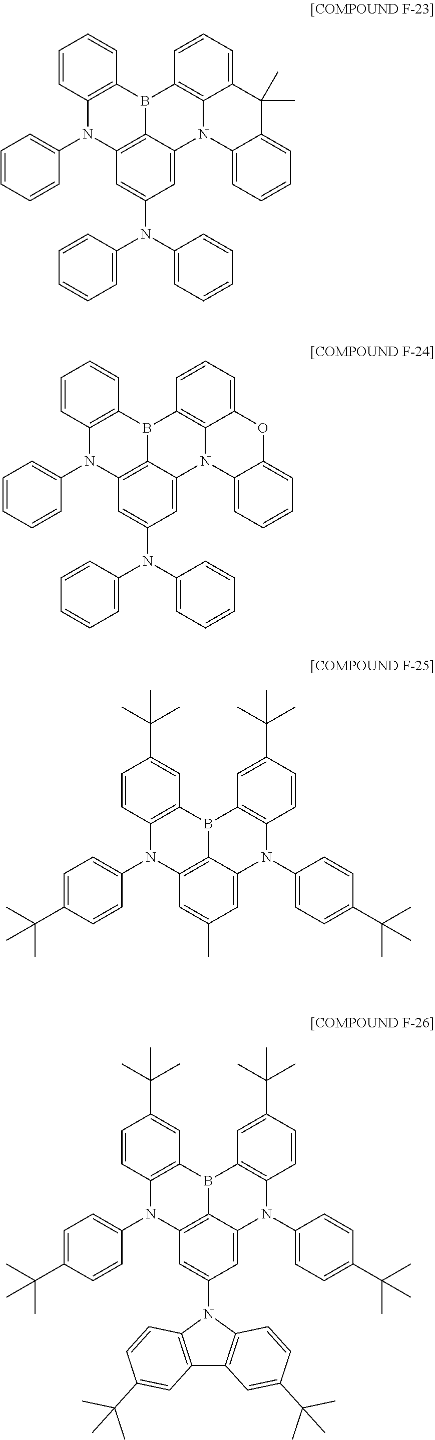

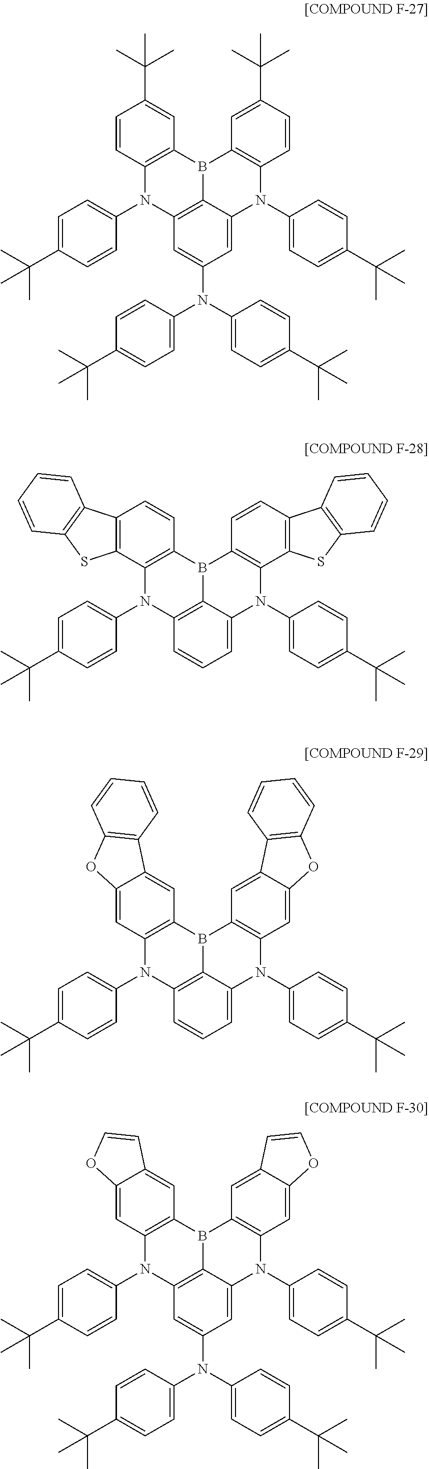

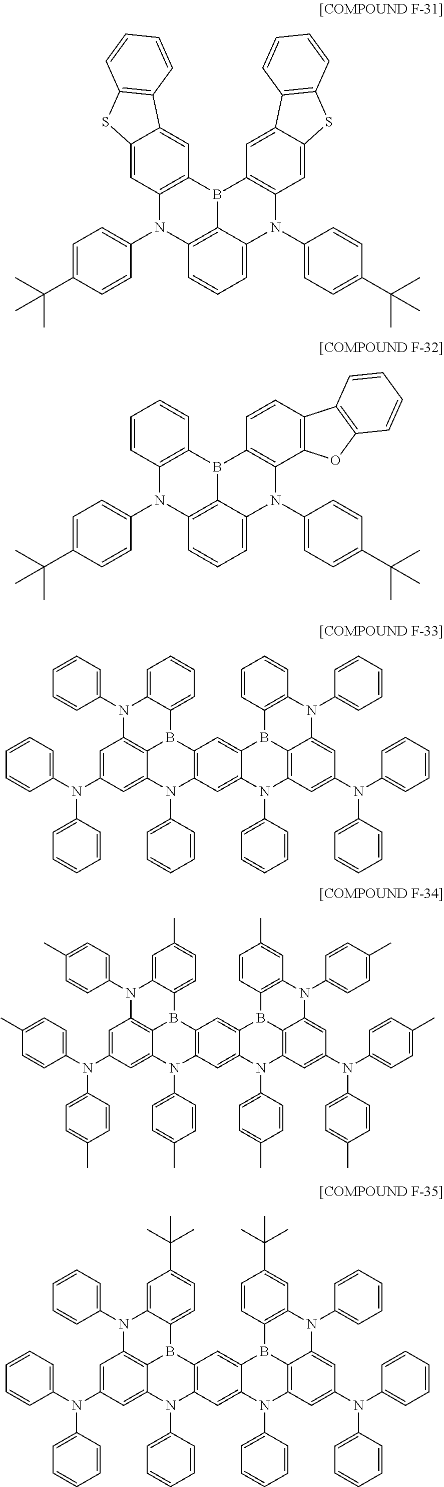

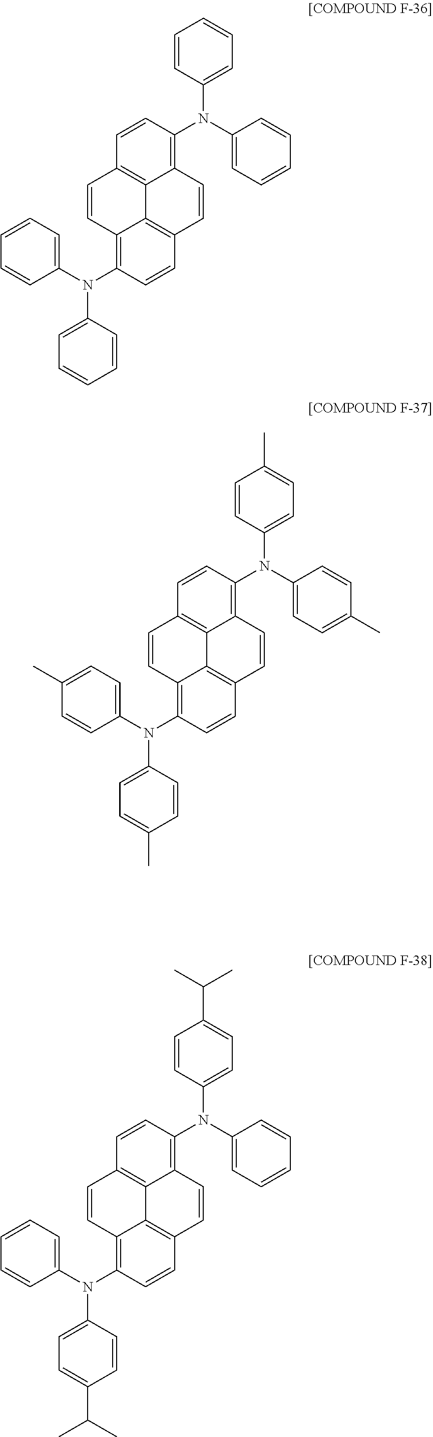

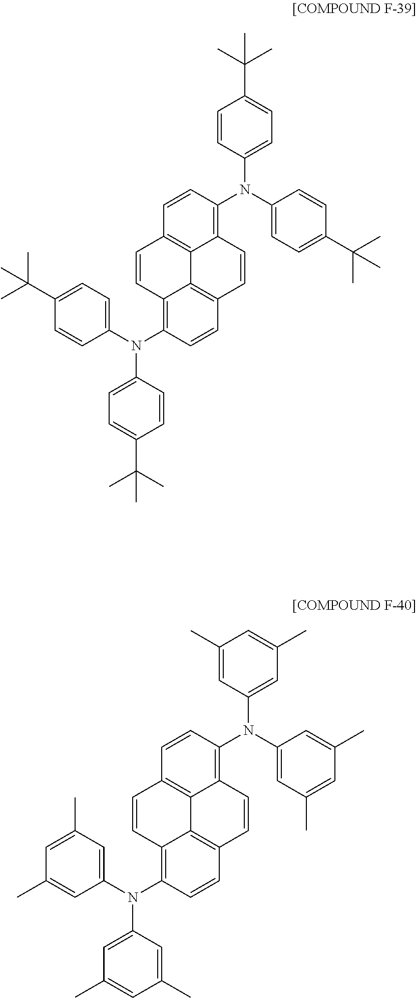

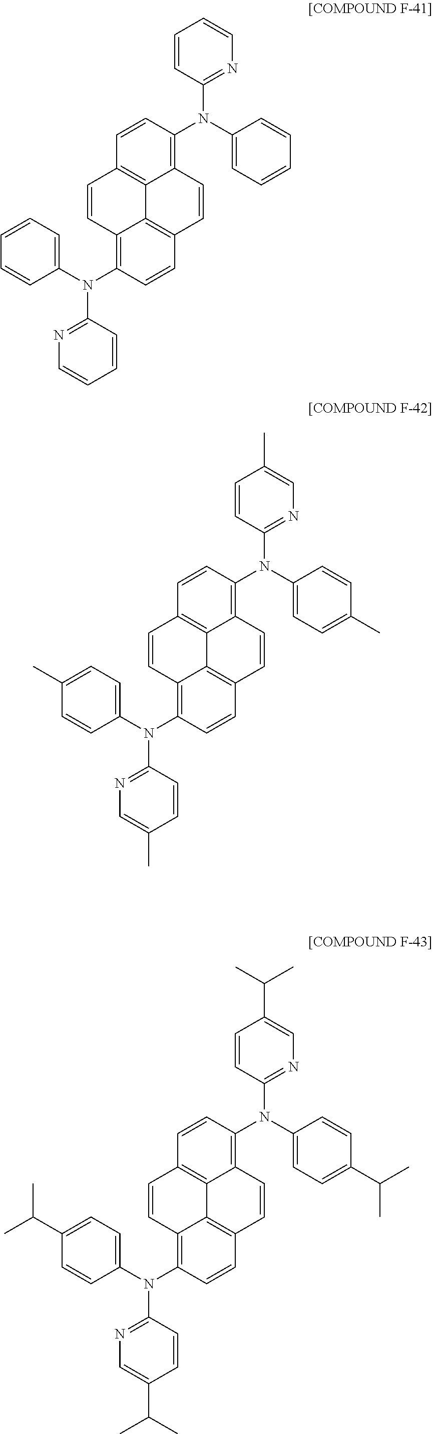

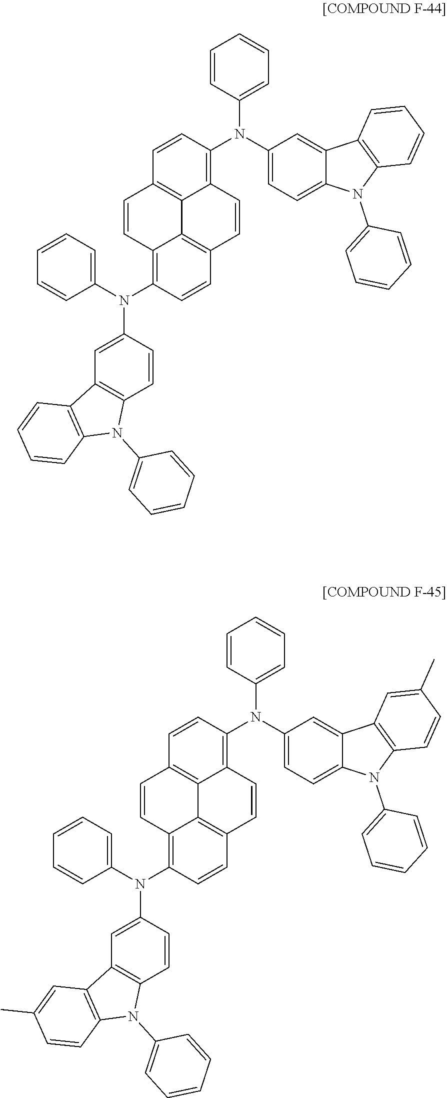 [SMILES: c1ccc(N(c2ccc3c(c2)c2ccccc2n3-c2ccccc2)c2ccc3ccc4c(N(c5ccccc5)c5ccc6c(c5)c5ccccc5n6-c5ccccc5)ccc5ccc2c3c54)cc1 ; Cc1ccc2c(c1)c1cc(N(c3ccccc3)c3ccc4ccc5c(N(c6ccccc6)c6ccc7c(c6)c6cc(C)ccc6n7-c6ccccc6)ccc6ccc3c4c65)ccc1n2-c1ccccc1]

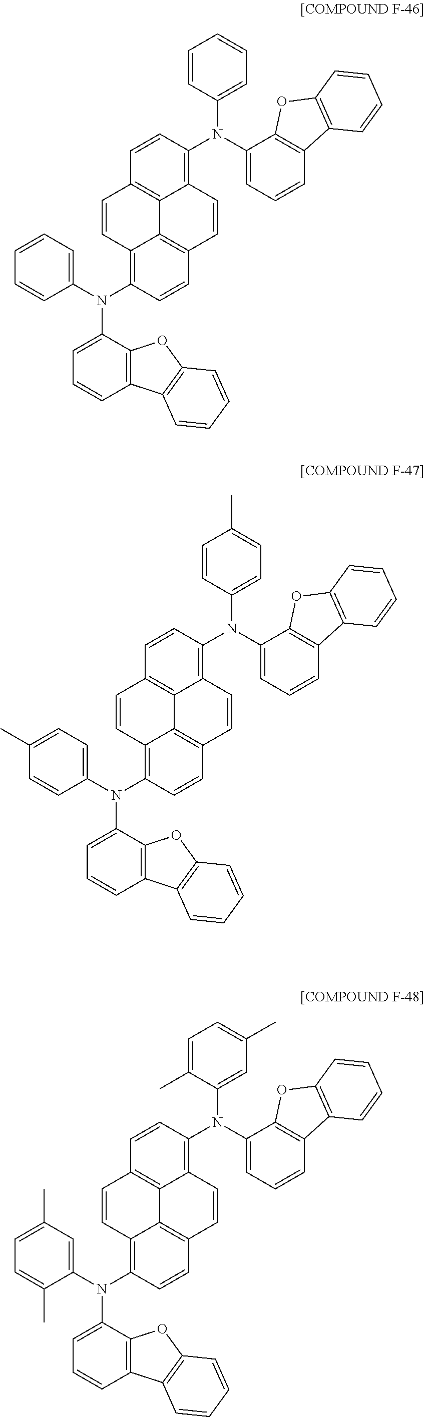 [SMILES: c1ccc(N(c2ccc3ccc4c(N(c5ccccc5)c5cccc6c5oc5ccccc56)ccc5ccc2c3c54)c2cccc3c2oc2ccccc23)cc1 ; Cc1ccc(N(c2ccc3ccc4c(N(c5ccc(C)cc5)c5cccc6c5oc5ccccc56)ccc5ccc2c3c54)c2cccc3c2oc2ccccc23)cc1 ; Cc1ccc(C)c(N(c2ccc3ccc4c(N(c5cc(C)ccc5C)c5cccc6c5oc5ccccc56)ccc5ccc2c3c54)c2cccc3c2oc2ccccc23)c1]

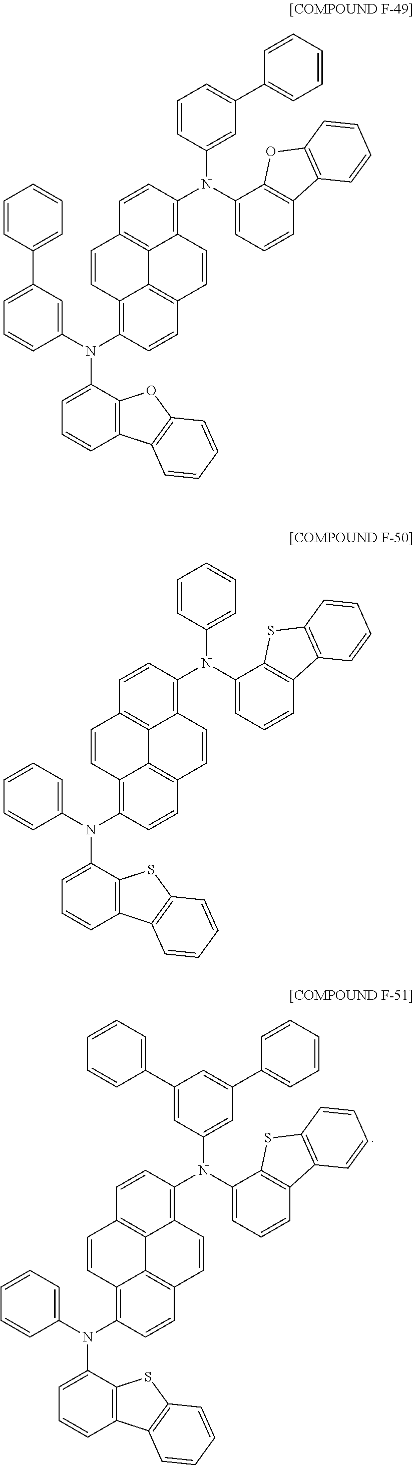 [SMILES: c1ccc(-c2cccc(N(c3ccc4ccc5c(N(c6cccc(-c7ccccc7)c6)c6cccc7c6oc6ccccc67)ccc6ccc3c4c65)c3cccc4c3oc3ccccc34)c2)cc1 ; c1ccc(N(c2ccc3ccc4c(N(c5ccccc5)c5cccc6c5sc5ccccc56)ccc5ccc2c3c54)c2cccc3c2sc2ccccc23)cc1 ; c1ccc(-c2cc(-c3ccccc3)cc(N(c3ccc4ccc5c(N(c6ccccc6)c6cccc7c6sc6ccccc67)ccc6ccc3c4c65)c3cccc4c3sc3ccccc34)c2)cc1]

In an embodiment, the organic light-emitting device may include: a first electrode and a second electrode facing each other; and a layered structure located between the first electrode and the second electrode, where the light-emitting layer is included in the layered structure.

In an embodiment, the layered structure may include at least one of a hole injection layer, a hole transport layer, an exciton blocking layer, an electron transport layer and an electron injection layer.

In an embodiment, the organic light-emitting device may have an LT90 lifetime of 10 hours or more at 1,000 nits.

### Advantageous Effects

According to an aspect of the present specification, the light-emitting layer includes a host having stronger binding strength energy in an anion state than that of the dopant, and the LUMO energy level of the host is adjusted according to the type of delayed fluorescent dopant so that electrons are designed to flow mainly to the host to delay deterioration of a delayed fluorescent material that is vulnerable to electrons, thereby significantly improving the lifespan characteristics of the delayed fluorescent device or delayed fluorescence photosensitive type hyperfluorescence device.

The effects of the present specification are not limited to the above-mentioned effects, and it should be understood that the effects of the present specification include all effects that could be inferred from the configuration of the invention described in the detailed description of the invention or the appended claims.

### DESCRIPTION OF DRAWINGS

FIG. 1 is a graph showing an electron movement path of an organic light-emitting device according to an embodiment of the present specification.

FIG. 2 is a graph showing the reasons for poor life characteristics of existing materials for light-emitting devices.

FIG. 3 is a graph showing the lifespan characteristics of organic light-emitting devices according to Examples and Comparative Examples of the present specification.

FIG. 4 is a graph showing the external quantum efficiency characteristics of organic light-emitting devices according to Examples and Comparative Examples of the present specification.

### MODES OF THE INVENTION

Hereinafter, the present specification will be described with reference to the accompanying drawings. However, the description of the present specification may be implemented in various different forms, and thus is not limited to the embodiments described herein. In addition, in order to clearly explain an aspect of the present specification in the drawings, portions that are not related to the present invention are omitted, and like reference numerals are used to refer to like elements throughout the specification.

Throughout the specification, it will be understood that when a portion is referred to as being “connected” to another portion, it can be “directly connected to” the other portion, or “indirectly connected to” the other portion with another member interposed therebetween. Also, when a component “includes” an element, it should be understood that the component does not exclude another element but may further include another element, unless otherwise stated.

When a numerical value is presented herein, the value has the precision of the significant digit provided in accordance with the standard rules in chemistry for significant digits unless its specific range is stated otherwise. For example, the numerical value 10 includes the range of 5.0 to 14.9 and the numerical value 10.0 includes the range of 9.50 to 10.49.

Hereinafter, embodiments of the present specification will be described in detail with reference to the accompanying drawings.

Organic Light-Emitting Device

An organic light-emitting device according to an aspect of the present specification may include a light-emitting layer which includes a first compound having a lowest unoccupied molecular orbital (LUMO) energy level of EL₁ and being a delayed fluorescent dopant, and a second compound having a LUMO energy level of EL₂ and being a host, and which satisfies |EL₁|−|EL₂|≤0.2 eV, and the binding energy of the first compound in an anion state may be lower than the binding energy of the second compound in an anion state.

A delayed fluorescent dopant containing boron has a high photon yield and a short triplet lifetime, but has a short operating lifespan. According to an aspect of the present specification, the weakness of delayed fluorescence may be compensated for and the lifetime of the device may be increased by controlling the characteristics of the host material doped into the light-emitting layer together with the delayed fluorescent dopant.

Since boron-based dopants tend to have weak bonding strength in an anion state, when a host having strong bonding strength in an anion state and excellent electron transport ability is applied, electrons may mainly move along the host when migrating from the electron transport layer toward the light-emitting layer in the state in which current is applied. At this time, when the binding energy of the delayed fluorescent dopant in an anion state is lower than that of the host and a value of |EL₁|−|EL₂| is 0.2 eV or less, electrons mainly move along the host. For example, since the LUMO energy level of a common boron-based delayed fluorescent dopant is in the range of 2.6 to 2.7 eV, the suitable LUMO energy level of the host may be 2.5 eV or less. Here, when the LUMO energy level of the host is equal to or lower than the LUMO energy level of the delayed fluorescent dopant, the aforementioned effect may be more easily realized. When the delayed fluorescent dopant and the host satisfy the aforementioned energy level relationship, the delayed fluorescent dopant may avoid electron attack in the light-emitting layer to prevent degradation of materials. The host material applied together is resistant to electrons and hardly deteriorates, resulting in an increase in the lifetime of the device.

In an example, the first compound having a LUMO energy level of EL₁ and being a delayed fluorescent dopant may be represented by the structure of the following Formula 1, and may have a binding energy in an anion state lower than that of the second compound serving as a host:

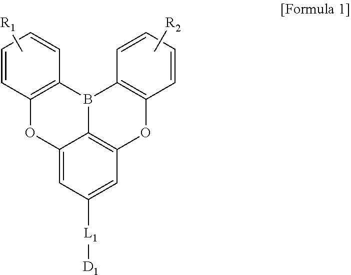

in Formula 1, D₁ is represented by one of the following Formulas 2 to 4,

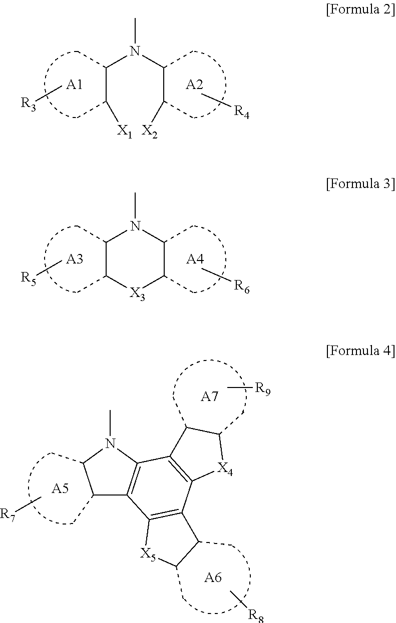

where A₁ to A₇ each independently represent a ring structure selected from a substituted or unsubstituted C₅ to C₆₀ carbocyclic group or a substituted or unsubstituted C₂ to C₆₀ heterocyclic group;
L₁ is a single bond or C₆ to C₆₀ arylene;
X₁ and X₂ each represent hydrogen or are mutually bonded to form a ring,
X₃ is O, N—R₂₆, S or C—(R₂₇)₂;
X₄ and X₅ each independently represent O, N—R₂₈, S or C—(R₂₉)₂;
R₁ to R₉ are each independently selected from hydrogen, deuterium, —F, —Cl, —Br, —I, a hydroxyl group, a cyano group, a nitro group, an amino group, an amidino group, a hydrazino group, a hydrazono group, a substituted or unsubstituted C₁ to C₆₀ alkyl group, a substituted or unsubstituted C₂ to C₆₀ alkenyl group, a substituted or unsubstituted C₂ to C₆₀ alkynyl group, a substituted or unsubstituted C₁ to C₆₀ alkoxy group, a substituted or unsubstituted C₃ to C₁₀ cycloalkyl group, a substituted or unsubstituted C₂ to C₁₀ heterocycloalkyl group, a substituted or unsubstituted C₃ to C₁₀ cycloalkenyl group, a substituted or unsubstituted C₂ to C₁₀ heterocycloalkenyl group, a substituted or unsubstituted C₆ to C₆₀ aryl group, a substituted or unsubstituted C₆ to C₆₀ aryloxy group, a substituted or unsubstituted C₆ to C₆₀ arylthio group, a substituted or unsubstituted C₁ to C₆₀ heteroaryl group, a substituted or unsubstituted C₁ to C₆₀ heteroaryloxy group, a substituted or unsubstituted monovalent non-aromatic condensed polycyclic group and a substituted or unsubstituted monovalent non-aromatic heterocondensed polycyclic group,
R₂₆ to R₂₉ are each independently selected from hydrogen, deuterium, a C₁ to C₆₀ alkyl group, a C₃ to C₁₀ cycloalkyl group, a C₆ to C₆₀ aryl group, or a C₁ to C₆₀ heteroaryl group.

In an example, the second compound having a LUMO energy level of EL₂ and being a host may be represented by a structure selected from the following Formulas 5 and 6, and may have a binding energy in an anion state higher than that of the first compound which is a delayed fluorescent dopant.

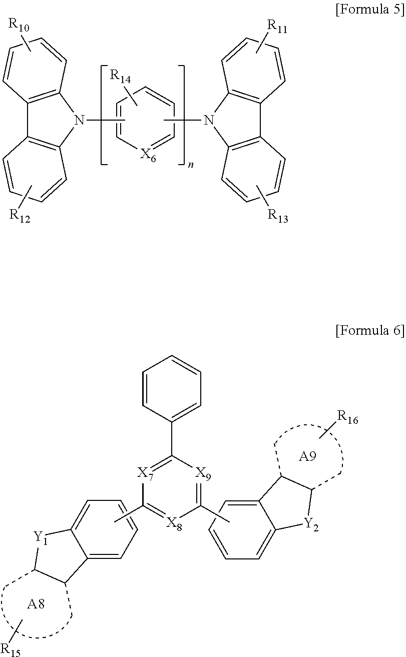

where A₈ to A₉ each independently represent a ring structure selected from a substituted or unsubstituted C₅ to C₆₀ carbocyclic group or a C₂ to C₆₀ heterocyclic group; X₆ is N or C—H; X₇ to X₉ are each independently selected from N or C—H and at least one of X₇ to X₉ is N, Y₁ to Y₂ are each independently selected from N—R₃₀, O or S; R₁₀ to R₁₄ are each independently selected from hydrogen, deuterium, a silyl group, a cyano group, a C₁ to C₆₀ alkyl group, a C₃ to C₁₀ cycloalkyl group, a C₆ to C₆₀ aryl group, a C₁ to C₆₀ heteroaryl group, a C₆ to C₃₀ diarylamino group, a C₂ to C₄₀ diheteroarylamino group, and a C₁₀ to C₄₀ arylheteroarylamino group; R₁₅ to R₁₆ are each independently selected from hydrogen, deuterium, a silyl group, a cyano group, a C₁ to C₆₀ alkyl group, a C₃ to C₁₀ cycloalkyl group, a C₆ to C₆₀ aryl group, a C₁ to C₆₀ heteroaryl group, a C₆ to C₃₀ diarylamino group, a C₂ to C₄₀ diheteroarylamino group, and a C₁₀ to C₄₀ arylheteroarylamino group; R₃₀ is selected from hydrogen, deuterium, a C₁ to C₆₀ alkyl group, a C₃ to C₁₀ cycloalkyl group, a C₆ to C₆₀ aryl group, or a C₁ to C₆₀ heteroaryl group; n is 1 or 2; and a compound of Formula 5 or 6 includes at least one nitrogen-containing benzene or benzene to which a cyano group is bonded.

The light-emitting layer may be represented by a structure selected from the following Formulas 7 and 8, further include a third compound having fluorescence or delayed fluorescence characteristics, and the organic light-emitting device may be a delayed fluorescence photosensitive type hyperfluorescence device:

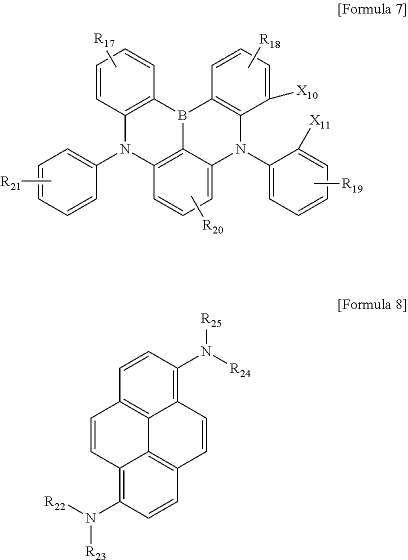

where X₁₀ to X₁₁ each independently represent hydrogen or are mutually bonded to form a ring; Rig to R₂₁ are each independently selected from hydrogen, deuterium, —F, —Cl, —Br, —I, a hydroxyl group, a cyano group, a nitro group, an amino group, an amidino group, a hydrazino group, a hydrazono group, a substituted group or unsubstituted C₁ to C₆₀ alkyl group, a substituted or unsubstituted C₂ to C₆₀ alkenyl group, a substituted or unsubstituted C₂ to C₆₀ alkynyl group, a substituted or unsubstituted C₁ to C₆₀ alkoxy group, a substituted or unsubstituted C₃ to C₁₀ cycloalkyl group, a substituted or unsubstituted C₂ to C₁₀ heterocycloalkyl group, a substituted or unsubstituted C₃ to C₁₀ cycloalkenyl group, a substituted or unsubstituted C₂ to C₁₀ heterocycloalkenyl group, a substituted or unsubstituted C₆ to C₆₀ aryl group, a substituted or unsubstituted C₆ to C₆₀ aryloxy group, a substituted or unsubstituted C₆ to C₆₀ arylthio group, a substituted or unsubstituted C₁ to C₆₀ heteroaryl group, a substituted or unsubstituted C₁ to C₆₀ heteroaryloxy group, a substituted or unsubstituted monovalent non-aromatic condensed polycyclic group, and a substituted or unsubstituted monovalent non-aromatic heterocondensed polycyclic group, R₂₂ to R₂₅ are each independently selected from hydrogen, deuterium, —F, —Cl, —Br, —I, a hydroxyl group, a cyano group, a nitro group, an amino group, an amidino group, a hydrazino group, a hydrazono group, a substituted or unsubstituted C₁ to C₆₀ alkyl group, a substituted or unsubstituted C₂ to C₆₀ alkenyl group, a substituted or unsubstituted C₂ to C₆₀ alkynyl group, a substituted or unsubstituted C₁ to C₆₀ alkoxy group, a substituted or unsubstituted C₃ to C₁₀ cycloalkyl group, a substituted or unsubstituted C₂ to C₁₀ heterocycloalkyl group, a substituted or unsubstituted C₃ to C₁₀ cycloalkenyl group, a substituted or unsubstituted C₂ to C₁₀ heterocycloalkenyl group, a substituted or unsubstituted C₆ to C₆₀ aryl group, a substituted or unsubstituted C₆ to C₆₀ aryloxy group, a substituted or unsubstituted C₆ to C₆₀ arylthio group, a substituted or unsubstituted C₁ to C₆₀ heteroaryl group, a substituted or unsubstituted C₁ to C₆₀ heteroaryloxy group, a substituted or unsubstituted monovalent non-aromatic condensed polycyclic group and a substituted or unsubstituted monovalent non-aromatic heterocondensed polycyclic group.

Among the above descriptions, the unsubstituted functional group may be composed of carbon and hydrogen, except for structures in which a specific functional group is essential, and the substituted functional group represents an unsubstituted functional group in which at least one carbon atom is substituted with an atom other than carbon. Examples of such substituted atoms include nitrogen, sulfur, oxygen, silicon, and halogen elements, but are not limited thereto.

In an example, the organic light-emitting device may be a delayed fluorescence organic light-emitting diode with excellent lifetime characteristics because the light-emitting layer includes the first compound which is a delayed fluorescent dopant vulnerable to electrons, and the second compound which is an N-type host that has excellent electron transport ability and is resistant to electrons by including at least one nitrogen atom on a benzene ring resonance structure or a cyanide group (—CN).

In another example, the organic light-emitting device may be a hyperfluorescence organic light-emitting diode having a narrow full width at half maximum, excellent color purity and lifespan because the light-emitting layer includes the third compound which has fluorescence or delayed fluorescence characteristics in a delayed fluorescence photosensitive type hyperfluorescence device in addition to the above-described first compound and second compound. The first compound acts as a type of host to form excitons, and these excitons migrate to the third compound to emit light, thereby realizing hyperfluorescent properties.

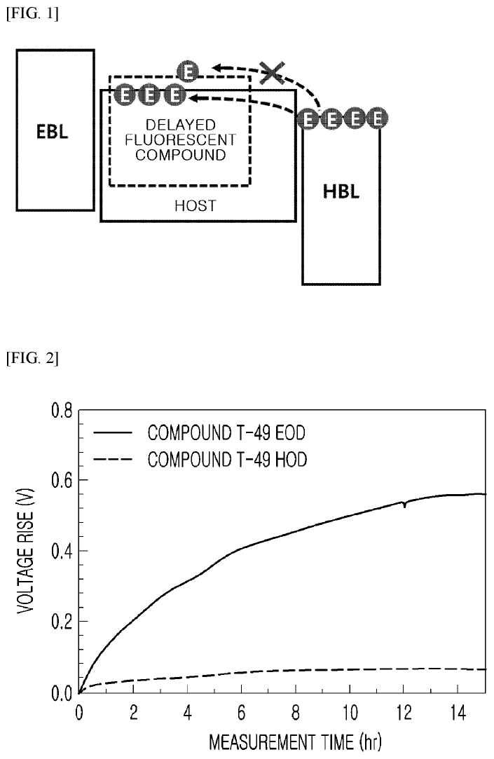

Referring to FIG. 1 showing an example of an electron transfer mechanism of the organic light-emitting device, the electron movement path may pass through the host other than Compound T-49, which is an example of a dopant vulnerable to electrons. Accordingly, lifetime characteristics may be improved compared to the related art.

For example, the first compound may have a structure of one of the following Compounds T-1 to T-82, but is not limited thereto:

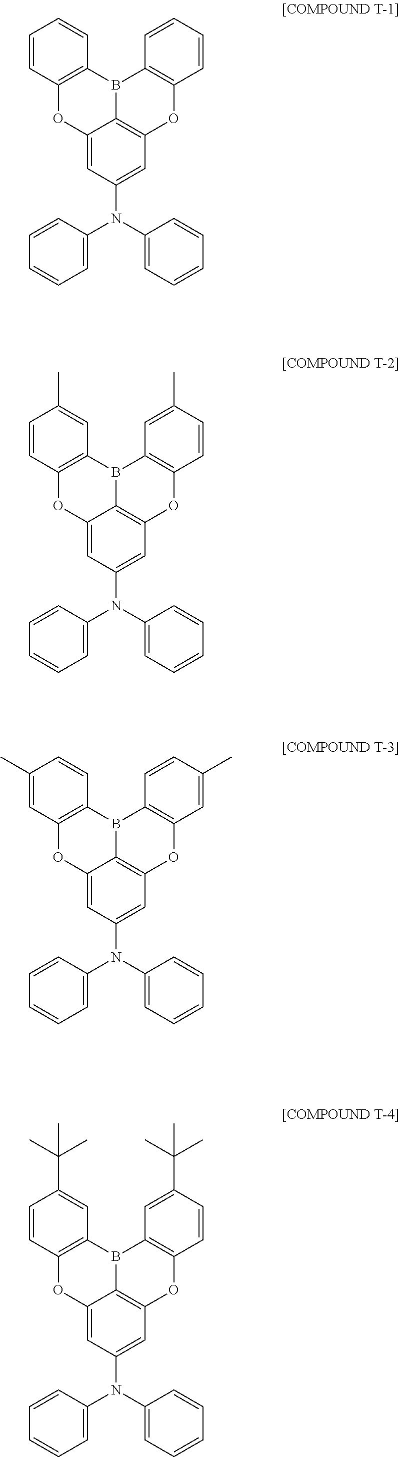

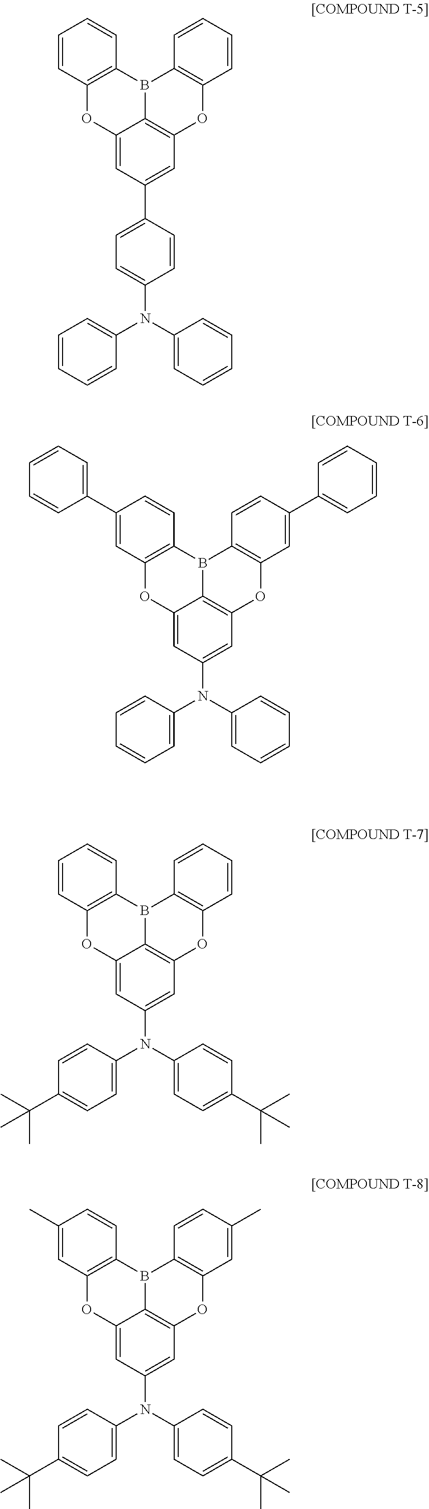

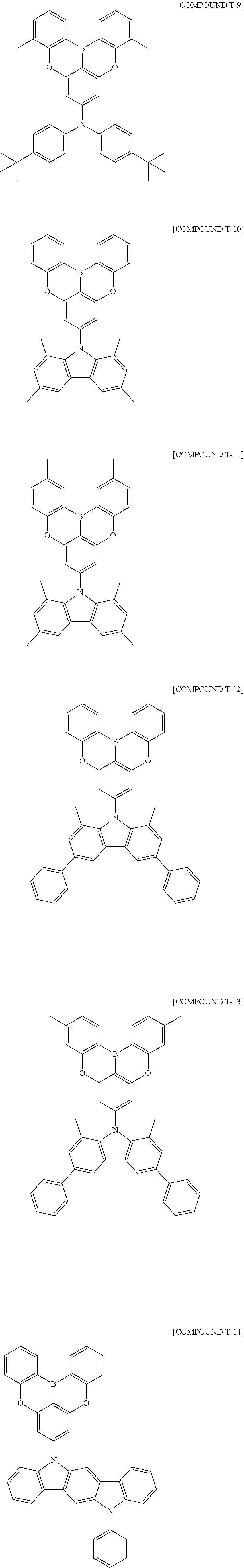

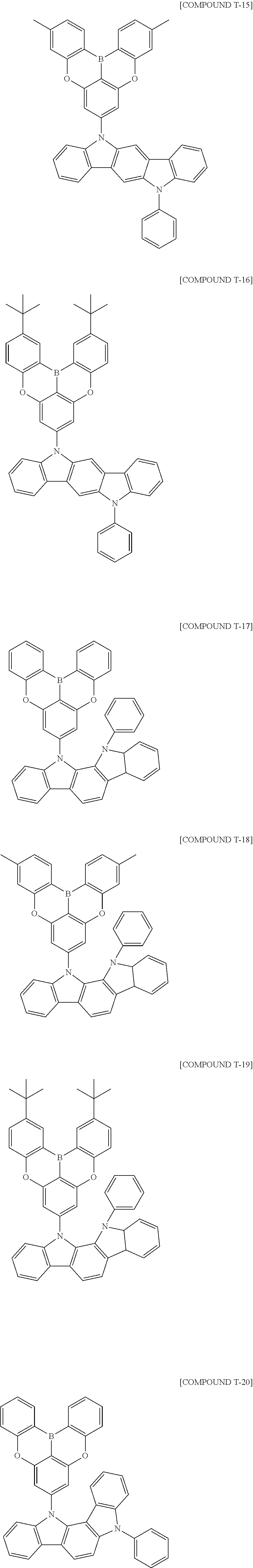

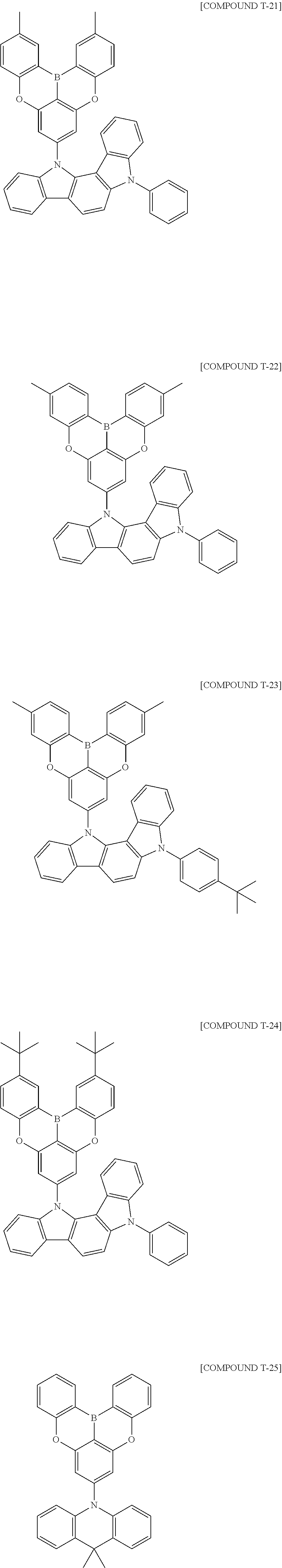 [SMILES: Cc1ccc2c(c1)B1c3cc(C)ccc3Oc3cc(-n4c5ccccc5c5ccc6c(c7ccccc7n6-c6ccccc6)c54)cc(c31)O2 ; Cc1ccc2c(c1)Oc1cc(-n3c4ccccc4c4ccc5c(c6ccccc6n5-c5ccccc5)c43)cc3c1B2c1ccc(C)cc1O3 ; Cc1ccc2c(c1)Oc1cc(-n3c4ccccc4c4ccc5c(c6ccccc6n5-c5ccc(C(C)(C)C)cc5)c43)cc3c1B2c1ccc(C)cc1O3 ; CC(C)(C)c1ccc2c(c1)B1c3cc(C(C)(C)C)ccc3Oc3cc(-n4c5ccccc5c5ccc6c(c7ccccc7n6-c6ccccc6)c54)cc(c31)O2 ; CC1(C)c2ccccc2N(c2cc3c4c(c2)Oc2ccccc2B4c2ccccc2O3)c2ccccc21]

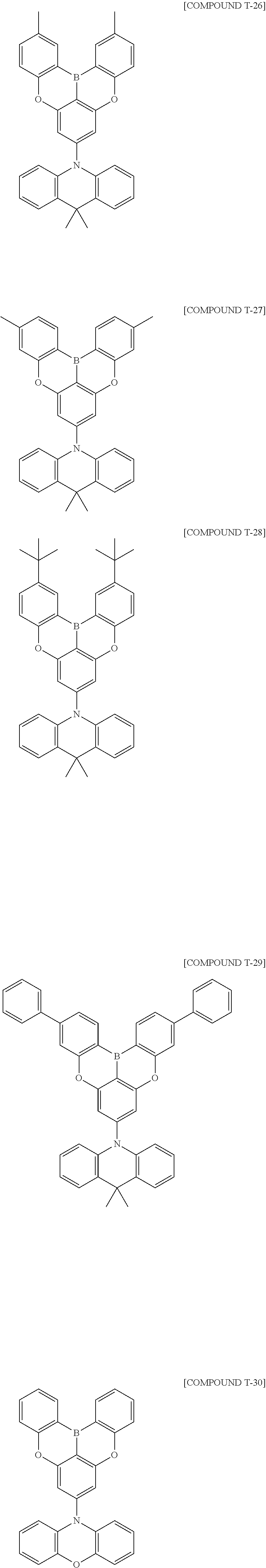

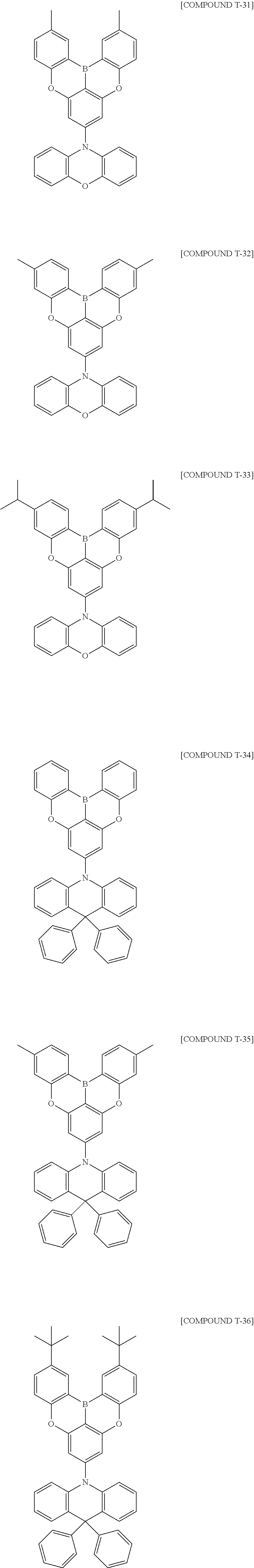

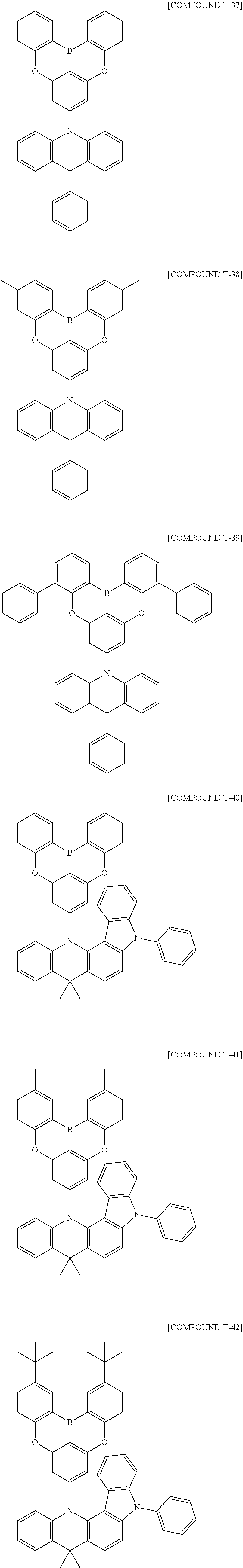

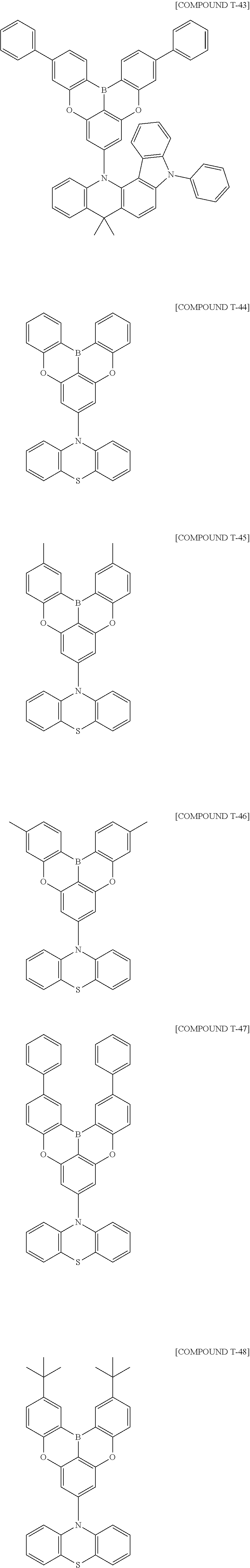

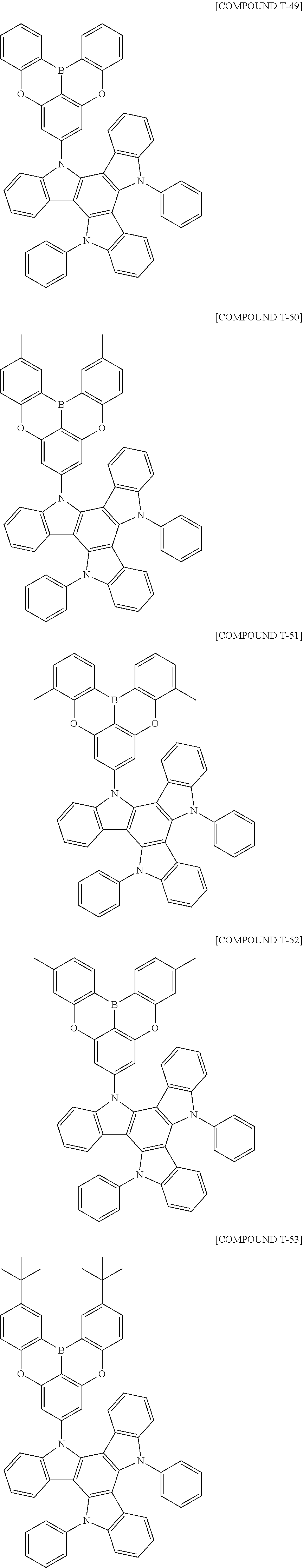

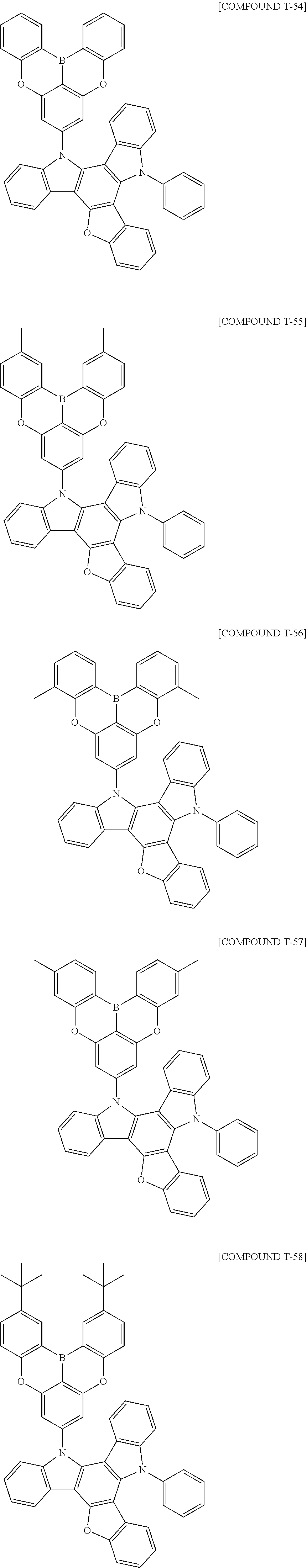 [SMILES: c1ccc(-n2c3ccccc3c3c4c(c5ccccc5n4-c4cc5c6c(c4)Oc4ccccc4B6c4ccccc4O5)c4oc5ccccc5c4c32)cc1 ; Cc1ccc2c(c1)B1c3cc(C)ccc3Oc3cc(-n4c5ccccc5c5c6oc7ccccc7c6c6c(c7ccccc7n6-c6ccccc6)c54)cc(c31)O2 ; Cc1cccc2c1Oc1cc(-n3c4ccccc4c4c5oc6ccccc6c5c5c(c6ccccc6n5-c5ccccc5)c43)cc3c1B2c1cccc(C)c1O3 ; Cc1ccc2c(c1)Oc1cc(-n3c4ccccc4c4c5oc6ccccc6c5c5c(c6ccccc6n5-c5ccccc5)c43)cc3c1B2c1ccc(C)cc1O3 ; CC(C)(C)c1ccc2c(c1)B1c3cc(C(C)(C)C)ccc3Oc3cc(-n4c5ccccc5c5c6oc7ccccc7c6c6c(c7ccccc7n6-c6ccccc6)c54)cc(c31)O2]

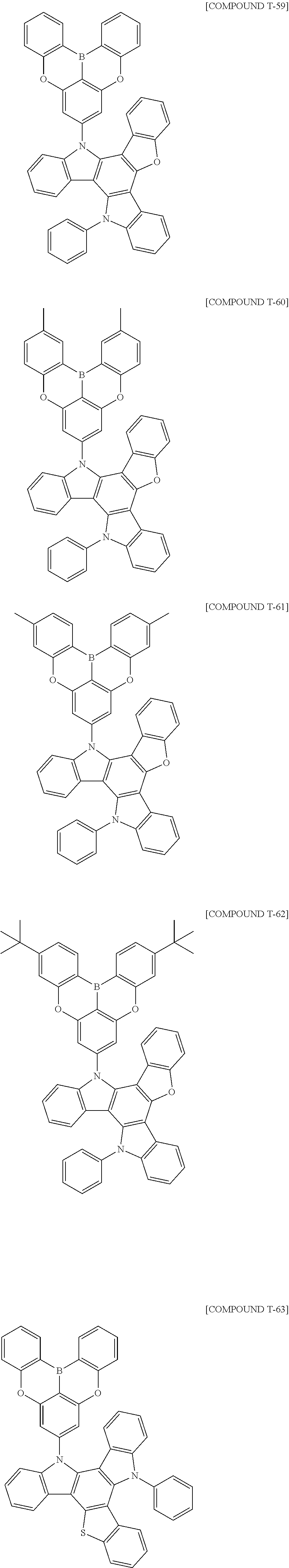 [SMILES: c1ccc(-n2c3ccccc3c3c4oc5ccccc5c4c4c(c5ccccc5n4-c4cc5c6c(c4)Oc4ccccc4B6c4ccccc4O5)c32)cc1 ; Cc1ccc2c(c1)B1c3cc(C)ccc3Oc3cc(-n4c5ccccc5c5c6c(c7ccccc7n6-c6ccccc6)c6oc7ccccc7c6c54)cc(c31)O2 ; Cc1ccc2c(c1)Oc1cc(-n3c4ccccc4c4c5c(c6ccccc6n5-c5ccccc5)c5oc6ccccc6c5c43)cc3c1B2c1ccc(C)cc1O3 ; CC(C)(C)c1ccc2c(c1)Oc1cc(-n3c4ccccc4c4c5c(c6ccccc6n5-c5ccccc5)c5oc6ccccc6c5c43)cc3c1B2c1ccc(C(C)(C)C)cc1O3 ; c1ccc(-n2c3ccccc3c3c4c(c5ccccc5n4-c4cc5c6c(c4)Oc4ccccc4B6c4ccccc4O5)c4sc5ccccc5c4c32)cc1]

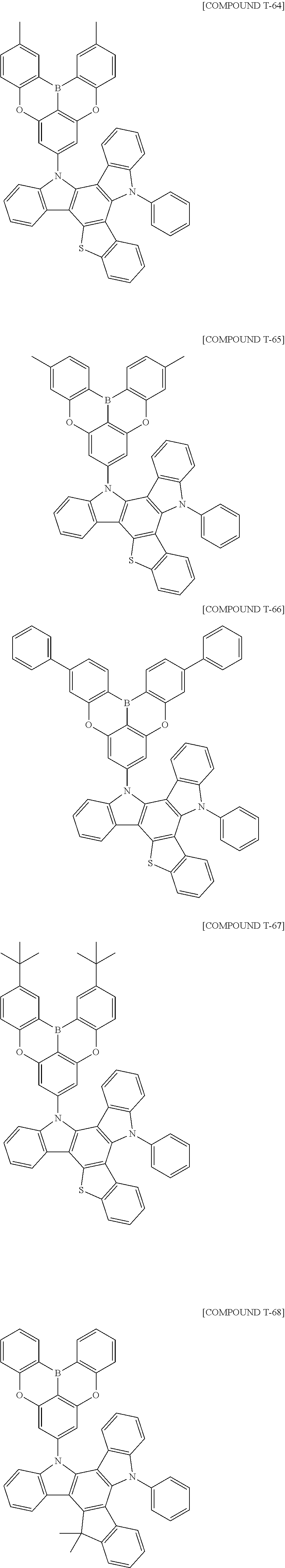

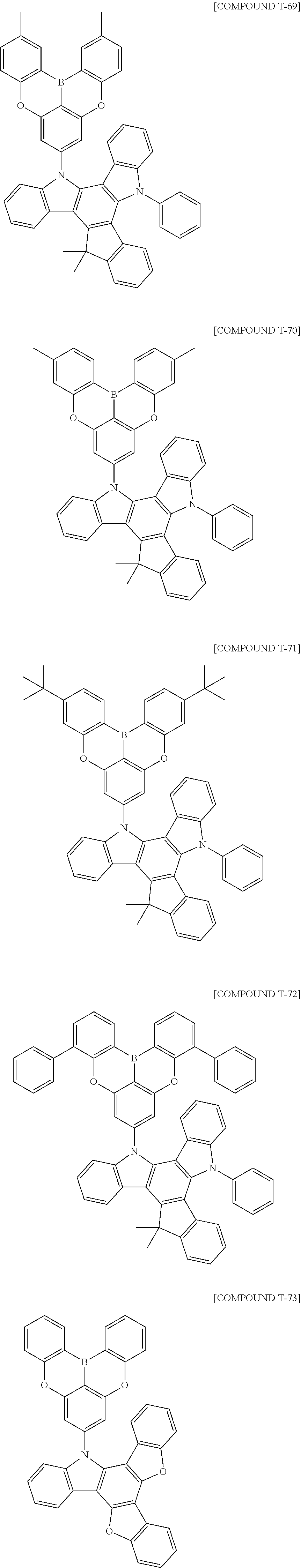

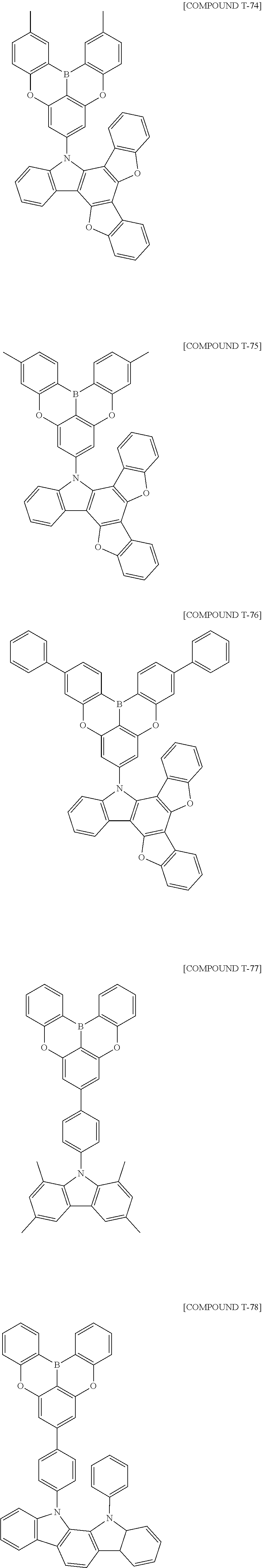

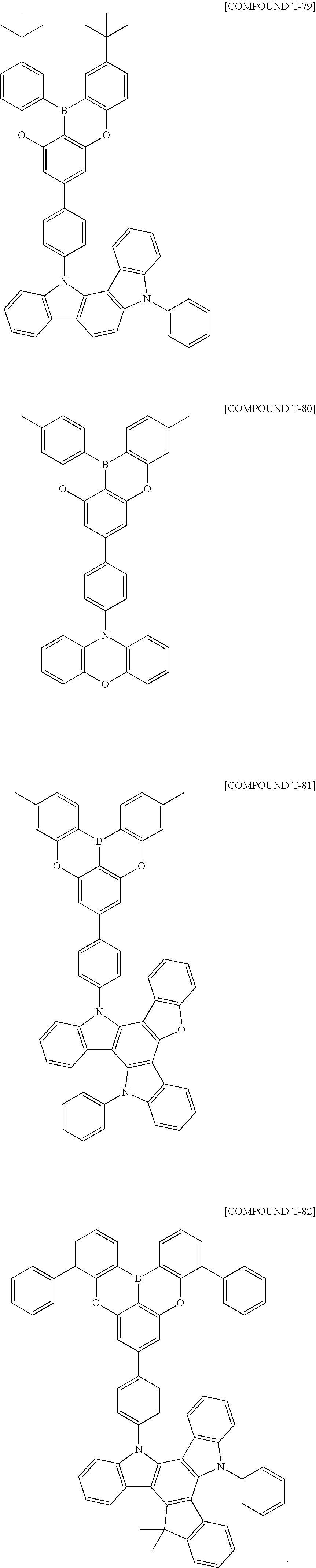

Compounds T-1 to T-82 may have delayed fluorescence characteristics because BO-structured acceptors and various donors are composed of C—N bonds. The C—N bond may be relatively vulnerable to electrons to cause inferior lifetime characteristics, but the lifetime characteristics may be remarkably improved by combining with the second compound, which is the above-described N-type host.

For example, the second compound may have a structure of one of the following Compounds H-1 to H-35, but is not limited thereto:

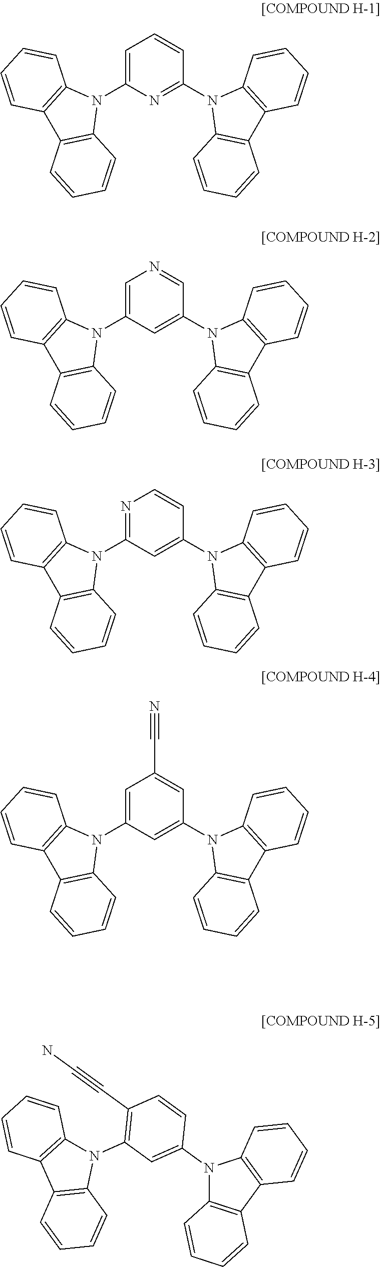 [SMILES: c1cc(-n2c3ccccc3c3ccccc32)nc(-n2c3ccccc3c3ccccc32)c1 ; c1ccc2c(c1)c1ccccc1n2-c1cncc(-n2c3ccccc3c3ccccc32)c1 ; c1ccc2c(c1)c1ccccc1n2-c1ccnc(-n2c3ccccc3c3ccccc32)c1 ; N#Cc1cc(-n2c3ccccc3c3ccccc32)cc(-n2c3ccccc3c3ccccc32)c1 ; NC#Cc1ccc(-n2c3ccccc3c3ccccc32)cc1-n1c2ccccc2c2ccccc21]

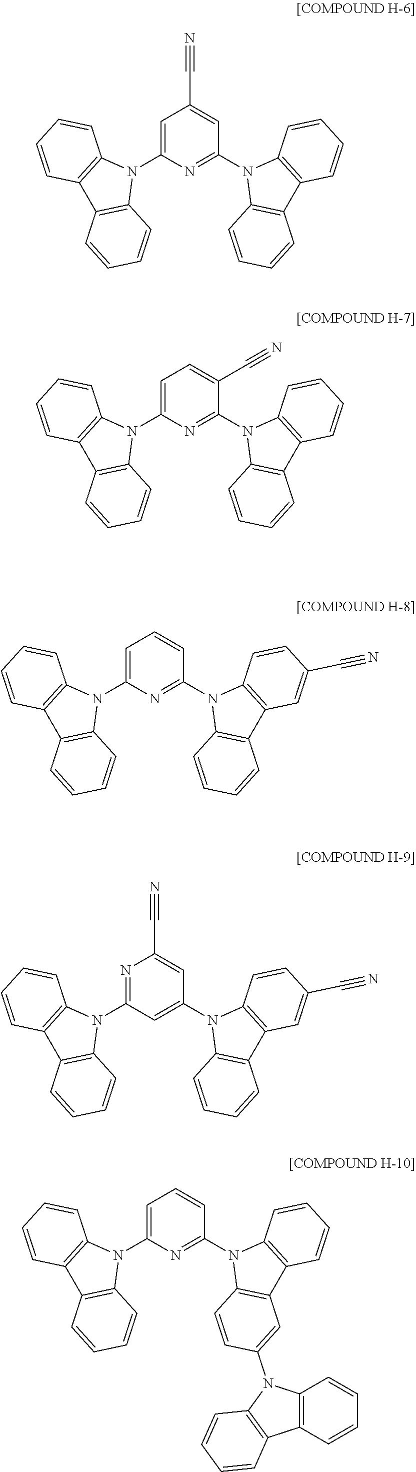 [SMILES: N#Cc1cc(-n2c3ccccc3c3ccccc32)nc(-n2c3ccccc3c3ccccc32)c1 ; N#Cc1ccc(-n2c3ccccc3c3ccccc32)nc1-n1c2ccccc2c2ccccc21 ; N#Cc1ccc2c(c1)c1ccccc1n2-c1cccc(-n2c3ccccc3c3ccccc32)n1 ; N#Cc1ccc2c(c1)c1ccccc1n2-c1cc(C#N)nc(-n2c3ccccc3c3ccccc32)c1 ; c1cc(-n2c3ccccc3c3ccccc32)nc(-n2c3ccccc3c3cc(-n4c5ccccc5c5ccccc54)ccc32)c1]

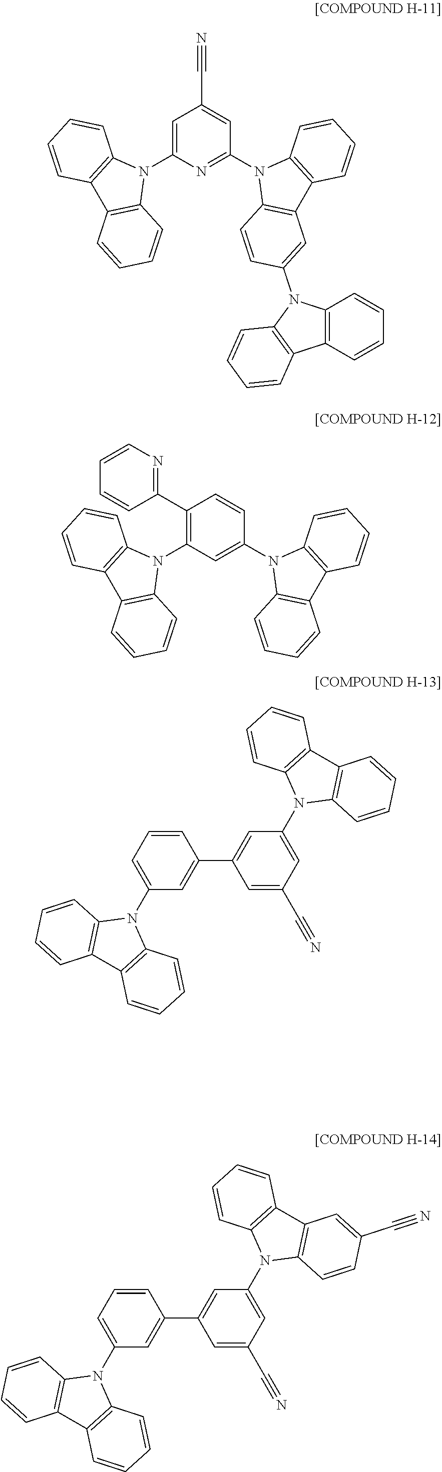 [SMILES: N#Cc1cc(-n2c3ccccc3c3ccccc32)nc(-n2c3ccccc3c3cc(-n4c5ccccc5c5ccccc54)ccc32)c1 ; c1ccc(-c2ccc(-n3c4ccccc4c4ccccc43)cc2-n2c3ccccc3c3ccccc32)nc1 ; N#Cc1cc(-c2cccc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

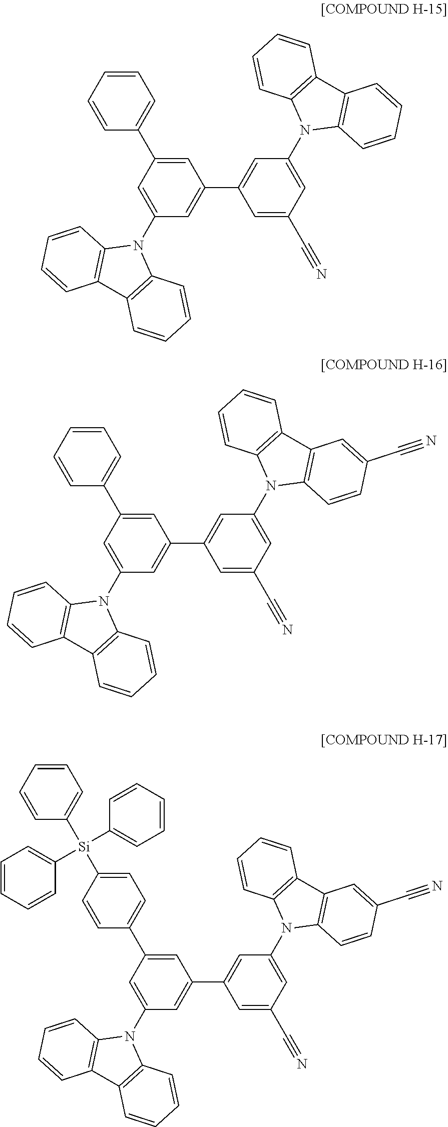 [SMILES: N#Cc1cc(-c2cc(-c3ccccc3)cc(-n3c4ccccc4c4ccccc43)c2)cc(-n2c3ccccc3c3ccccc32)c1 ; N#Cc1cc(-c2cc(-c3ccccc3)cc(-n3c4ccccc4c4ccccc43)c2)cc(-n2c3ccccc3c3cc(C#N)ccc32)c1 ; N#Cc1cc(-c2cc(-c3ccc([Si](c4ccccc4)(c4ccccc4)c4ccccc4)cc3)cc(-n3c4ccccc4c4ccccc43)c2)cc(-n2c3ccccc3c3cc(C#N)ccc32)c1]

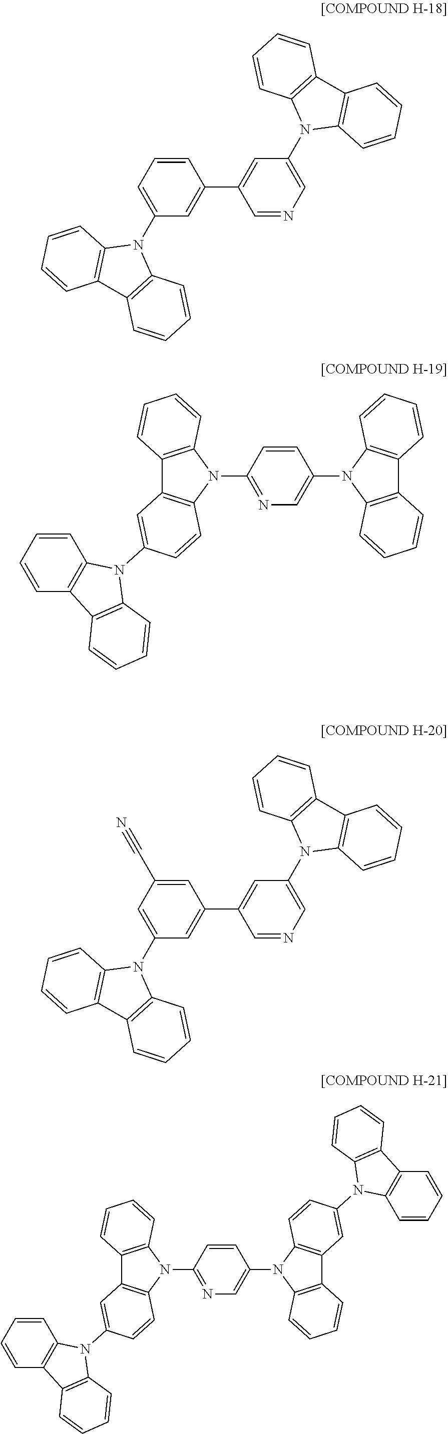 [SMILES: c1cc(-c2cncc(-n3c4ccccc4c4ccccc43)c2)cc(-n2c3ccccc3c3ccccc32)c1 ; c1ccc2c(c1)c1ccccc1n2-c1ccc(-n2c3ccccc3c3cc(-n4c5ccccc5c5ccccc54)ccc32)nc1 ; N#Cc1cc(-c2cncc(-n3c4ccccc4c4ccccc43)c2)cc(-n2c3ccccc3c3ccccc32)c1 ; c1ccc2c(c1)c1ccccc1n2-c1ccc2c(c1)c1ccccc1n2-c1ccc(-n2c3ccccc3c3cc(-n4c5ccccc5c5ccccc54)ccc32)nc1]

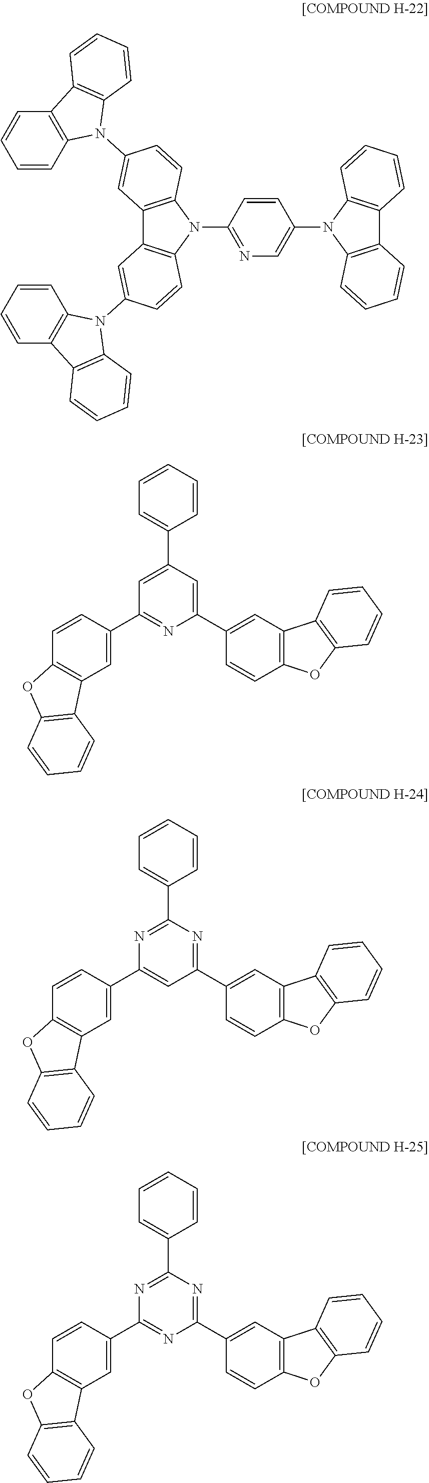 [SMILES: c1ccc2c(c1)c1ccccc1n2-c1ccc(-n2c3ccc(-n4c5ccccc5c5ccccc54)cc3c3cc(-n4c5ccccc5c5ccccc54)ccc32)nc1 ; c1ccc(-c2cc(-c3ccc4oc5ccccc5c4c3)nc(-c3ccc4oc5ccccc5c4c3)c2)cc1 ; c1ccc(-c2nc(-c3ccc4oc5ccccc5c4c3)cc(-c3ccc4oc5ccccc5c4c3)n2)cc1 ; c1ccc(-c2nc(-c3ccc4oc5ccccc5c4c3)nc(-c3ccc4oc5ccccc5c4c3)n2)cc1]

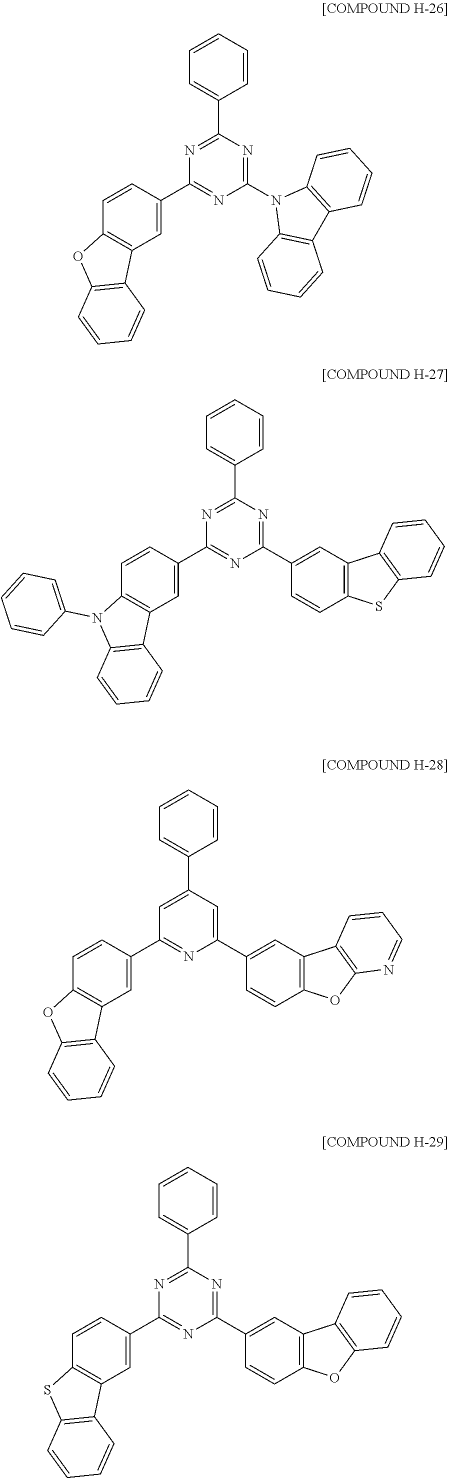 [SMILES: c1ccc(-c2nc(-c3ccc4oc5ccccc5c4c3)nc(-n3c4ccccc4c4ccccc43)n2)cc1 ; c1ccc(-c2nc(-c3ccc4sc5ccccc5c4c3)nc(-c3ccc4c(c3)c3ccccc3n4-c3ccccc3)n2)cc1 ; c1ccc(-c2cc(-c3ccc4oc5ccccc5c4c3)nc(-c3ccc4oc5ncccc5c4c3)c2)cc1 ; c1ccc(-c2nc(-c3ccc4oc5ccccc5c4c3)nc(-c3ccc4sc5ccccc5c4c3)n2)cc1]

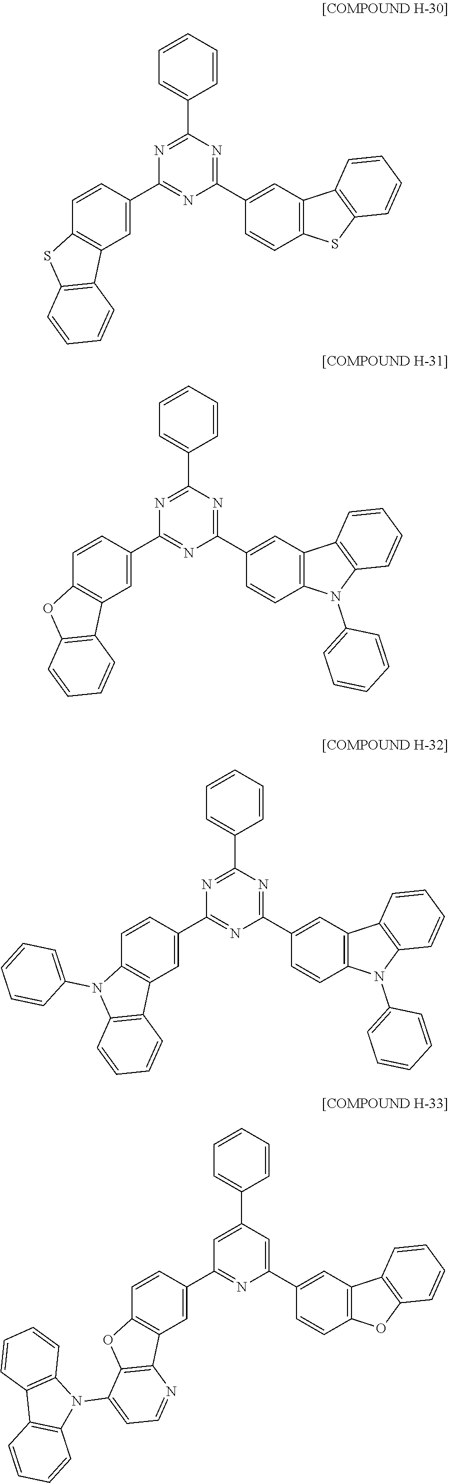 [SMILES: c1ccc(-c2nc(-c3ccc4sc5ccccc5c4c3)nc(-c3ccc4sc5ccccc5c4c3)n2)cc1 ; c1ccc(-c2nc(-c3ccc4oc5ccccc5c4c3)nc(-c3ccc4c(c3)c3ccccc3n4-c3ccccc3)n2)cc1 ; c1ccc(-c2nc(-c3ccc4c(c3)c3ccccc3n4-c3ccccc3)nc(-c3ccc4c(c3)c3ccccc3n4-c3ccccc3)n2)cc1 ; c1ccc(-c2cc(-c3ccc4oc5ccccc5c4c3)nc(-c3ccc4oc5c(-n6c7ccccc7c7ccccc76)ccnc5c4c3)c2)cc1]

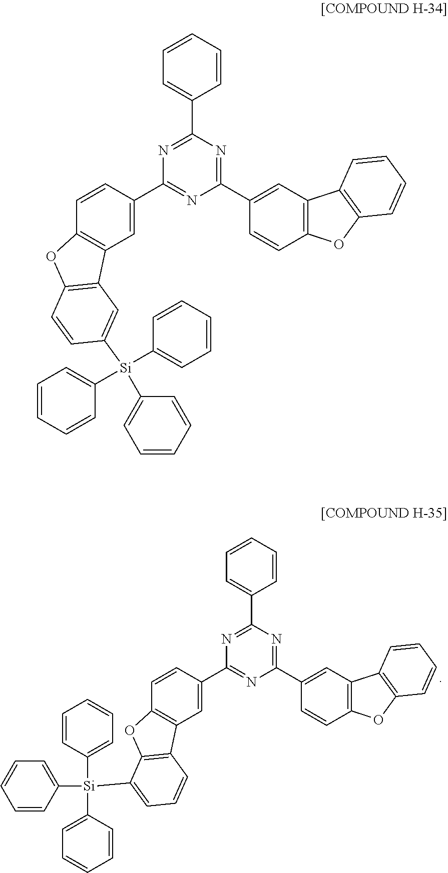 [SMILES: c1ccc(-c2nc(-c3ccc4oc5ccccc5c4c3)nc(-c3ccc4oc5ccc([Si](c6ccccc6)(c6ccccc6)c6ccccc6)cc5c4c3)n2)cc1 ; c1ccc(-c2nc(-c3ccc4oc5ccccc5c4c3)nc(-c3ccc4oc5c([Si](c6ccccc6)(c6ccccc6)c6ccccc6)cccc5c4c3)n2)cc1]

Compounds H-1 to H-35 are examples of the above-described N-type host, and have excellent electron transport ability to improve the lifespan of a dopant compound that is vulnerable to electrons.

For example, the third compound may have a structure of one of the following Compounds F-1 to F-51, but is not limited thereto:

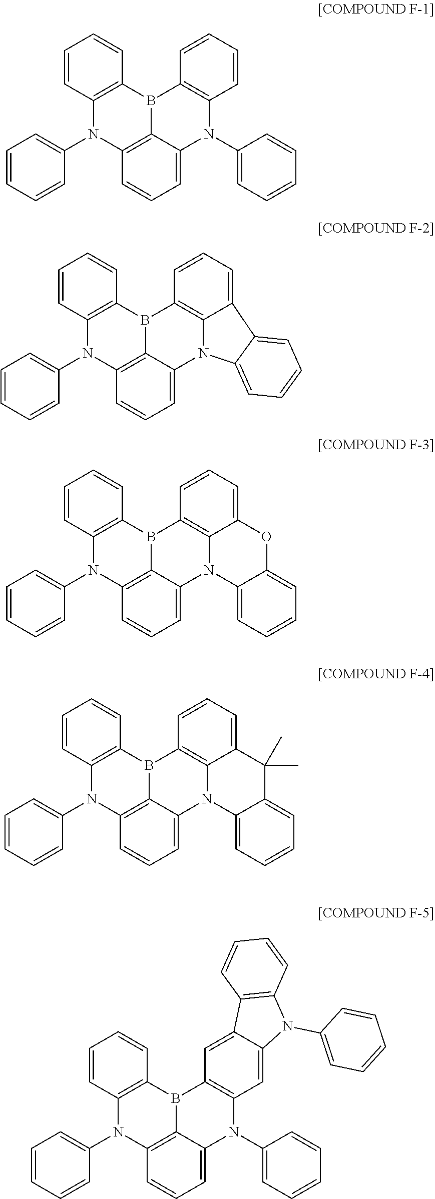 [SMILES: c1ccc(N2c3ccccc3B3c4ccccc4N(c4ccccc4)c4cccc2c43)cc1 ; c1ccc(N2c3ccccc3B3c4c2cccc4-n2c4ccccc4c4cccc3c42)cc1 ; c1ccc(N2c3ccccc3B3c4cccc5c4N(c4ccccc4O5)c4cccc2c43)cc1 ; CC1(C)c2ccccc2N2c3cccc4c3B(c3ccccc3N4c3ccccc3)c3cccc1c32 ; c1ccc(N2c3ccccc3B3c4cc5c6ccccc6n(-c6ccccc6)c5cc4N(c4ccccc4)c4cccc2c43)cc1]

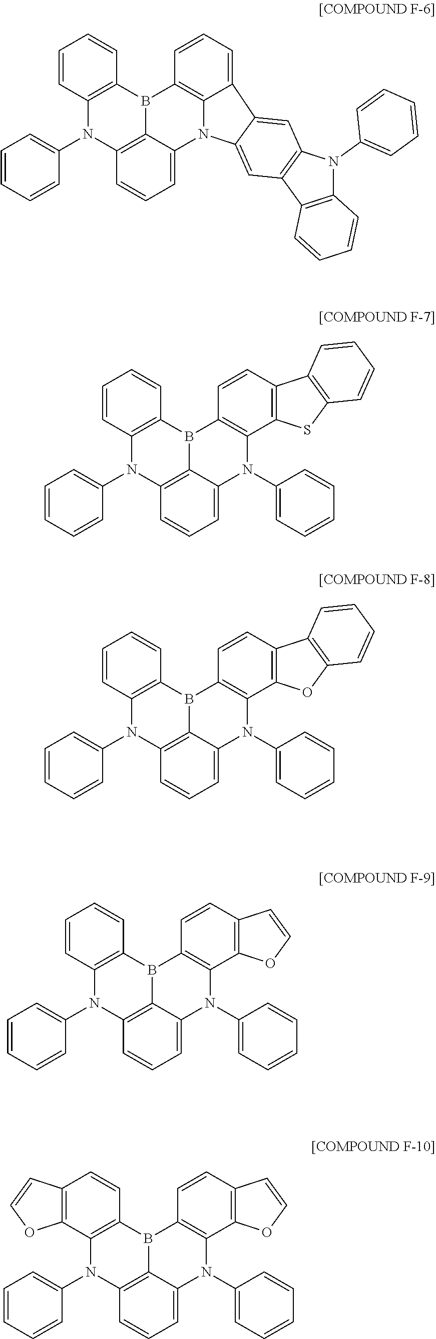 [SMILES: c1ccc(N2c3ccccc3B3c4c2cccc4-n2c4cc5c6ccccc6n(-c6ccccc6)c5cc4c4cccc3c42)cc1 ; c1ccc(N2c3ccccc3B3c4ccc5c(sc6ccccc65)c4N(c4ccccc4)c4cccc2c43)cc1 ; c1ccc(N2c3ccccc3B3c4ccc5c(oc6ccccc65)c4N(c4ccccc4)c4cccc2c43)cc1 ; c1ccc(N2c3ccccc3B3c4ccc5ccoc5c4N(c4ccccc4)c4cccc2c43)cc1 ; c1ccc(N2c3cccc4c3B(c3ccc5ccoc5c32)c2ccc3ccoc3c2N4c2ccccc2)cc1]

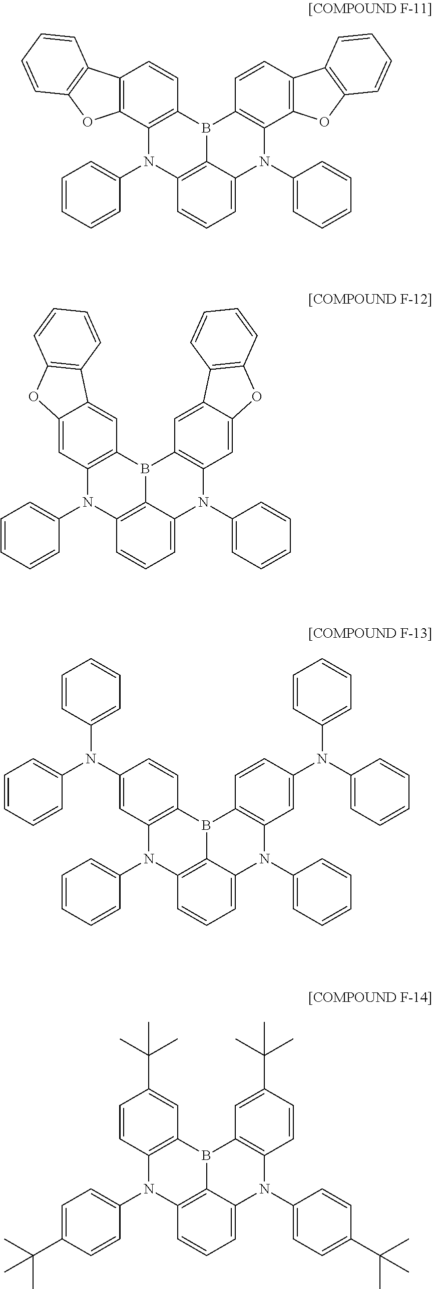 [SMILES: c1ccc(N2c3cccc4c3B(c3ccc5c(oc6ccccc65)c32)c2ccc3c(oc5ccccc53)c2N4c2ccccc2)cc1 ; c1ccc(N2c3cc4oc5ccccc5c4cc3B3c4cc5c(cc4N(c4ccccc4)c4cccc2c43)oc2ccccc25)cc1 ; c1ccc(N(c2ccccc2)c2ccc3c(c2)N(c2ccccc2)c2cccc4c2B3c2ccc(N(c3ccccc3)c3ccccc3)cc2N4c2ccccc2)cc1 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1]

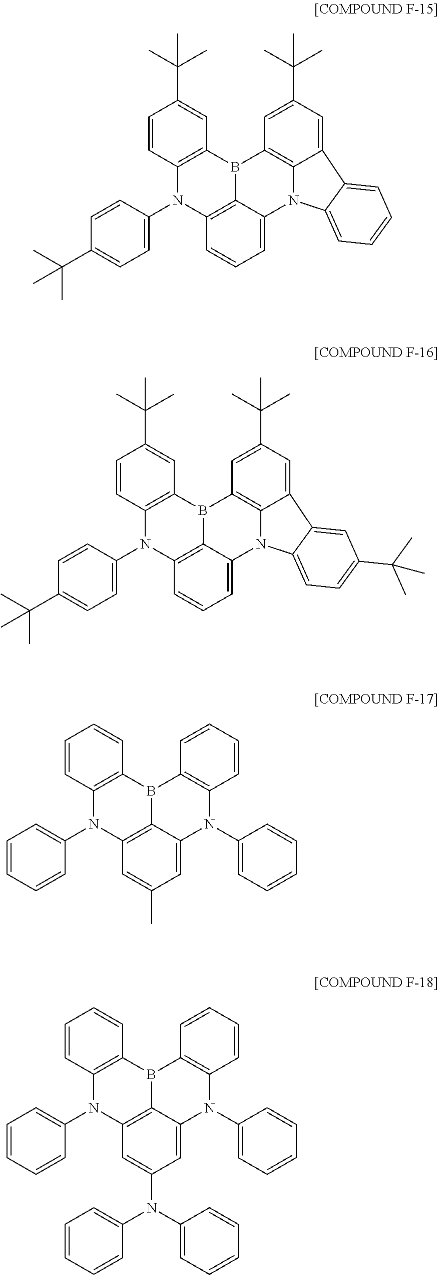 [SMILES: CC(C)(C)c1ccc(N2c3ccc(C(C)(C)C)cc3B3c4c2cccc4-n2c4ccccc4c4cc(C(C)(C)C)cc3c42)cc1 ; CC(C)(C)c1ccc(N2c3ccc(C(C)(C)C)cc3B3c4c2cccc4-n2c4ccc(C(C)(C)C)cc4c4cc(C(C)(C)C)cc3c42)cc1 ; Cc1cc2c3c(c1)N(c1ccccc1)c1ccccc1B3c1ccccc1N2c1ccccc1 ; c1ccc(N(c2ccccc2)c2cc3c4c(c2)N(c2ccccc2)c2ccccc2B4c2ccccc2N3c2ccccc2)cc1]

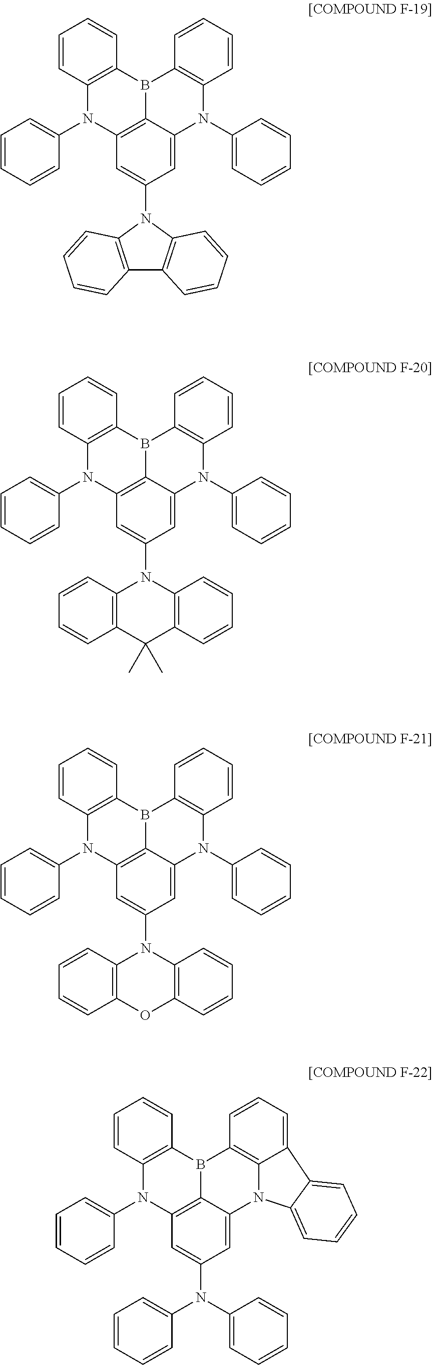 [SMILES: c1ccc(N2c3ccccc3B3c4ccccc4N(c4ccccc4)c4cc(-n5c6ccccc6c6ccccc65)cc2c43)cc1 ; CC1(C)c2ccccc2N(c2cc3c4c(c2)N(c2ccccc2)c2ccccc2B4c2ccccc2N3c2ccccc2)c2ccccc21 ; c1ccc(N2c3ccccc3B3c4ccccc4N(c4ccccc4)c4cc(N5c6ccccc6Oc6ccccc65)cc2c43)cc1 ; c1ccc(N(c2ccccc2)c2cc3c4c(c2)-n2c5ccccc5c5cccc(c52)B4c2ccccc2N3c2ccccc2)cc1]

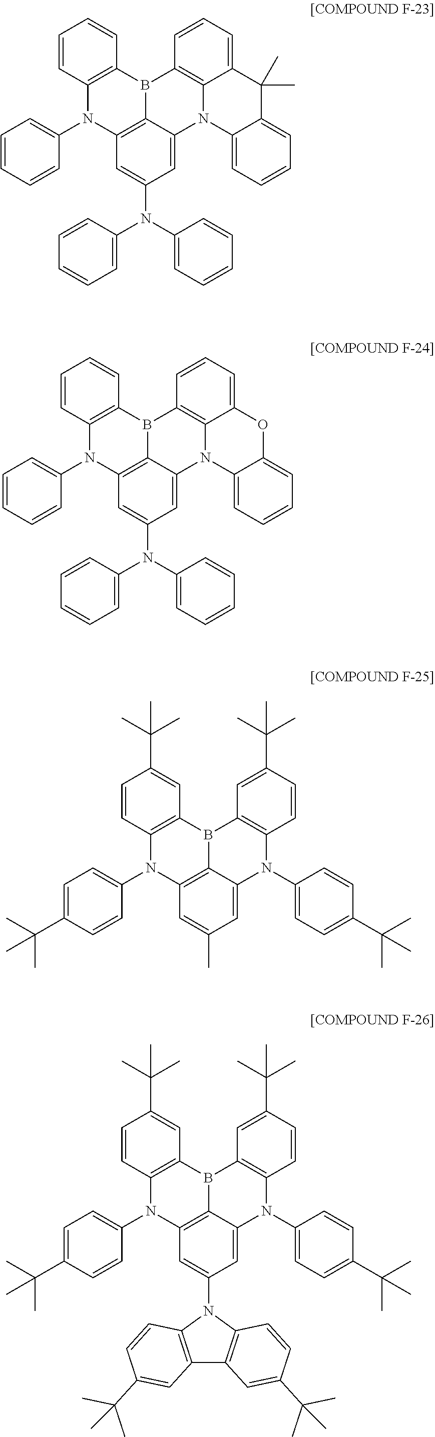

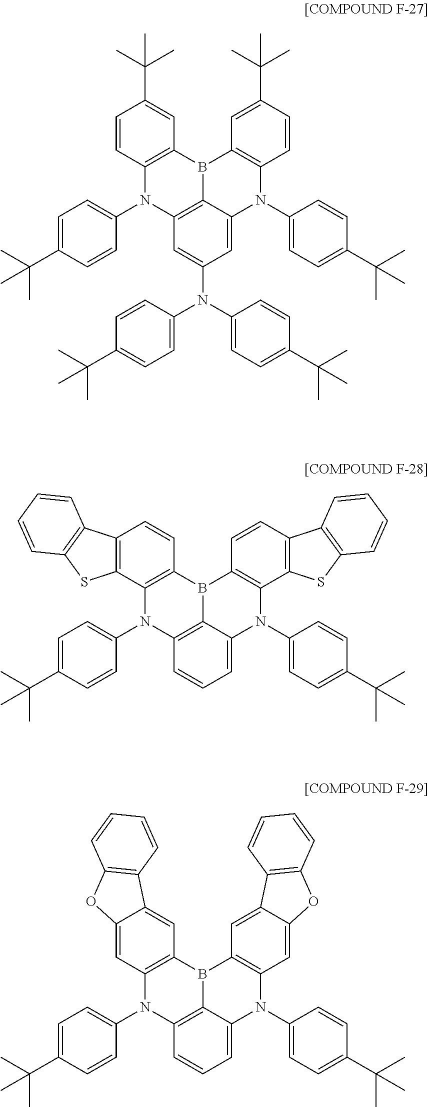

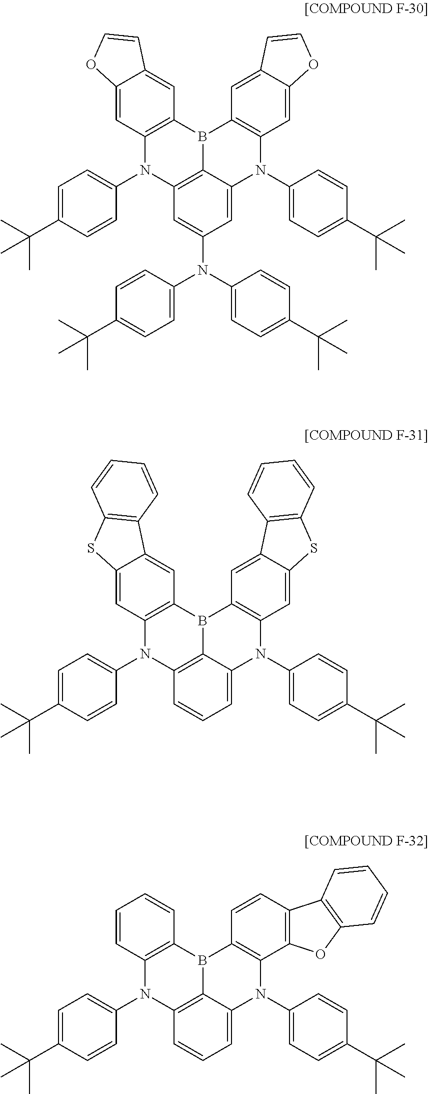

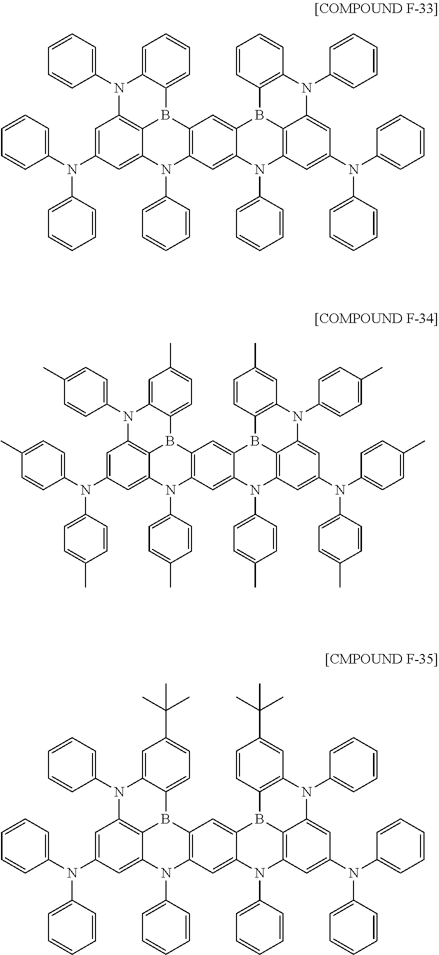

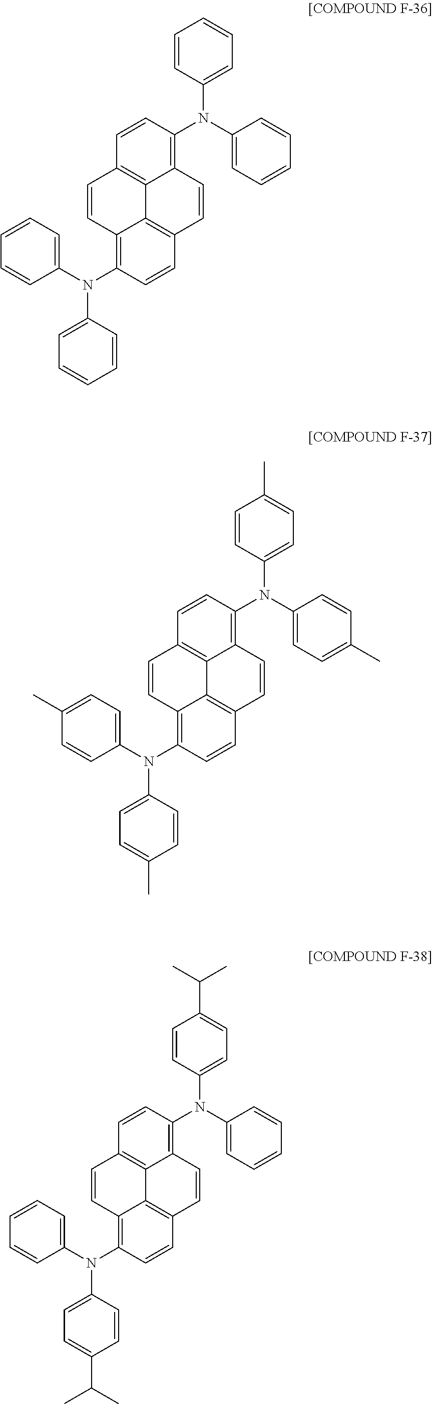

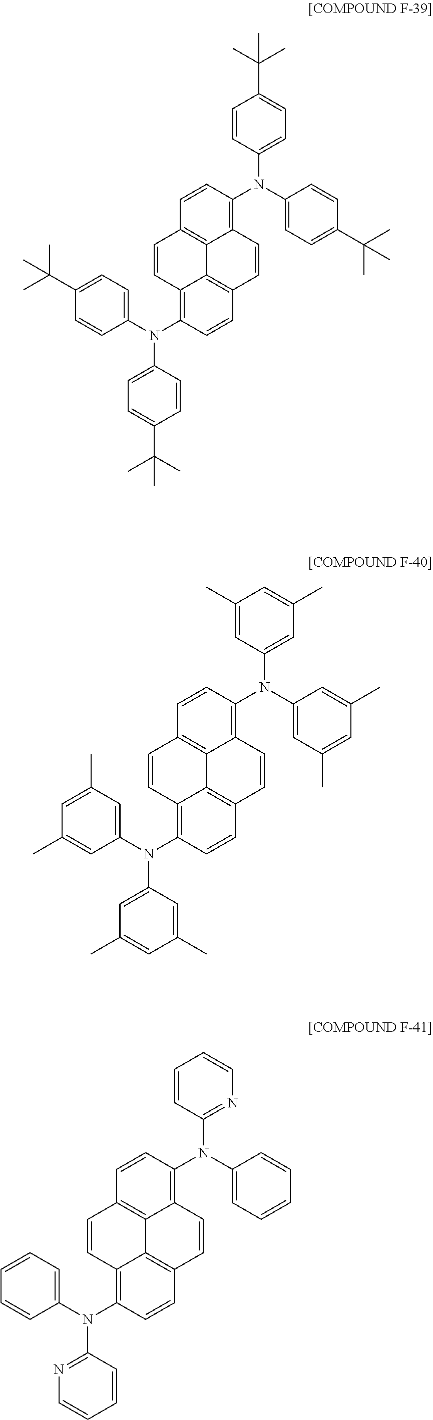

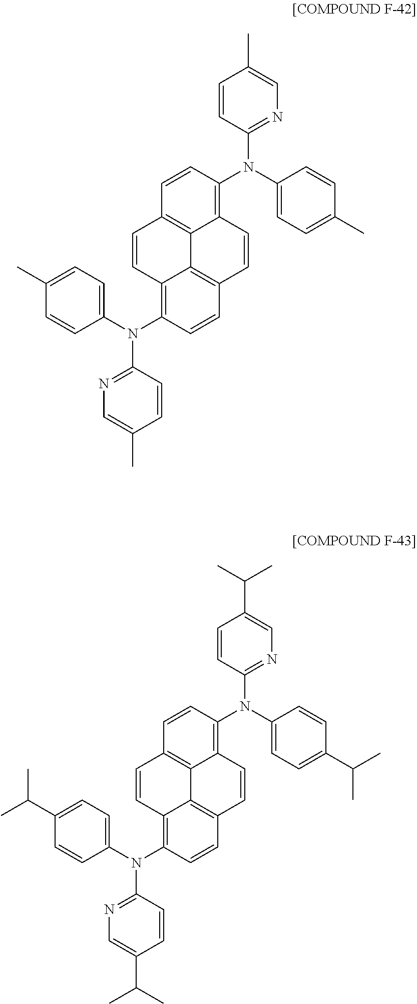

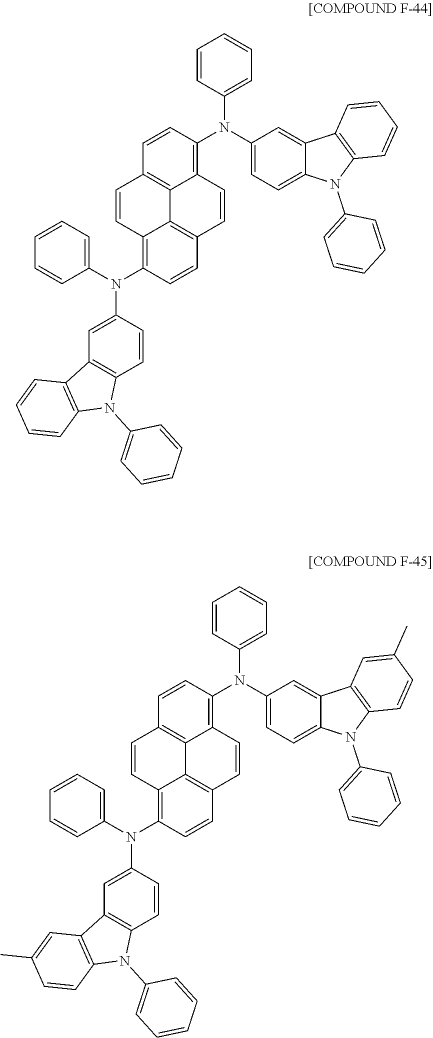 [SMILES: c1ccc(N(c2ccc3c(c2)c2ccccc2n3-c2ccccc2)c2ccc3ccc4c(N(c5ccccc5)c5ccc6c(c5)c5ccccc5n6-c5ccccc5)ccc5ccc2c3c54)cc1 ; Cc1ccc2c(c1)c1cc(N(c3ccccc3)c3ccc4ccc5c(N(c6ccccc6)c6ccc7c(c6)c6cc(C)ccc6n7-c6ccccc6)ccc6ccc3c4c65)ccc1n2-c1ccccc1]

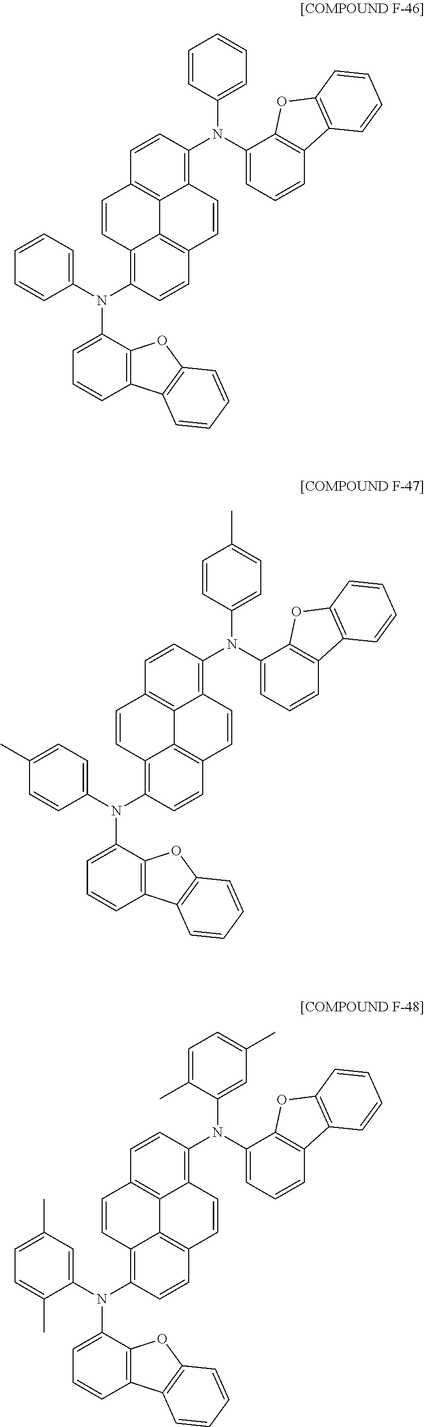 [SMILES: c1ccc(N(c2ccc3ccc4c(N(c5ccccc5)c5cccc6c5oc5ccccc56)ccc5ccc2c3c54)c2cccc3c2oc2ccccc23)cc1 ; Cc1ccc(N(c2ccc3ccc4c(N(c5ccc(C)cc5)c5cccc6c5oc5ccccc56)ccc5ccc2c3c54)c2cccc3c2oc2ccccc23)cc1 ; Cc1ccc(C)c(N(c2ccc3ccc4c(N(c5cc(C)ccc5C)c5cccc6c5oc5ccccc56)ccc5ccc2c3c54)c2cccc3c2oc2ccccc23)c1]

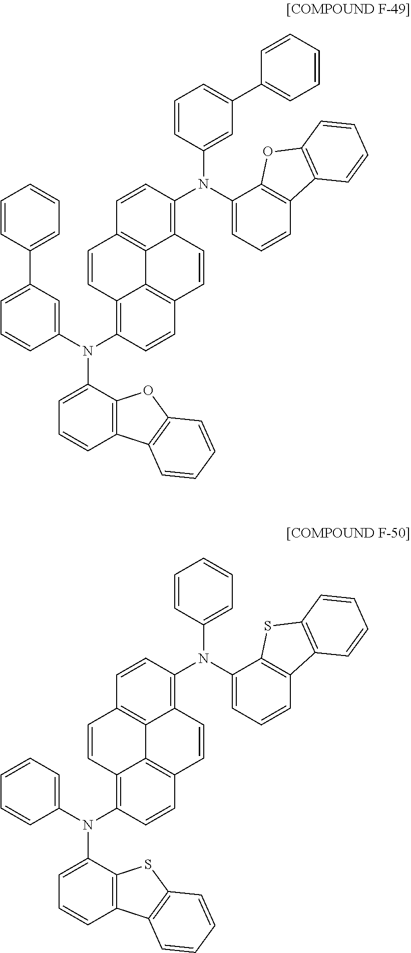 [SMILES: c1ccc(-c2cccc(N(c3ccc4ccc5c(N(c6cccc(-c7ccccc7)c6)c6cccc7c6oc6ccccc67)ccc6ccc3c4c65)c3cccc4c3oc3ccccc34)c2)cc1 ; c1ccc(N(c2ccc3ccc4c(N(c5ccccc5)c5cccc6c5sc5ccccc56)ccc5ccc2c3c54)c2cccc3c2sc2ccccc23)cc1]

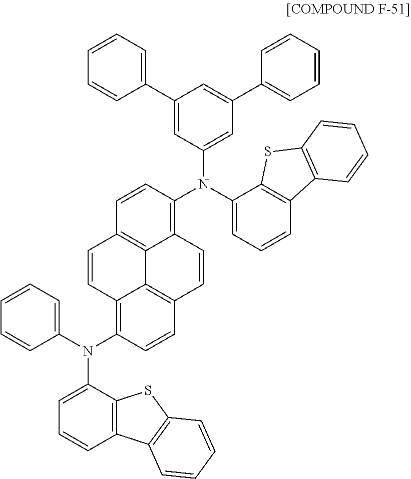 [SMILES: c1ccc(-c2cc(-c3ccccc3)cc(N(c3ccc4ccc5c(N(c6ccccc6)c6cccc7c6sc6ccccc67)ccc6ccc3c4c65)c3cccc4c3sc3ccccc34)c2)cc1]

Compounds F-1 to F-51, which are examples of the third compound, are fluorescent dopant compounds based on a DABNA structure including a BN structure or a pyrene structure, and may be used as the fluorescent dopant of the delayed fluorescence photosensitive hyperfluorescence organic light-emitting device using the first compound as a host. For example, when at least one delayed fluorescent compound among Compounds T-1 to T-82 is used as a host and at least one of Compounds F-1 to F-51 is included as a fluorescent dopant, luminescent properties may be significantly improved.

The organic light-emitting device may include a first electrode and a second electrode facing each other; and a layered structure located between the first electrode and the second electrode, and the light-emitting layer may be included in the layered structure.

The layered structure may include at least one of a hole injection layer, a hole transport layer, an exciton blocking layer, an electron transport layer and an electron injection layer.

For example, the first electrode may be an anode, the second electrode may be a cathode, and the layered structure may include: a light-emitting layer having the above characteristics; a hole transport region interposed between the first electrode and the light-emitting layer and including at least one of a hole injection layer, a hole transport layer, and an electron blocking layer; and an electron transport region interposed between the light-emitting layer and the second electrode and including at least one of a hole blocking layer, an electron transport layer, and an electron injection layer.

A substrate may be additionally disposed below the first electrode or above the second electrode. As the substrate, a substrate used in a general organic light-emitting device may be used, and a glass substrate or a transparent plastic substrate having excellent mechanical strength, thermal stability, transparency, surface smoothness, ease of handling and water resistance may be used.

The first electrode may be a reflective electrode, a transflective electrode or a transmissive electrode. The first electrode may be formed, for example, on a substrate by depositing or sputtering a material for the first electrode. The material for the first electrode may be selected from materials having a high work function to facilitate hole injection, and examples of the material for the first electrode may include indium tin oxide (ITO), indium zinc oxide (IZO), tin oxide (SnO₂), zinc oxide (ZnO), magnesium (Mg), aluminum (Al), aluminum-lithium (Al—Li), calcium (Ca), magnesium-indium (Mg—In), magnesium-silver (Mg—Ag), etc.

The hole injection layer may be formed on the first electrode using various methods such as a vacuum deposition method, a spin coating method, a cast method, an LB method and the like. When the hole injection layer is formed by the vacuum deposition method, deposition conditions vary depending on the compound used as a material for the hole injection layer, the desired structure and thermal characteristics of the hole injection layer and the like, but for example, the deposition temperature may be in the range of about 100° C. to about 500° C., a degree of vacuum may be in the range of about 10⁻⁸ to about 10⁻³ torr, and a deposition rate may be in the range of about 0.01 to about 100 Å/sec, but the present invention is not limited thereto.

When the hole injection layer is formed by the spin coating method, coating conditions vary depending on the compound used as a material for the hole injection layer, the desired structure and thermal characteristics of the hole injection layer, and a coating speed may be in the range of about 2,000 rpm to about 5,000 rpm, a heat treatment temperature for removing a solvent after coating may be in the range of about 80° C. to 200° C., but the present invention is not limited thereto.

Conditions for forming the hole transport layer and the electron blocking layer may refer to conditions for forming the hole injection layer.

Each layer may have a thickness in the range of about 100 to about 10,000 Å, for example, about 100 to about 1,000 Å.

When the light-emitting layer includes a host and a dopant, the content of the dopant may be typically selected from about 0.01 to about 45 parts by weight based on about 100 parts by weight of the host, but is not limited thereto.

In addition, when the light-emitting layer has hyperfluorescent emission characteristics, the delayed fluorescence host and the fluorescent dopant may be included in an amount of 0.01 to 45 parts by weight based on 100 parts by weight of the host, but is not limited thereto.

The organic light-emitting device has an LT90 lifetime of 10 hours or more at 1,000 nits, for example, 10 hours, 11 hours, 12 hours, 13 hours, 14 hours, 15 hours, 16 hours, 17 hours, 18 hours, 19 hours, 20 hours, 21 hours, 22 hours, 23 hours, 24 hours, 25 hours, 26 hours, 27 hours, 28 hours, 29 hours, 30 hours, 31 hours, 32 hours, 33 hours, 34 hours, 35 hours, 36 hours, 37 hours, 38 hours, 39 hours, 40 hours, 41 hours, 42 hours, 43 hours, 44 hours, 45 hours, 46 hours, 47 hours, 48 hours, 49 hours, hours, 51 hours, 52 hours, 53 hour, 54 hours, 55 hours, 56 hours, 57 hours, 58 hours, 59 hours, 60 hours or any value between two of the aforementioned values at 1,000 nits, but is not limited thereto.

This characteristic may result from the above-described combination of the host and dopant of the light-emitting layer.

Hereinafter, the embodiments of the present specification will be described in more detail. However, the experimental results in the following show only representative experimental results of the examples, and the scope and contents of the present disclosure cannot be construed to be reduced or limited by the examples and the like. Each effect of the various embodiments of the present disclosure not expressly set forth below will be specifically described in a relevant section.

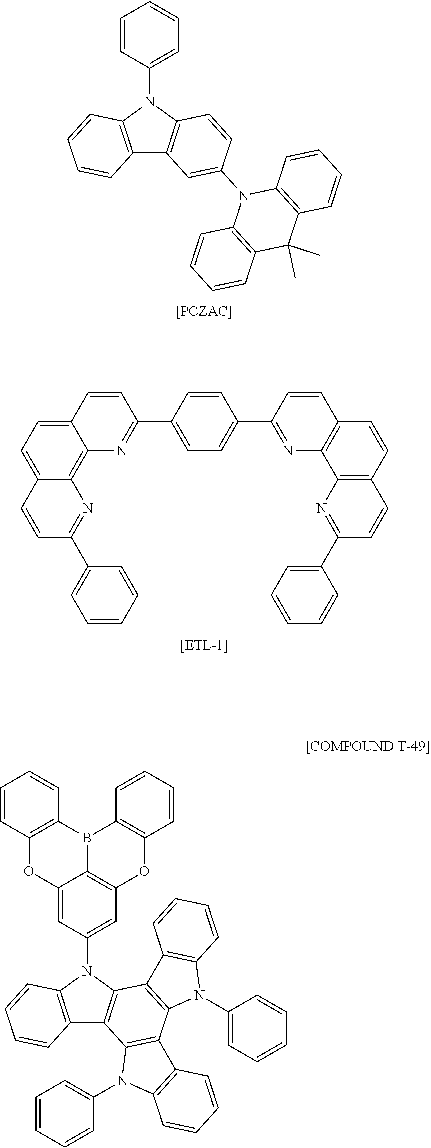 [SMILES: CC1(C)c2ccccc2N(c2ccc3c(c2)c2ccccc2n3-c2ccccc2)c2ccccc21 ; c1ccc(-c2ccc3ccc4ccc(-c5ccc(-c6ccc7ccc8ccc(-c9ccccc9)nc8c7n6)cc5)nc4c3n2)cc1 ; c1ccc(-n2c3ccccc3c3c2c2c4ccccc4n(-c4cc5c6c(c4)Oc4ccccc4B6c4ccccc4O5)c2c2c4ccccc4n(-c4ccccc4)c32)cc1]

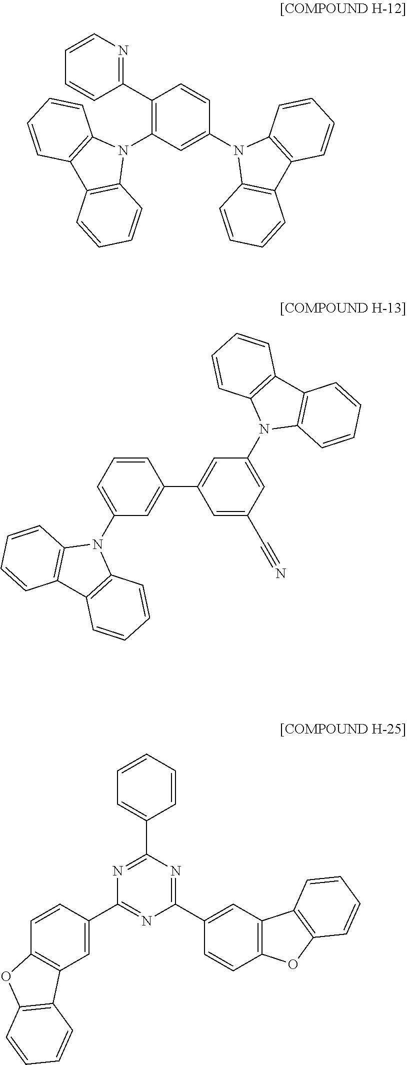 [SMILES: c1ccc(-c2ccc(-n3c4ccccc4c4ccccc43)cc2-n2c3ccccc3c3ccccc32)nc1 ; N#Cc1cc(-c2cccc(-n3c4ccccc4c4ccccc43)c2)cc(-n2c3ccccc3c3ccccc32)c1 ; c1ccc(-c2nc(-c3ccc4oc5ccccc5c4c3)nc(-c3ccc4oc5ccccc5c4c3)n2)cc1]

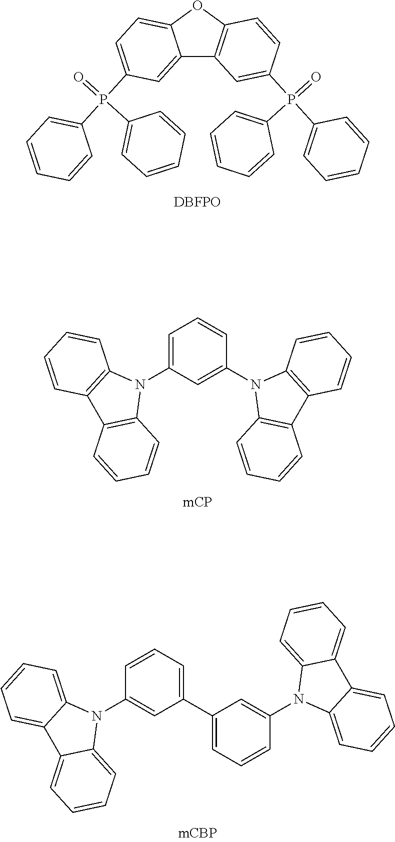

### Example 1

An ITO glass substrate was cut to a 50 mm×50 mm×0.7 mm size, washed with acetone, isopropyl alcohol, and distilled water for 10 minutes each, irradiated with ultraviolet rays for 10 minutes, exposed to ozone and cleaned, and then the ITO glass substrate was mounted in a vacuum evaporator. HATCN (7 nm)/NPB (50 nm)/PCZAC (10 nm)/Compound H-12 and 30 wt % of Compound T-49 (25 nm)/Compound H-25 (5 nm)/ETL-1 (20 nm)/LiF (1.5 nm)/Al (100 nm) were sequentially laminated on the ITO glass substrate to manufacture an organic light-emitting device. An electron movement path to which the host of the embodiment is applied is shown in FIG. 1.

### Example 2

An organic light-emitting device was manufactured in the same manner as in Example 1, except that Compound H-13 was used instead of Compound H-12.

### Example 3

An organic light-emitting device was manufactured in the same manner as in Example 1, except that Compound H-25 was used instead of Compound H-12.

### COMPARATIVE EXAMPLE 1

An organic light-emitting device was manufactured in the same manner as in Example 1, except that DBFPO was used instead of Compound H-12 as a host compound.

### Comparative Example 2

An organic light-emitting diode was manufactured in the same manner as in Example 1, except that mCP was used instead of Compound H-12 as a host compound.

### Comparative Example 3

An organic light-emitting device was manufactured in the same manner as in Example 1, except that mCBP was used instead of Compound H-12 as a host compound.

### Experimental Example 1

Each bond dissociation energy (BDE) of Compound T-49 used in Examples in neutral, anion and cation states was calculated using a simulation program Schrodinger 2019-3, and shown in the following Table 1.

TABLE 1

| 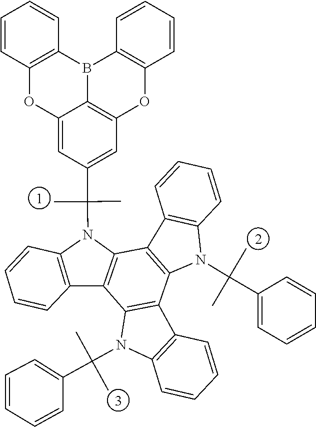 [SMILES: CC(C)(c1ccccc1)n1c2ccccc2c2c1c1c3ccccc3n(C(C)(C)c3cc4c5c(c3)Oc3ccccc3B5c3ccccc3O4)c1c1c3ccccc3n(C(C)(C)c3ccccc3)c21] | | | |
|---|---|---|---|
| Classification | \textcircled{1} | \textcircled{2} | \textcircled{3} |
| Neutral | 3.16 eV | 3.16 eV | 3.16 eV |
| Anion | 2.72 eV | 3.43 eV | 3.43 eV |
| Cation | 4.75 eV | 5.40 eV | 5.40 eV |

Referring to Table 1, it can be seen that the C—N bond connecting a donor and an acceptor is relatively weak in an anion state.

### Experimental Example 2

An electron only device (EOD) and a hole only device (HOD) were manufactured in order to compare the stability of Compound T-49 against electrons and holes.

An ITO glass substrate was cut to a 50 mm×50 mm×0.7 mm size, washed with acetone, isopropyl alcohol, and distilled water for 10 minutes each, irradiated with ultraviolet rays for 10 minutes, exposed to ozone, cleaned, and then mounted in a vacuum evaporator. ETL-1 (30 nm)/Compound T-49 (30 nm)/ETL-1 (40 nm)/LiF (1.5 nm)/Al (100 nm) were sequentially laminated on the ITO glass substrate to manufacture an EOD.

An HOD was manufactured in the same manner as the EOD, except that HATCN (7 nm)/PCZAC (40 nm)/Compound T-49 (30 nm)/PCZAC (30 nm)/Al (100 nm) were sequentially laminated on the ITO glass substrate.

The change in voltage was measured over time by applying current at a current density of 20 mA/cm 2 and shown in FIG. 2, and as a result, it was confirmed that the voltage rises rapidly in the EOD, from which it can be seen that Compound T-49 is vulnerable to electrons.

### Experimental Example 3

The LUMO energy levels of each compound used in Examples 1 to 3 and Comparative Examples 1 to 3 were compared and shown in the following Table 2.

TABLE 2

| | Comparative | Comparative | Comparative | | | |
|---|---|---|---|---|---|---|
| Classification | Example 1 | Example 2 | Example 3 | Example 1 | Example 2 | Example 3 |
| Host | DBFPO | mCP | mCBP | Compound | Compound | Compound |
| | | | | H12 | H13 | H25 |
| LUMO | 2.5 eV | 2.3 eV | 2.3 eV | 2.7 eV | 2.7 eV | 3.0 eV |

Referring to Table 2, it can be seen that the LUMO energy level of Compound T-49 used in each Example is 2.7 eV, and the difference between the LUMO energy levels between Compound T-49 and the compound used as a host in each Example is less than 0.1 eV.

### Experimental Example 4

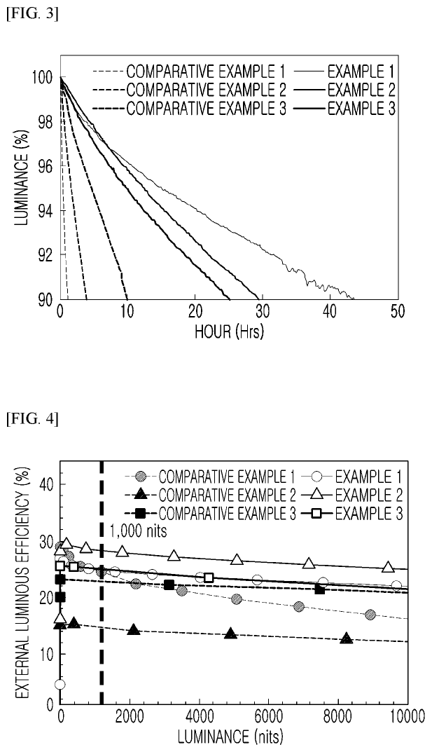

The characteristics of the organic light-emitting devices manufactured according to Examples 1 to 3 and Comparative Examples 1 to 3 were measured and are shown in the following Table 3, and FIGS. 3 and 4.

The lifetime was measured as the time from when the initial luminance was 1,000 nits until it decreased by 10%.

TABLE 3

| | | | | Lifetime | |
|---|---|---|---|---|---|
| | | | EQE | LT90 | |
| | | Maximum | (@1,000 | (@1,000 | |
| Classification | Host | EQE | nits) | nits) | |
| Comparative | DBFPO | 28.8% | 24.4% | 1.1 | hours |
| Example 1 | | | | | |
| Comparative | mCP | 15.2% | 14.5% | 3.7 | hours |
| Example 2 | | | | | |
| Comparative | mCBP | 23.7% | 22.8% | 9.9 | hours |
| Example 3 | | | | | |
| Example 1 | Compound H12 | 26.7% | 24.9% | 43.2 | hours |
| Example 2 | Compound H13 | 29.2% | 28.3% | 29.3 | hours |
| Example 3 | Compound H25 | 25.3% | 24.9% | 16.8 | hours |

Referring to Table 2, and FIGS. 3 and 4, Examples 1 to 3 to which Compounds H-12, H-13 and H-25 were applied showed an excellent lifespan compared to that of Comparative Examples 1 to 3. This is because electrons move mainly through a host with electron transport ability rather than through a Compound T-49 dopant. As confirmed in Table 2 of Experimental Example 3, this can be confirmed from the fact that the LUMO energy level of each host is similar to or lower than that of the delayed fluorescent dopant.

It can be seen that DBFPO of Comparative Example 1 is a representative host with electron transport ability, but a P═O bond is weak in an anion state, and thus a molecular bond tends to be easily broken, and mCP of Comparative Example 2 has little electron transport ability so that electrons move through a Compound T-49 dopant which is vulnerable to electrons, resulting in a relatively short lifetime. In addition, it was confirmed that mCBP of Comparative Example 3 is also composed of only carbazole with high hole transport ability and lacks electron transport ability, whereas Compound H-13 of Example 2 to which a CN group is bonded has electron transport ability and has a low LUMO energy level so that the lifespan was improved nearly three times from 10 hours to 29.3 hours.

According to these results, when an existing delayed fluorescent compound, which is vulnerable to electrons and has an inferior lifespan is used, lifespan characteristics may be significantly improved by combining an N-type host having higher bonding energy in an anion state than the dopant because the N-type host includes a pyridine group or the like having N in the resonance structure or a cyanide group (—CN).

While this specification includes specific embodiments, it will be apparent to those of ordinary skill to which this specification pertains that various changes in form and details may be made in these embodiments without departing from the spirit and scope of the claims and their equivalents. Therefore, the embodiments described herein are to be considered in a descriptive sense only, and not for purposes of limitation. For example, each component described as a single type may be implemented to be distributed and similarly, components described to be distributed may also be implemented in a combined form.

The scope of the specification is defined not by the detailed description, but by the claims and their equivalents, and all variations within the scope of the claims and their equivalents are to be construed as being included in the specification.

1. An organic light-emitting device, comprising a light-emitting layer which includes a first compound having a lowest unoccupied molecular orbital (LUMO) energy level of EL₁ and being a delayed fluorescent dopant, and a second compound having a LUMO energy level of EL₂ and being a host, and which satisfies |EL₁|−|EL₂|≤0.2 eV, wherein the binding energy of the first compound in an anion state is lower than the binding energy of the second compound in an anion state.

2. The organic light-emitting device according to claim 1, wherein
the first compound is represented by a structure of the following Formula 1: 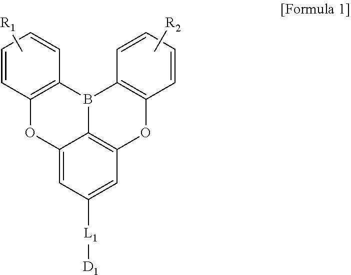
in Formula 1, D₁ is represented by one of the following Formulas 2 to 4, 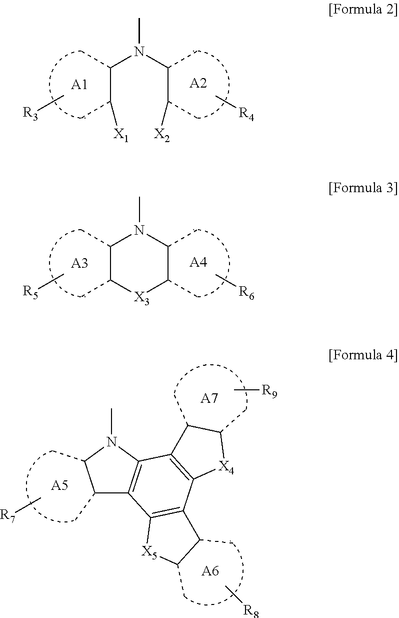
wherein A₁ to A₇ each independently represent a ring structure selected from a substituted or unsubstituted C₅ to C₆₀ carbocyclic group or a substituted or unsubstituted C₂ to C₆₀ heterocyclic group;
L₁ is a single bond or C₆ to C₆₀ arylene;
X₁ and X₂ each represent hydrogen or are mutually bonded to form a ring,
X₃ is O, N—R₂₆, S or C—(R₂₇)₂;
X₄ and X₅ each independently represent O, N—R₂₈, S or C—(R₂₉)₂;
R₁ to R₉ are each independently selected from hydrogen, deuterium, —F, —Cl, —Br, —I, a hydroxyl group, a cyano group, a nitro group, an amino group, an amidino group, a hydrazino group, a hydrazono group, a substituted or unsubstituted C₁ to C₆₀ alkyl group, a substituted or unsubstituted C₂ to C₆₀ alkenyl group, a substituted or unsubstituted C₂ to C₆₀ alkynyl group, a substituted or unsubstituted C₁ to C₆₀ alkoxy group, a substituted or unsubstituted C₃ to C₁₀ cycloalkyl group, a substituted or unsubstituted C₂ to C₁₀ heterocycloalkyl group, a substituted or unsubstituted C₃ to C₁₀ cycloalkenyl group, a substituted or unsubstituted C₂ to C₁₀ heterocycloalkenyl group, a substituted or unsubstituted C₆ to C₆₀ aryl group, a substituted or unsubstituted C₆ to C₆₀ aryloxy group, a substituted or unsubstituted C₆ to C₆₀ arylthio group, a substituted or unsubstituted C₁ to C₆₀ heteroaryl group, a substituted or unsubstituted C₁ to C₆₀ heteroaryloxy group, a substituted or unsubstituted monovalent non-aromatic condensed polycyclic group and a substituted or unsubstituted monovalent non-aromatic heterocondensed polycyclic group; and
R₂₆ to R₂₉ are each independently selected from hydrogen, deuterium, a C₁ to C₆₀ alkyl group, a C₃ to C₁₀ cycloalkyl group, a C₆ to C₆₀ aryl group, or a C₁ to C₆₀ heteroaryl group.

3. The organic light-emitting device according to claim 1, wherein
the second compound is represented by a structure selected from the following Formulas 5 and 6: 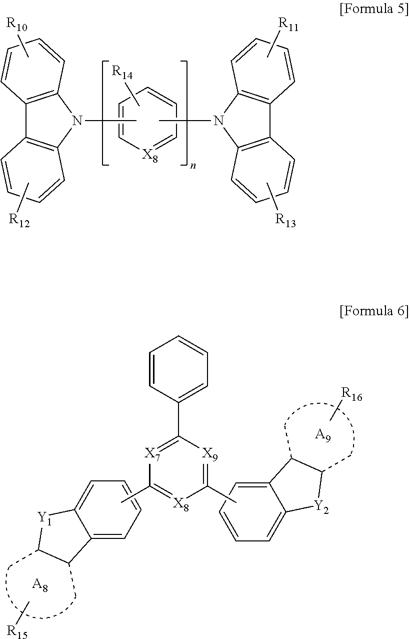
wherein A₈ to A₉ each independently represent a ring structure selected from a substituted or unsubstituted C₅ to C₆₀ carbocyclic group or a C₂ to C₆₀ heterocyclic group;
X₆ is N or C—H;
X₇ to X₉ are each independently selected from N or C—H and at least one of X₇ to X₉ is N, Y₁ to Y₂ are each independently selected from N—R₃₀, O or S;
R₁₀ to R₁₄ are each independently selected from hydrogen, deuterium, a silyl group, a cyano group, a C₁ to C₆₀ alkyl group, a C₃ to C₁₀ cycloalkyl group, a C₆ to C₆₀ aryl group, a C₁ to C₆₀ heteroaryl group, a C₆ to C₃₀ diarylamino group, a C₂ to C₄₀ diheteroarylamino group, and a C₁₀ to C₄₀ arylheteroarylamino group;
R₁₅ to R₁₆ are each independently selected from hydrogen, deuterium, a silyl group, a cyano group, a C₁ to C₆₀ alkyl group, a C₃ to C₁₀ cycloalkyl group, a C₆ to C₆₀ aryl group, a C₁ to C₆₀ heteroaryl group, a C₆ to C₃₀ diarylamino group, a C₂ to C₄₀ diheteroarylamino group, and a C₁₀ to C₄₀ arylheteroarylamino group;
R₃₀ is selected from hydrogen, deuterium, a C₁ to C₆₀ alkyl group, a C₃ to C₁₀ cycloalkyl group, a C₆ to C₆₀ aryl group, or a C₁ to C₆₀ heteroaryl group;
n is 1 or 2; and
the compound of Formula 5 or 6 includes at least one nitrogen-containing benzene or benzene to which a cyano group is bonded.

4. The organic light-emitting device according to claim 1, wherein the light-emitting layer is represented by a structure selected from the following Formulas 7 and 8 and further includes a third compound having fluorescence or delayed fluorescence characteristics, and
the organic light-emitting device is a delayed fluorescence photosensitive hyperfluorescence device: 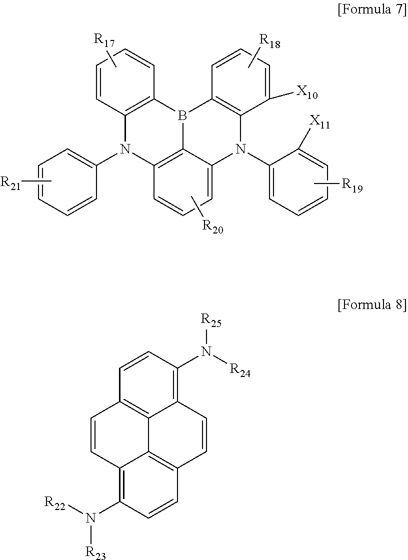
wherein X₁₀ to X₁₁ each independently represent hydrogen or are mutually bonded to form a ring;
R₁₇ to R₂₁ are each independently selected from hydrogen, deuterium, —F, —Cl, —Br, —I, a hydroxyl group, a cyano group, a nitro group, an amino group, an amidino group, a hydrazino group, a hydrazono group, a substituted group or unsubstituted C₁ to C₆₀ alkyl group, a substituted or unsubstituted C₂ to C₆₀ alkenyl group, a substituted or unsubstituted C₂ to C₆₀ alkynyl group, a substituted or unsubstituted C₁ to C₆₀ alkoxy group, a substituted or unsubstituted C₃ to C₁₀ cycloalkyl group, a substituted or unsubstituted C₂ to C₁₀ heterocycloalkyl group, a substituted or unsubstituted C₃ to C₁₀ cycloalkenyl group, a substituted or unsubstituted C₂ to C₁₀ heterocycloalkenyl group, a substituted or unsubstituted C₆ to C₆₀ aryl group, a substituted or unsubstituted C₆ to C₆₀ aryloxy group, a substituted or unsubstituted C₆ to C₆₀ arylthio group, a substituted or unsubstituted C₁ to C₆₀ heteroaryl group, a substituted or unsubstituted C₁ to C₆₀ heteroaryloxy group, a substituted or unsubstituted monovalent non-aromatic condensed polycyclic group, and a substituted or unsubstituted monovalent non-aromatic heterocondensed polycyclic group,
R₂₂ to R₂₅ are each independently selected from hydrogen, deuterium, —F, —Cl, —Br, —I, a hydroxyl group, a cyano group, a nitro group, an amino group, an amidino group, a hydrazino group, a hydrazono group, a substituted or unsubstituted C₁ to C₆₀ alkyl group, a substituted or unsubstituted C₂ to C₆₀ alkenyl group, a substituted or unsubstituted C₂ to C₆₀ alkynyl group, a substituted or unsubstituted C₁ to C₆₀ alkoxy group, a substituted or unsubstituted C₃ to C₁₀ cycloalkyl group, a substituted or unsubstituted C₂ to C₁₀ heterocycloalkyl group, a substituted or unsubstituted C₃ to C₁₀ cycloalkenyl group, a substituted or unsubstituted C₂ to C₁₀ heterocycloalkenyl group, a substituted or unsubstituted C₆ to C₆₀ aryl group, a substituted or unsubstituted C₆ to C₆₀ aryloxy group, a substituted or unsubstituted C₆ to C₆₀ arylthio group, a substituted or unsubstituted C₁ to C₆₀ heteroaryl group, a substituted or unsubstituted C₁ to C₆₀ heteroaryloxy group, a substituted or unsubstituted monovalent non-aromatic condensed polycyclic group and a substituted or unsubstituted monovalent non-aromatic heterocondensed polycyclic group.

5. The organic light-emitting device according to claim 1, wherein the first compound has a structure of one of the following Compounds T-1 to T-82:

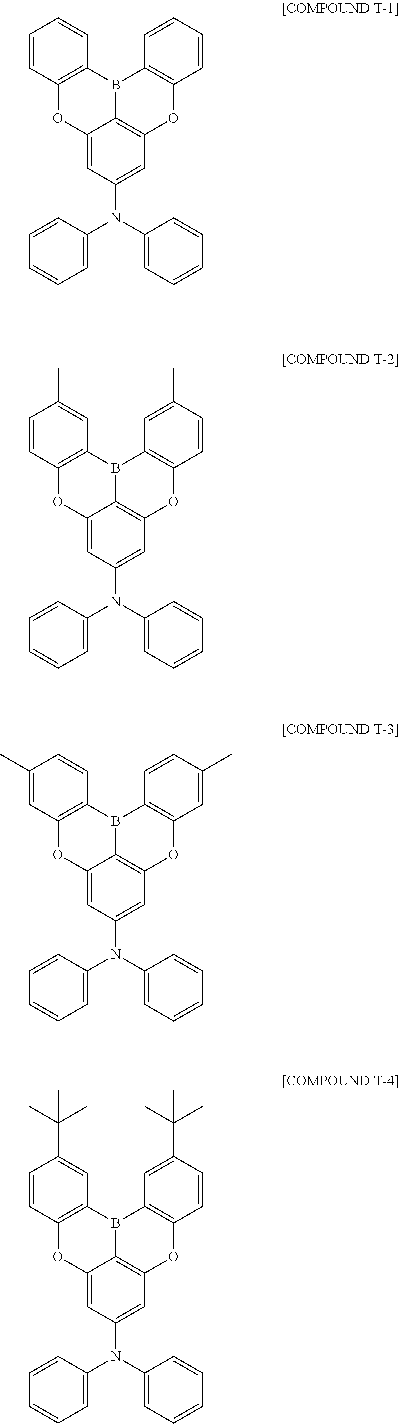

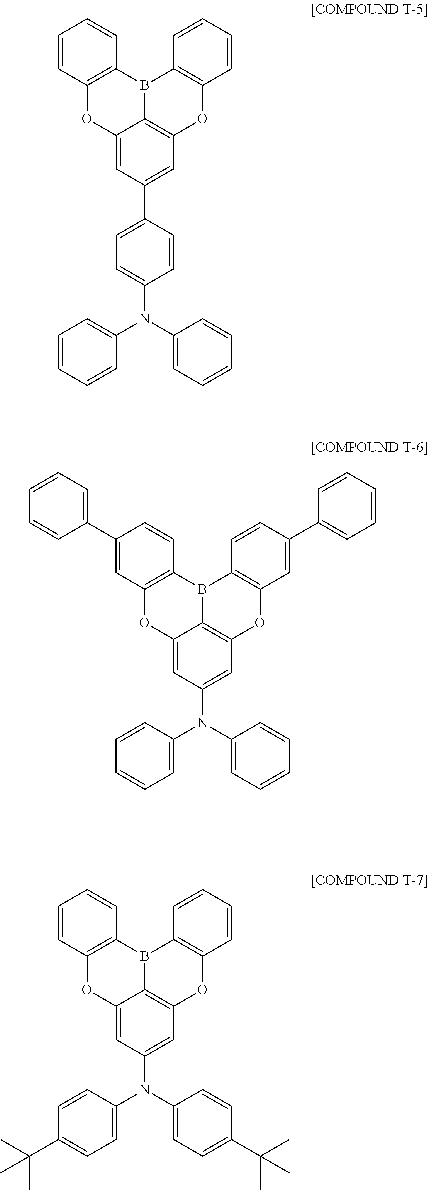 [SMILES: c1ccc(N(c2ccccc2)c2ccc(-c3cc4c5c(c3)Oc3ccccc3B5c3ccccc3O4)cc2)cc1 ; c1ccc(-c2ccc3c(c2)Oc2cc(N(c4ccccc4)c4ccccc4)cc4c2B3c2ccc(-c3ccccc3)cc2O4)cc1 ; CC(C)(C)c1ccc(N(c2ccc(C(C)(C)C)cc2)c2cc3c4c(c2)Oc2ccccc2B4c2ccccc2O3)cc1]

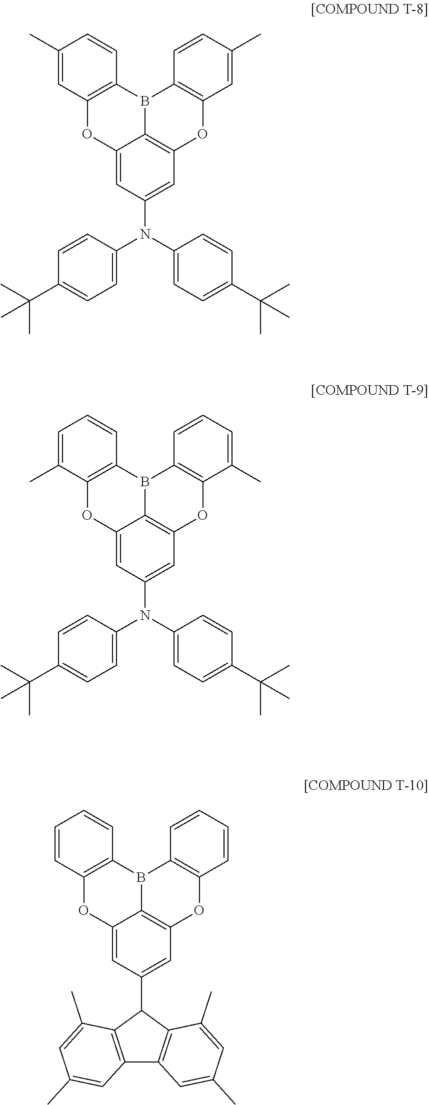

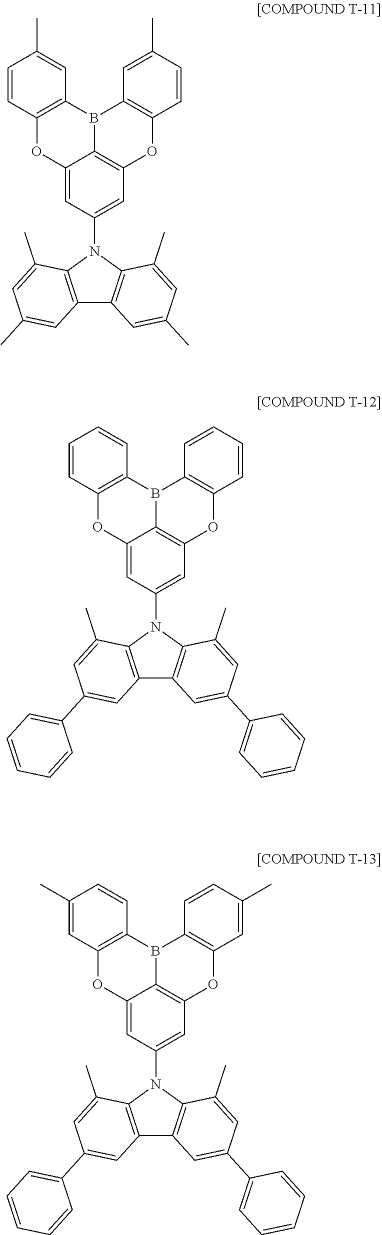

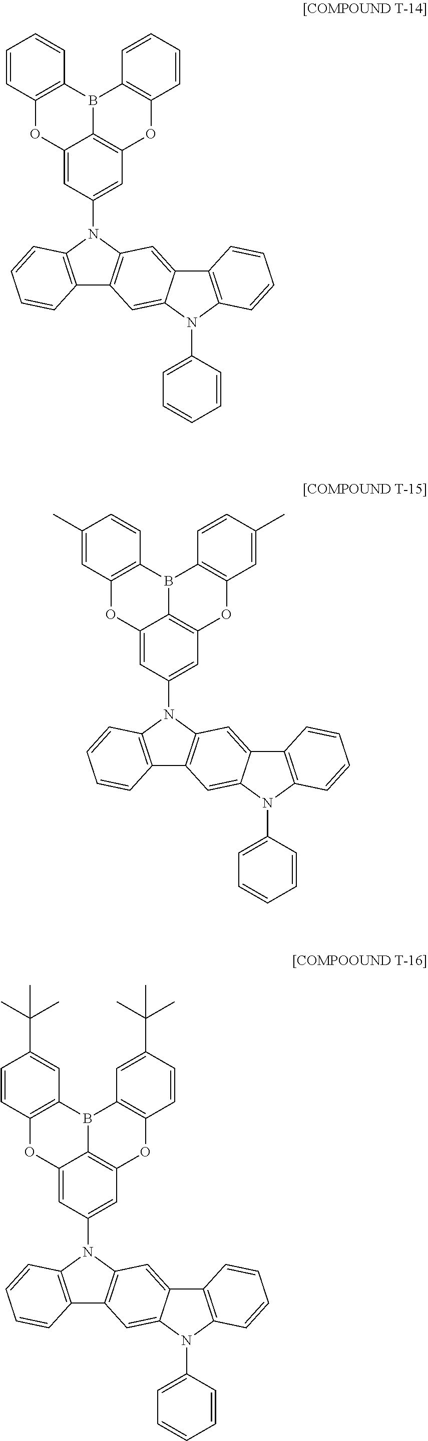 [SMILES: c1ccc(-n2c3ccccc3c3cc4c(cc32)c2ccccc2n4-c2cc3c4c(c2)Oc2ccccc2B4c2ccccc2O3)cc1 ; Cc1ccc2c(c1)Oc1cc(-n3c4ccccc4c4cc5c(cc43)c3ccccc3n5-c3ccccc3)cc3c1B2c1ccc(C)cc1O3 ; CC(C)(C)c1ccc2c(c1)B1c3cc(C(C)(C)C)ccc3Oc3cc(-n4c5ccccc5c5cc6c(cc54)c4ccccc4n6-c4ccccc4)cc(c31)O2]

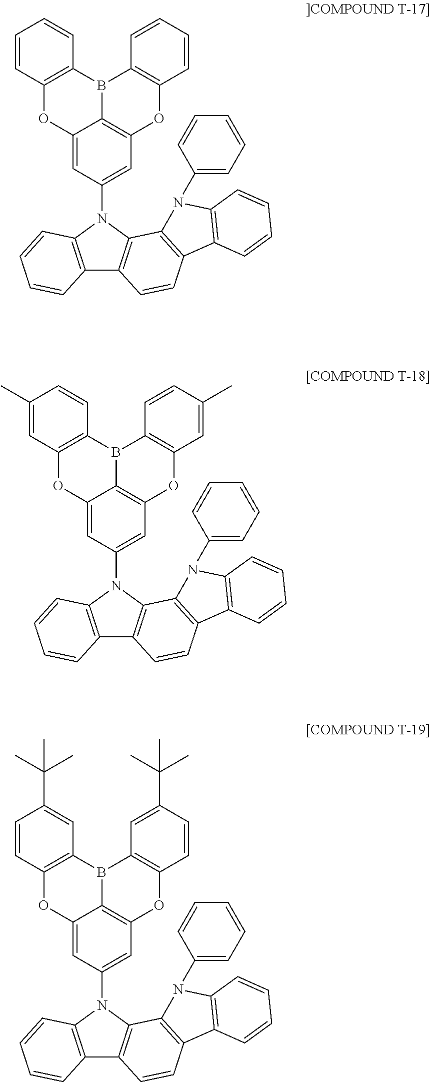 [SMILES: c1ccc(-n2c3ccccc3c3ccc4c5ccccc5n(-c5cc6c7c(c5)Oc5ccccc5B7c5ccccc5O6)c4c32)cc1 ; Cc1ccc2c(c1)Oc1cc(-n3c4ccccc4c4ccc5c6ccccc6n(-c6ccccc6)c5c43)cc3c1B2c1ccc(C)cc1O3 ; CC(C)(C)c1ccc2c(c1)B1c3cc(C(C)(C)C)ccc3Oc3cc(-n4c5ccccc5c5ccc6c7ccccc7n(-c7ccccc7)c6c54)cc(c31)O2]

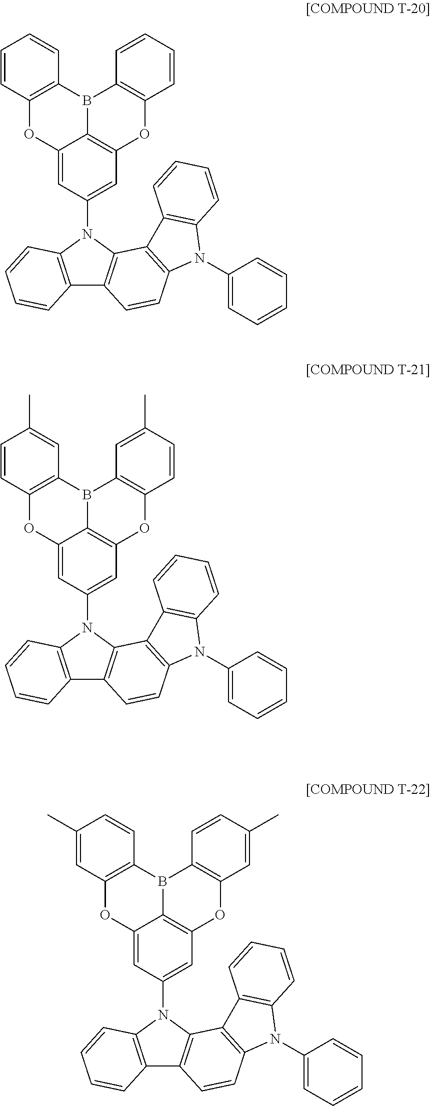 [SMILES: c1ccc(-n2c3ccccc3c3c2ccc2c4ccccc4n(-c4cc5c6c(c4)Oc4ccccc4B6c4ccccc4O5)c23)cc1 ; Cc1ccc2c(c1)B1c3cc(C)ccc3Oc3cc(-n4c5ccccc5c5ccc6c(c7ccccc7n6-c6ccccc6)c54)cc(c31)O2 ; Cc1ccc2c(c1)Oc1cc(-n3c4ccccc4c4ccc5c(c6ccccc6n5-c5ccccc5)c43)cc3c1B2c1ccc(C)cc1O3]

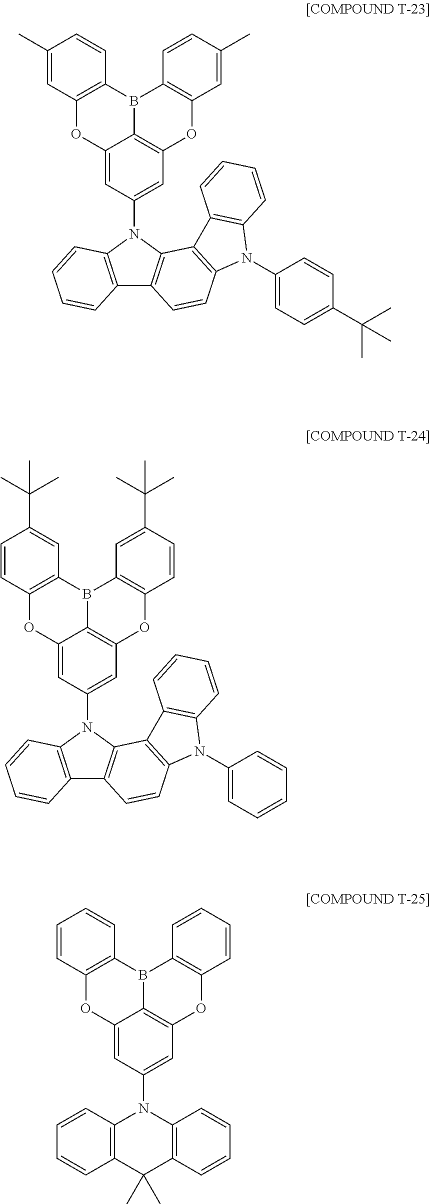 [SMILES: Cc1ccc2c(c1)Oc1cc(-n3c4ccccc4c4ccc5c(c6ccccc6n5-c5ccc(C(C)(C)C)cc5)c43)cc3c1B2c1ccc(C)cc1O3 ; CC(C)(C)c1ccc2c(c1)B1c3cc(C(C)(C)C)ccc3Oc3cc(-n4c5ccccc5c5ccc6c(c7ccccc7n6-c6ccccc6)c54)cc(c31)O2 ; CC1(C)c2ccccc2N(c2cc3c4c(c2)Oc2ccccc2B4c2ccccc2O3)c2ccccc21]

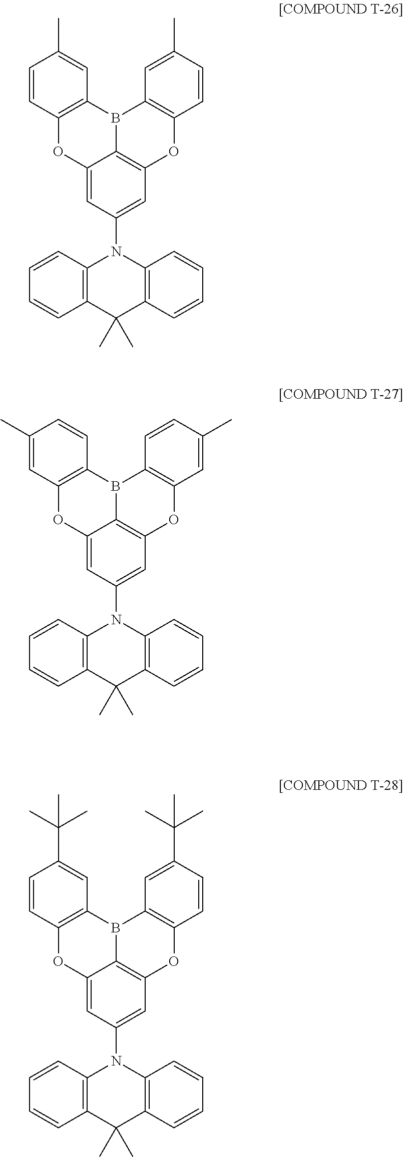

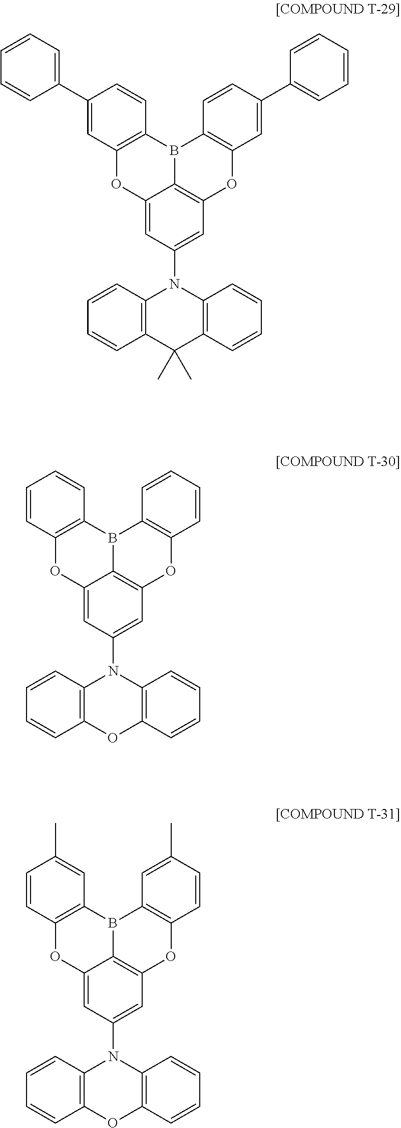 [SMILES: CC1(C)c2ccccc2N(c2cc3c4c(c2)Oc2cc(-c5ccccc5)ccc2B4c2ccc(-c4ccccc4)cc2O3)c2ccccc21 ; c1ccc2c(c1)Oc1cc(N3c4ccccc4Oc4ccccc43)cc3c1B2c1ccccc1O3 ; Cc1ccc2c(c1)B1c3cc(C)ccc3Oc3cc(N4c5ccccc5Oc5ccccc54)cc(c31)O2]

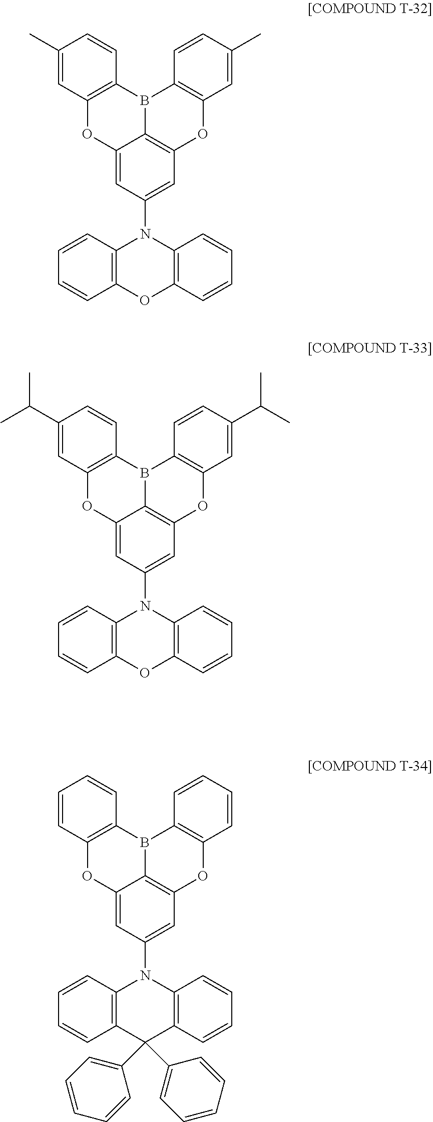

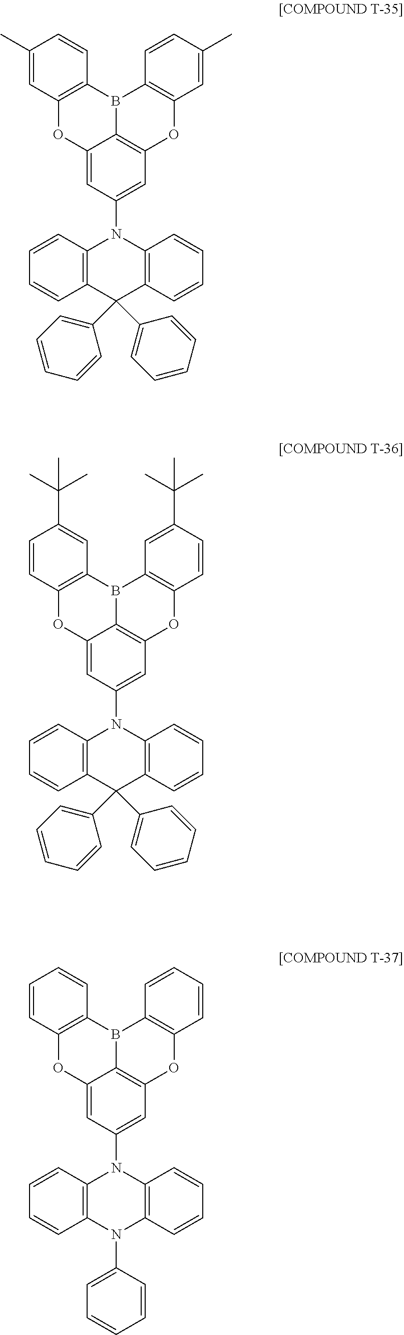

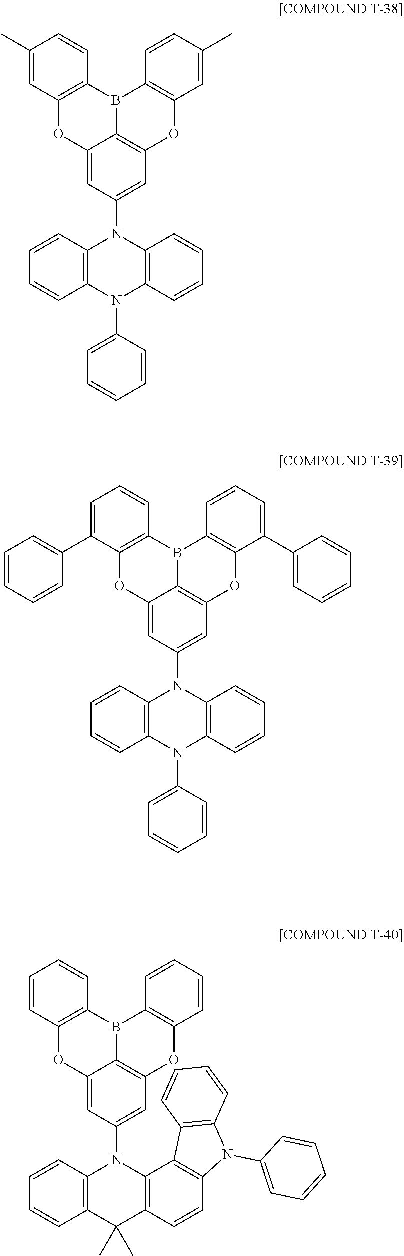

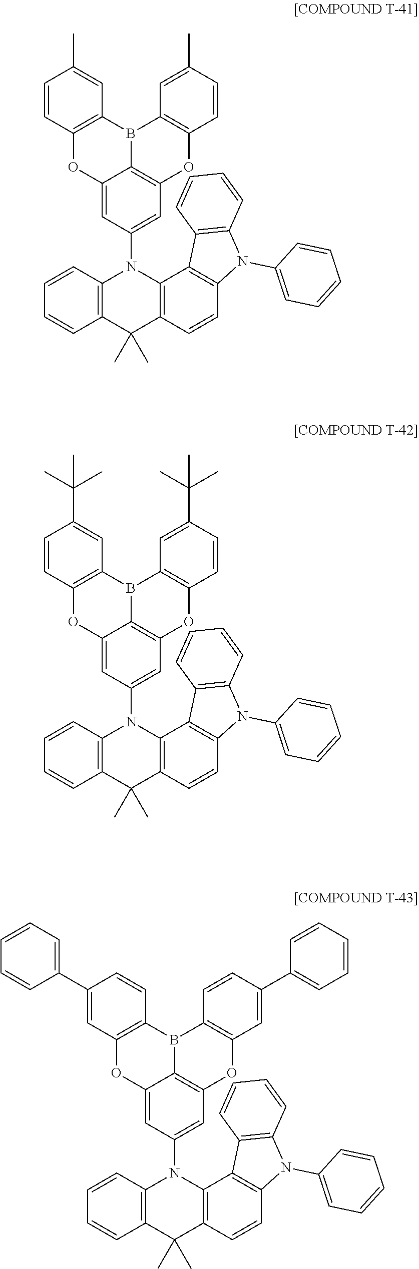 [SMILES: Cc1ccc2c(c1)B1c3cc(C)ccc3Oc3cc(N4c5ccccc5C(C)(C)c5ccc6c(c54)c4ccccc4n6-c4ccccc4)cc(c31)O2 ; CC(C)(C)c1ccc2c(c1)B1c3cc(C(C)(C)C)ccc3Oc3cc(N4c5ccccc5C(C)(C)c5ccc6c(c54)c4ccccc4n6-c4ccccc4)cc(c31)O2 ; CC1(C)c2ccccc2N(c2cc3c4c(c2)Oc2cc(-c5ccccc5)ccc2B4c2ccc(-c4ccccc4)cc2O3)c2c1ccc1c2c2ccccc2n1-c1ccccc1]

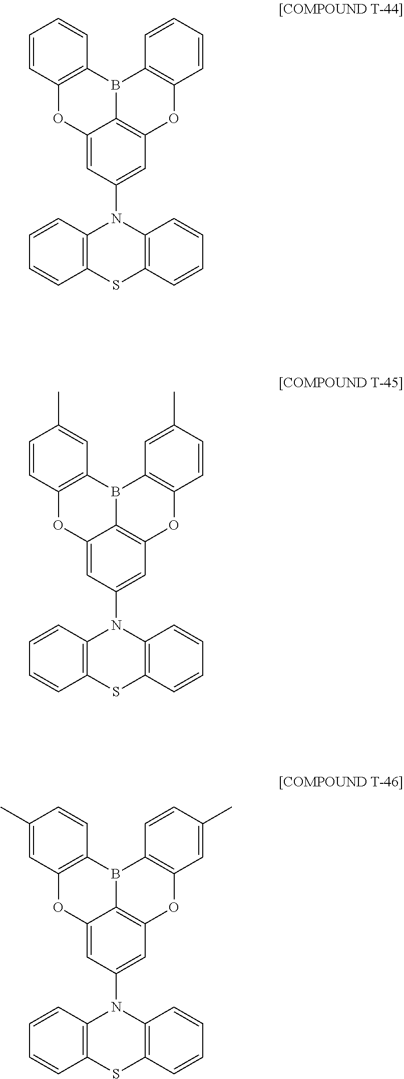

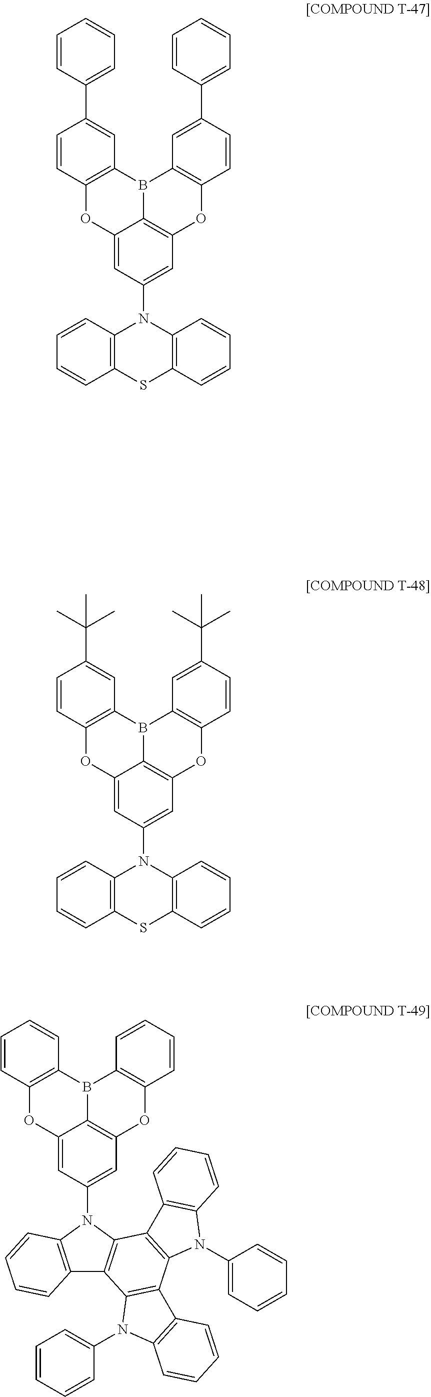

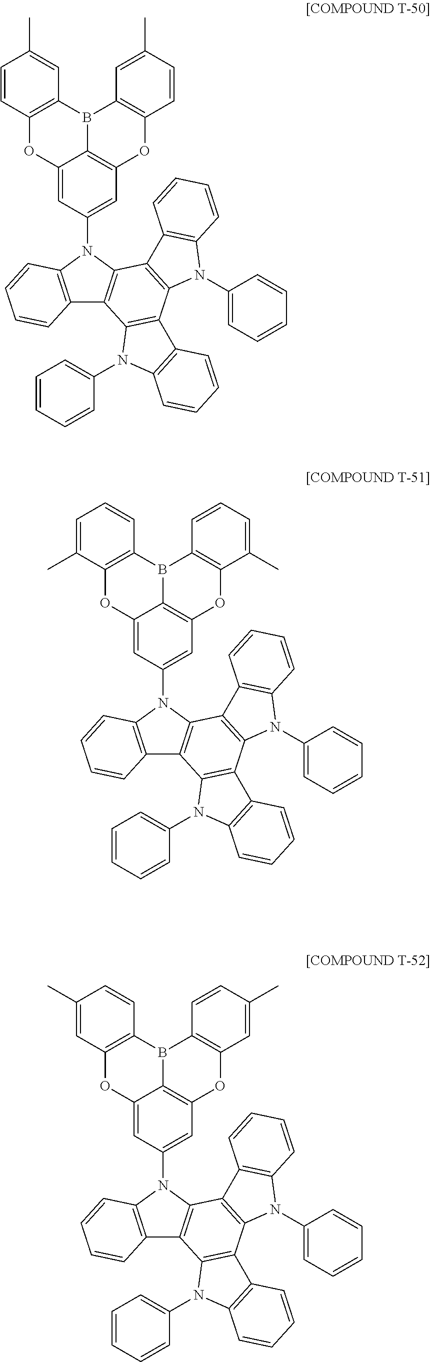 [SMILES: Cc1ccc2c(c1)B1c3cc(C)ccc3Oc3cc(-n4c5ccccc5c5c6c(c7ccccc7n6-c6ccccc6)c6c(c7ccccc7n6-c6ccccc6)c54)cc(c31)O2 ; Cc1cccc2c1Oc1cc(-n3c4ccccc4c4c5c(c6ccccc6n5-c5ccccc5)c5c(c6ccccc6n5-c5ccccc5)c43)cc3c1B2c1cccc(C)c1O3 ; Cc1ccc2c(c1)Oc1cc(-n3c4ccccc4c4c5c(c6ccccc6n5-c5ccccc5)c5c(c6ccccc6n5-c5ccccc5)c43)cc3c1B2c1ccc(C)cc1O3]

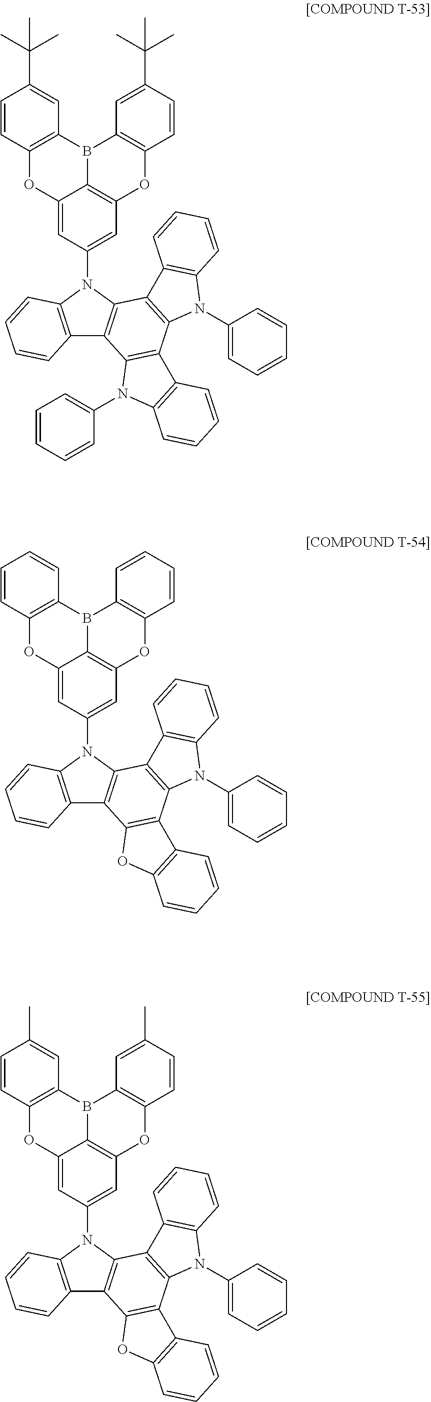 [SMILES: CC(C)(C)c1ccc2c(c1)B1c3cc(C(C)(C)C)ccc3Oc3cc(-n4c5ccccc5c5c6c(c7ccccc7n6-c6ccccc6)c6c(c7ccccc7n6-c6ccccc6)c54)cc(c31)O2 ; c1ccc(-n2c3ccccc3c3c4c(c5ccccc5n4-c4cc5c6c(c4)Oc4ccccc4B6c4ccccc4O5)c4oc5ccccc5c4c32)cc1 ; Cc1ccc2c(c1)B1c3cc(C)ccc3Oc3cc(-n4c5ccccc5c5c6oc7ccccc7c6c6c(c7ccccc7n6-c6ccccc6)c54)cc(c31)O2]

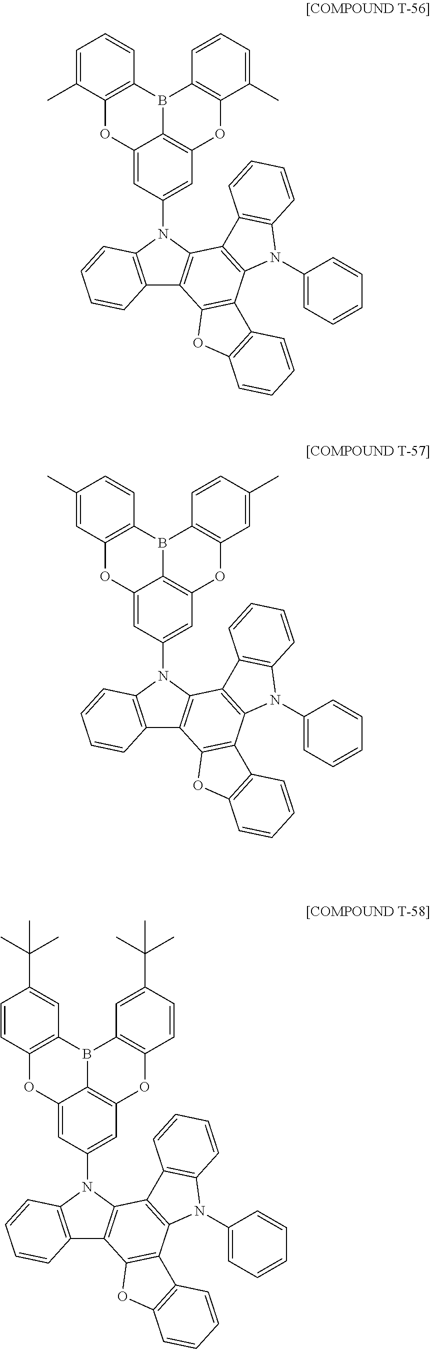 [SMILES: Cc1cccc2c1Oc1cc(-n3c4ccccc4c4c5oc6ccccc6c5c5c(c6ccccc6n5-c5ccccc5)c43)cc3c1B2c1cccc(C)c1O3 ; Cc1ccc2c(c1)Oc1cc(-n3c4ccccc4c4c5oc6ccccc6c5c5c(c6ccccc6n5-c5ccccc5)c43)cc3c1B2c1ccc(C)cc1O3 ; CC(C)(C)c1ccc2c(c1)B1c3cc(C(C)(C)C)ccc3Oc3cc(-n4c5ccccc5c5c6oc7ccccc7c6c6c(c7ccccc7n6-c6ccccc6)c54)cc(c31)O2]

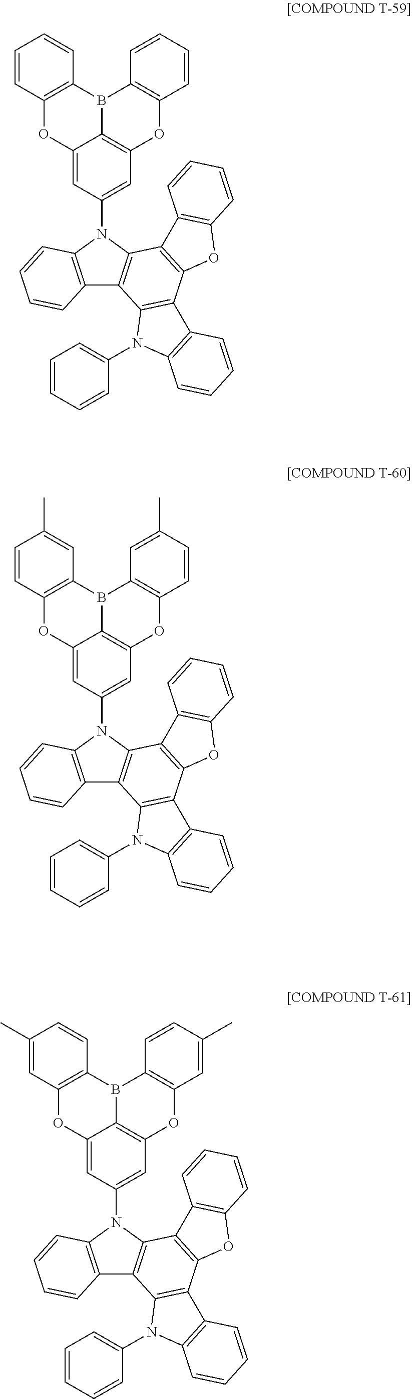 [SMILES: c1ccc(-n2c3ccccc3c3c4oc5ccccc5c4c4c(c5ccccc5n4-c4cc5c6c(c4)Oc4ccccc4B6c4ccccc4O5)c32)cc1 ; Cc1ccc2c(c1)B1c3cc(C)ccc3Oc3cc(-n4c5ccccc5c5c6c(c7ccccc7n6-c6ccccc6)c6oc7ccccc7c6c54)cc(c31)O2 ; Cc1ccc2c(c1)Oc1cc(-n3c4ccccc4c4c5c(c6ccccc6n5-c5ccccc5)c5oc6ccccc6c5c43)cc3c1B2c1ccc(C)cc1O3]

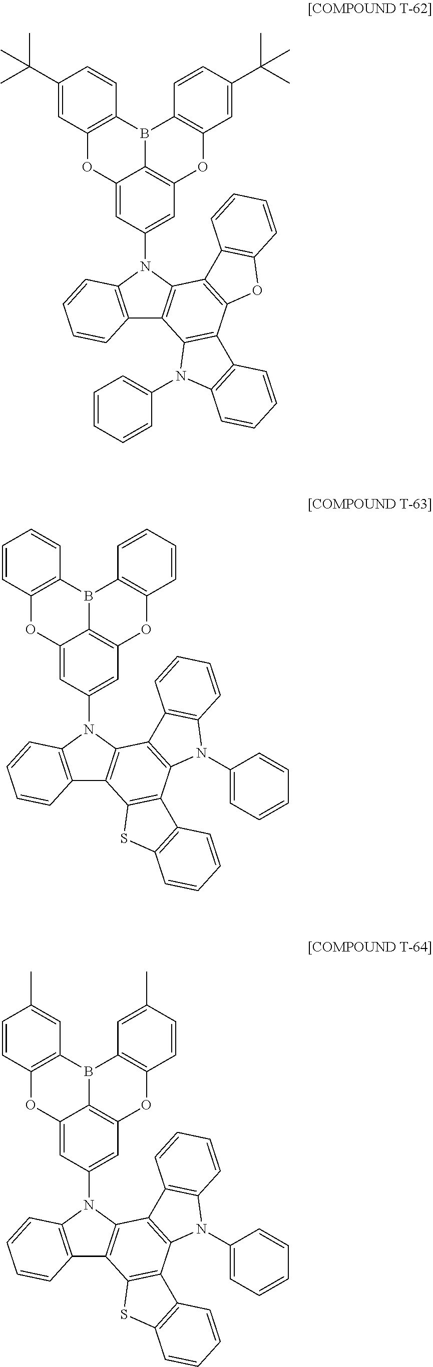 [SMILES: CC(C)(C)c1ccc2c(c1)Oc1cc(-n3c4ccccc4c4c5c(c6ccccc6n5-c5ccccc5)c5oc6ccccc6c5c43)cc3c1B2c1ccc(C(C)(C)C)cc1O3 ; c1ccc(-n2c3ccccc3c3c4c(c5ccccc5n4-c4cc5c6c(c4)Oc4ccccc4B6c4ccccc4O5)c4sc5ccccc5c4c32)cc1 ; Cc1ccc2c(c1)B1c3cc(C)ccc3Oc3cc(-n4c5ccccc5c5c6sc7ccccc7c6c6c(c7ccccc7n6-c6ccccc6)c54)cc(c31)O2]

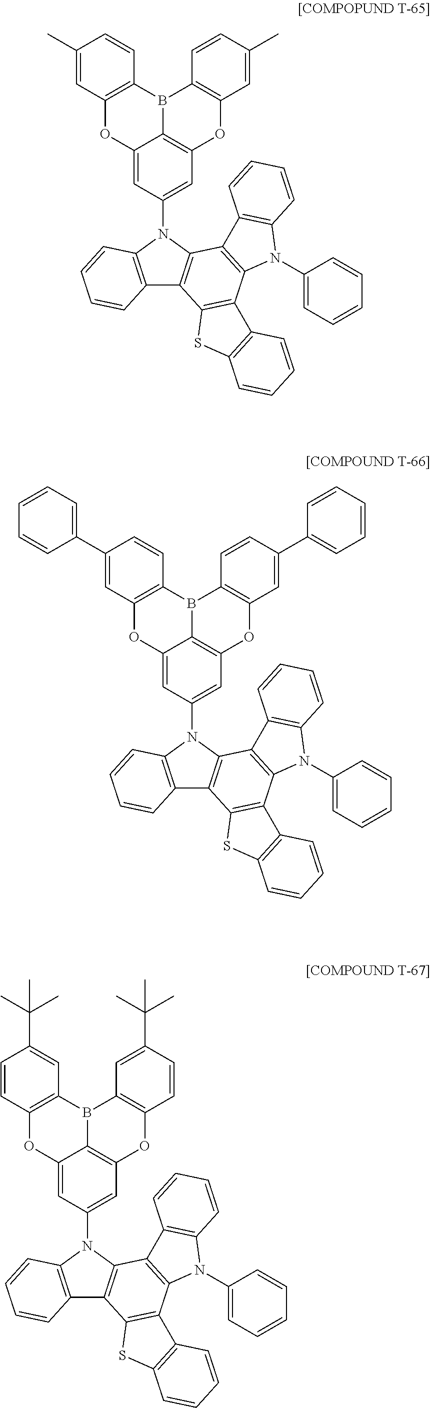 [SMILES: Cc1ccc2c(c1)Oc1cc(-n3c4ccccc4c4c5sc6ccccc6c5c5c(c6ccccc6n5-c5ccccc5)c43)cc3c1B2c1ccc(C)cc1O3 ; c1ccc(-c2ccc3c(c2)Oc2cc(-n4c5ccccc5c5c6sc7ccccc7c6c6c(c7ccccc7n6-c6ccccc6)c54)cc4c2B3c2ccc(-c3ccccc3)cc2O4)cc1 ; CC(C)(C)c1ccc2c(c1)B1c3cc(C(C)(C)C)ccc3Oc3cc(-n4c5ccccc5c5c6sc7ccccc7c6c6c(c7ccccc7n6-c6ccccc6)c54)cc(c31)O2]

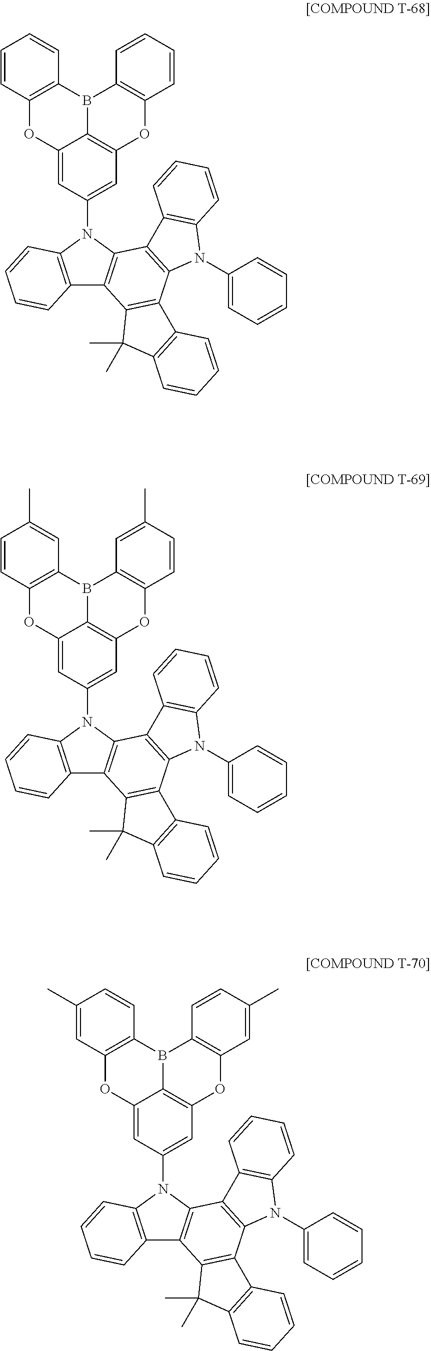 [SMILES: CC1(C)c2ccccc2-c2c1c1c3ccccc3n(-c3cc4c5c(c3)Oc3ccccc3B5c3ccccc3O4)c1c1c3ccccc3n(-c3ccccc3)c21 ; Cc1ccc2c(c1)B1c3cc(C)ccc3Oc3cc(-n4c5ccccc5c5c6c(c7c(c8ccccc8n7-c7ccccc7)c54)-c4ccccc4C6(C)C)cc(c31)O2 ; Cc1ccc2c(c1)Oc1cc(-n3c4ccccc4c4c5c(c6c(c7ccccc7n6-c6ccccc6)c43)-c3ccccc3C5(C)C)cc3c1B2c1ccc(C)cc1O3]

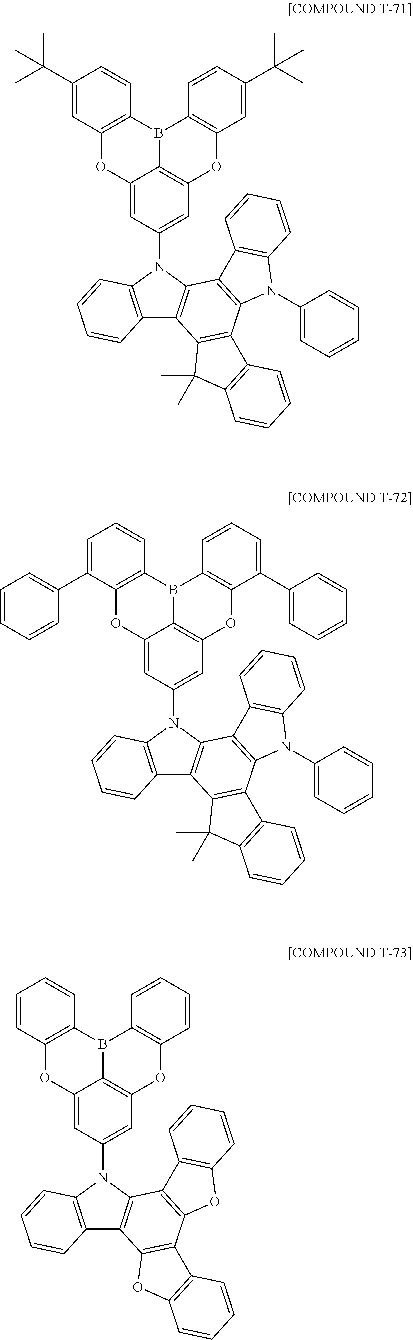 [SMILES: CC(C)(C)c1ccc2c(c1)Oc1cc(-n3c4ccccc4c4c5c(c6c(c7ccccc7n6-c6ccccc6)c43)-c3ccccc3C5(C)C)cc3c1B2c1ccc(C(C)(C)C)cc1O3 ; CC1(C)c2ccccc2-c2c1c1c3ccccc3n(-c3cc4c5c(c3)Oc3c(cccc3-c3ccccc3)B5c3cccc(-c5ccccc5)c3O4)c1c1c3ccccc3n(-c3ccccc3)c21 ; c1ccc2c(c1)Oc1cc(-n3c4ccccc4c4c5oc6ccccc6c5c5oc6ccccc6c5c43)cc3c1B2c1ccccc1O3]

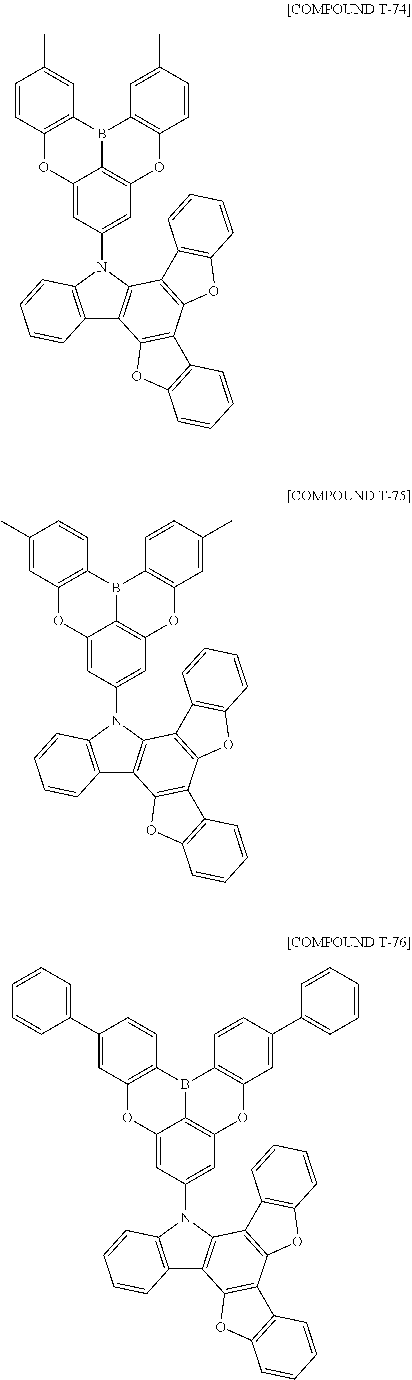 [SMILES: Cc1ccc2c(c1)B1c3cc(C)ccc3Oc3cc(-n4c5ccccc5c5c6oc7ccccc7c6c6oc7ccccc7c6c54)cc(c31)O2 ; Cc1ccc2c(c1)Oc1cc(-n3c4ccccc4c4c5oc6ccccc6c5c5oc6ccccc6c5c43)cc3c1B2c1ccc(C)cc1O3 ; c1ccc(-c2ccc3c(c2)Oc2cc(-n4c5ccccc5c5c6oc7ccccc7c6c6oc7ccccc7c6c54)cc4c2B3c2ccc(-c3ccccc3)cc2O4)cc1]

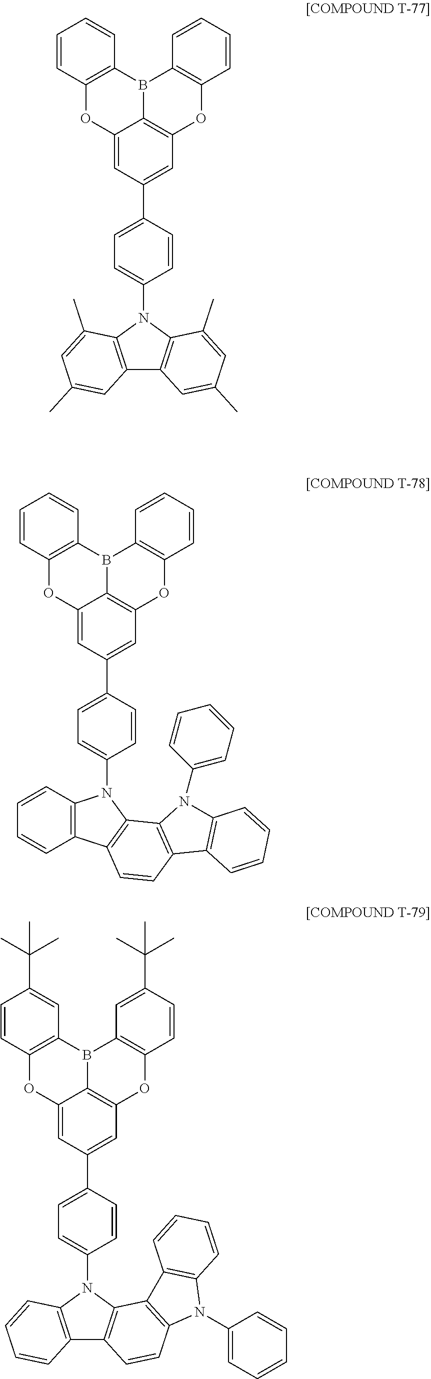

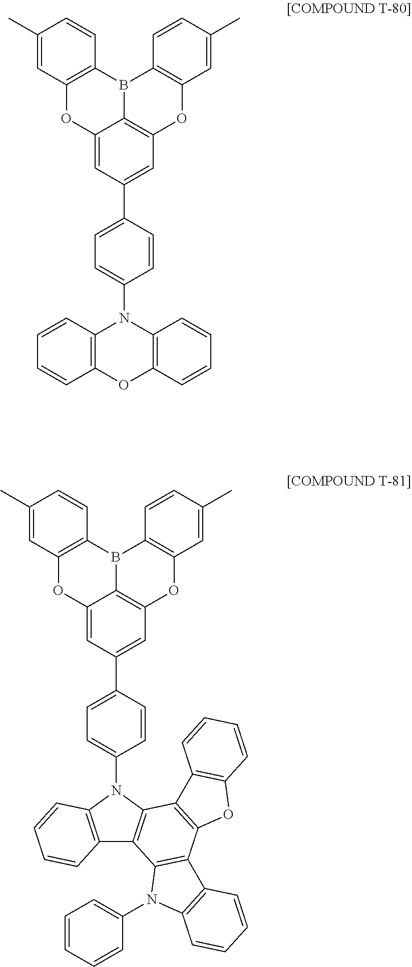

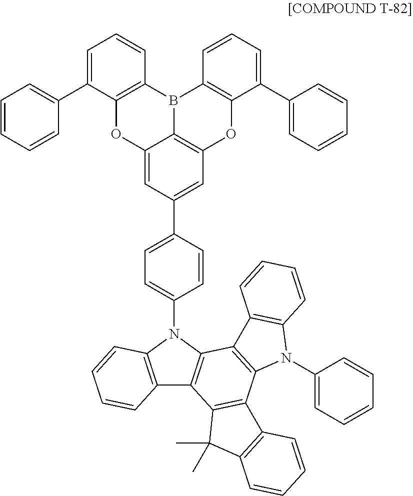 [SMILES: CC1(C)c2ccccc2-c2c1c1c3ccccc3n(-c3ccc(-c4cc5c6c(c4)Oc4c(cccc4-c4ccccc4)B6c4cccc(-c6ccccc6)c4O5)cc3)c1c1c3ccccc3n(-c3ccccc3)c21]

6. The organic light-emitting device according to claim 1, wherein the second compound has a structure of one of the following Compounds H-1 to H-35:

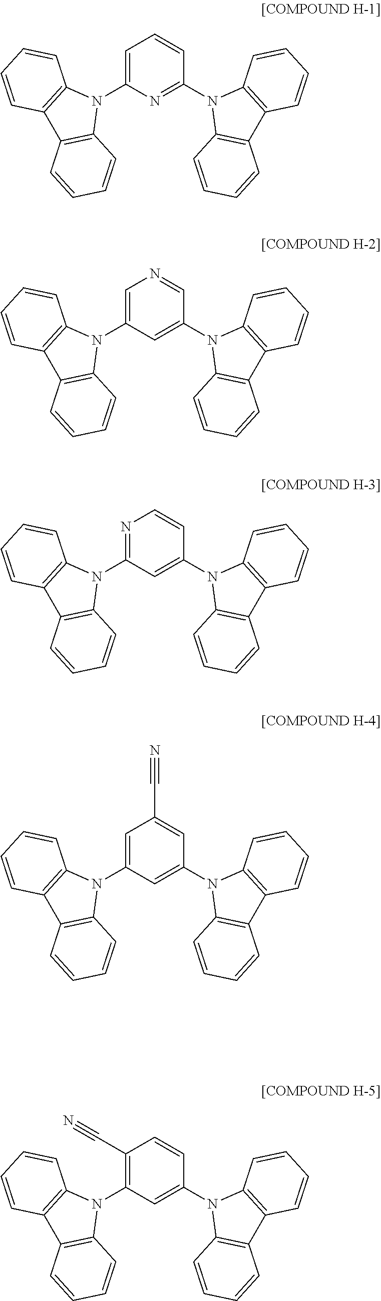 [SMILES: c1cc(-n2c3ccccc3c3ccccc32)nc(-n2c3ccccc3c3ccccc32)c1 ; c1ccc2c(c1)c1ccccc1n2-c1cncc(-n2c3ccccc3c3ccccc32)c1 ; c1ccc2c(c1)c1ccccc1n2-c1ccnc(-n2c3ccccc3c3ccccc32)c1 ; N#Cc1cc(-n2c3ccccc3c3ccccc32)cc(-n2c3ccccc3c3ccccc32)c1 ; N#Cc1ccc(-n2c3ccccc3c3ccccc32)cc1-n1c2ccccc2c2ccccc21]

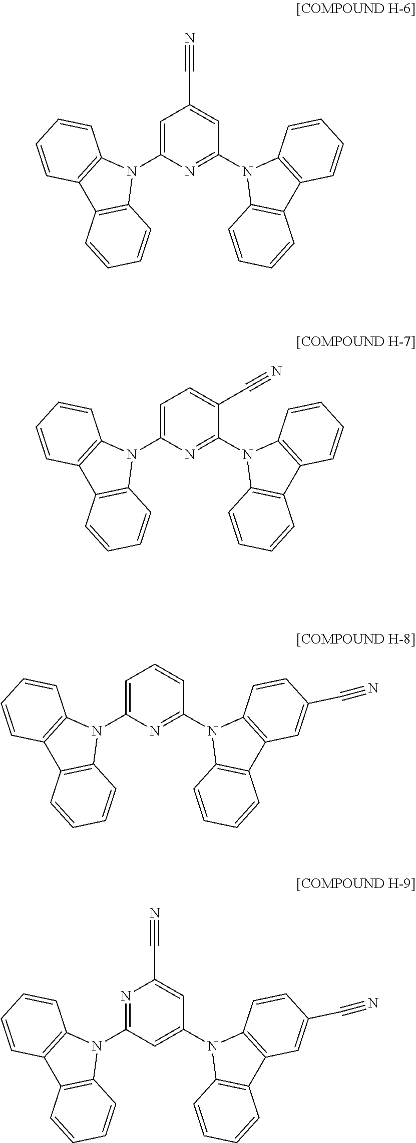 [SMILES: N#Cc1cc(-n2c3ccccc3c3ccccc32)nc(-n2c3ccccc3c3ccccc32)c1 ; N#Cc1ccc(-n2c3ccccc3c3ccccc32)nc1-n1c2ccccc2c2ccccc21 ; N#Cc1ccc2c(c1)c1ccccc1n2-c1cccc(-n2c3ccccc3c3ccccc32)n1 ; N#Cc1ccc2c(c1)c1ccccc1n2-c1cc(C#N)nc(-n2c3ccccc3c3ccccc32)c1]

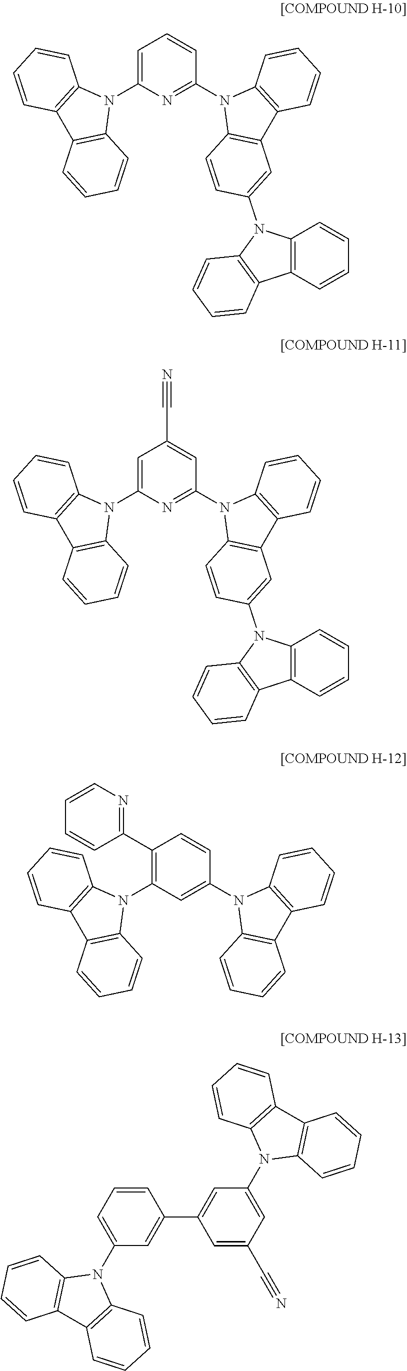 [SMILES: c1cc(-n2c3ccccc3c3ccccc32)nc(-n2c3ccccc3c3cc(-n4c5ccccc5c5ccccc54)ccc32)c1 ; N#Cc1cc(-n2c3ccccc3c3ccccc32)nc(-n2c3ccccc3c3cc(-n4c5ccccc5c5ccccc54)ccc32)c1 ; c1ccc(-c2ccc(-n3c4ccccc4c4ccccc43)cc2-n2c3ccccc3c3ccccc32)nc1 ; N#Cc1cc(-c2cccc(-n3c4ccccc4c4ccccc43)c2)cc(-n2c3ccccc3c3ccccc32)c1]

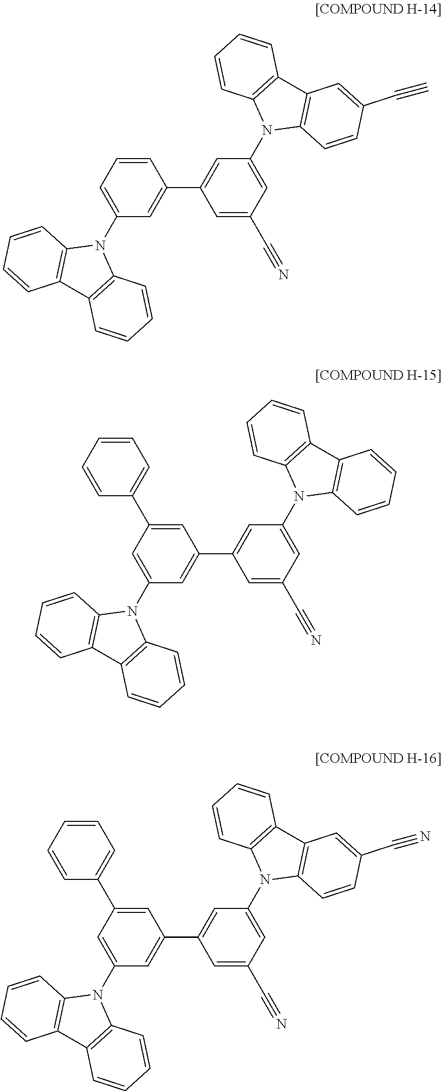 [SMILES: C#Cc1ccc2c(c1)c1ccccc1n2-c1cc(C#N)cc(-c2cccc(-n3c4ccccc4c4ccccc43)c2)c1 ; N#Cc1cc(-c2cc(-c3ccccc3)cc(-n3c4ccccc4c4ccccc43)c2)cc(-n2c3ccccc3c3ccccc32)c1 ; N#Cc1cc(-c2cc(-c3ccccc3)cc(-n3c4ccccc4c4ccccc43)c2)cc(-n2c3ccccc3c3cc(C#N)ccc32)c1]

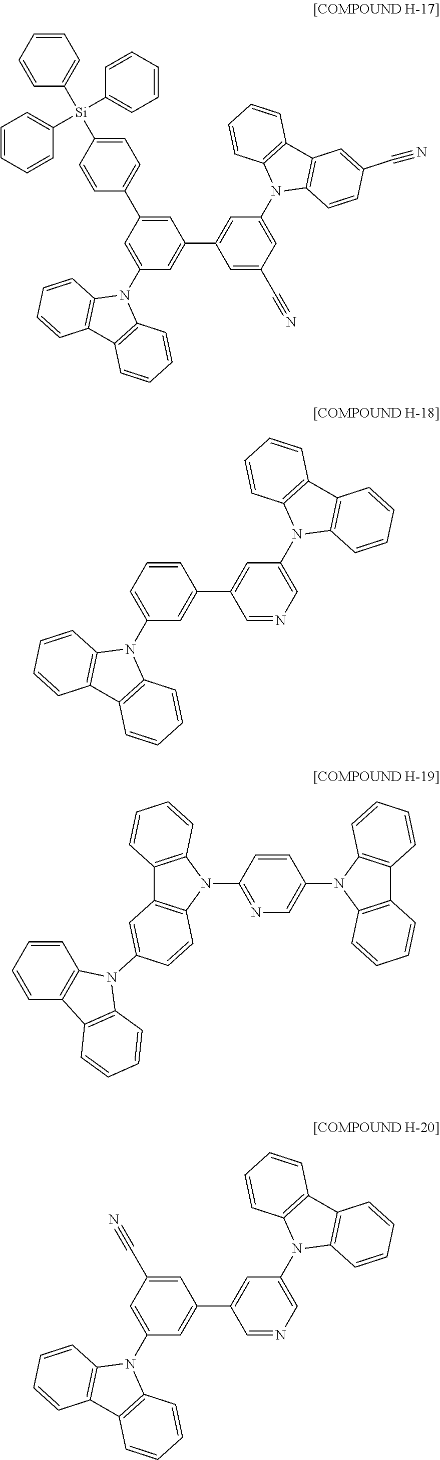 [SMILES: N#Cc1cc(-c2cc(-c3ccc([Si](c4ccccc4)(c4ccccc4)c4ccccc4)cc3)cc(-n3c4ccccc4c4ccccc43)c2)cc(-n2c3ccccc3c3cc(C#N)ccc32)c1 ; c1cc(-c2cncc(-n3c4ccccc4c4ccccc43)c2)cc(-n2c3ccccc3c3ccccc32)c1 ; c1ccc2c(c1)c1ccccc1n2-c1ccc(-n2c3ccccc3c3cc(-n4c5ccccc5c5ccccc54)ccc32)nc1 ; N#Cc1cc(-c2cncc(-n3c4ccccc4c4ccccc43)c2)cc(-n2c3ccccc3c3ccccc32)c1]

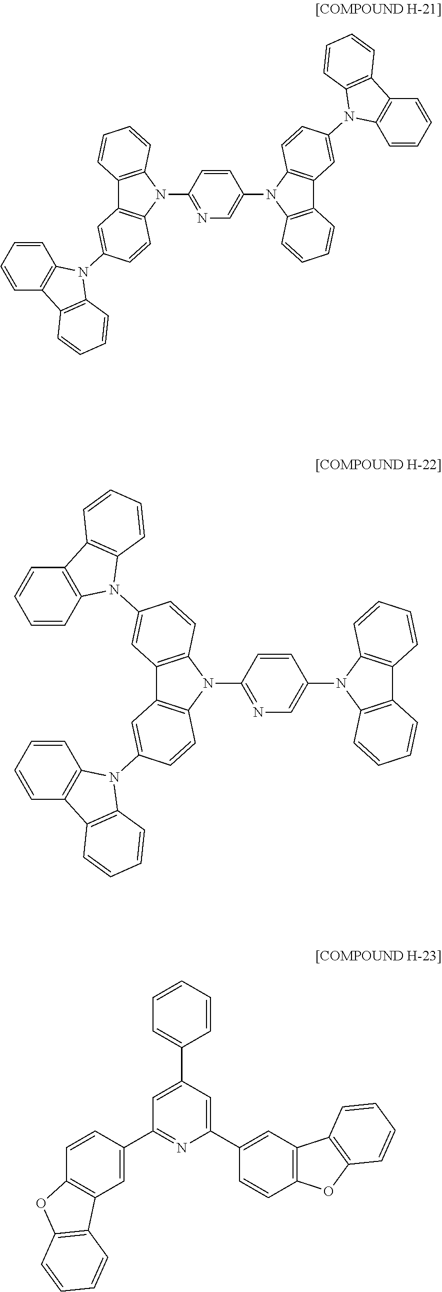 [SMILES: c1ccc2c(c1)c1ccccc1n2-c1ccc2c(c1)c1ccccc1n2-c1ccc(-n2c3ccccc3c3cc(-n4c5ccccc5c5ccccc54)ccc32)nc1 ; c1ccc2c(c1)c1ccccc1n2-c1ccc(-n2c3ccc(-n4c5ccccc5c5ccccc54)cc3c3cc(-n4c5ccccc5c5ccccc54)ccc32)nc1 ; c1ccc(-c2cc(-c3ccc4oc5ccccc5c4c3)nc(-c3ccc4oc5ccccc5c4c3)c2)cc1]

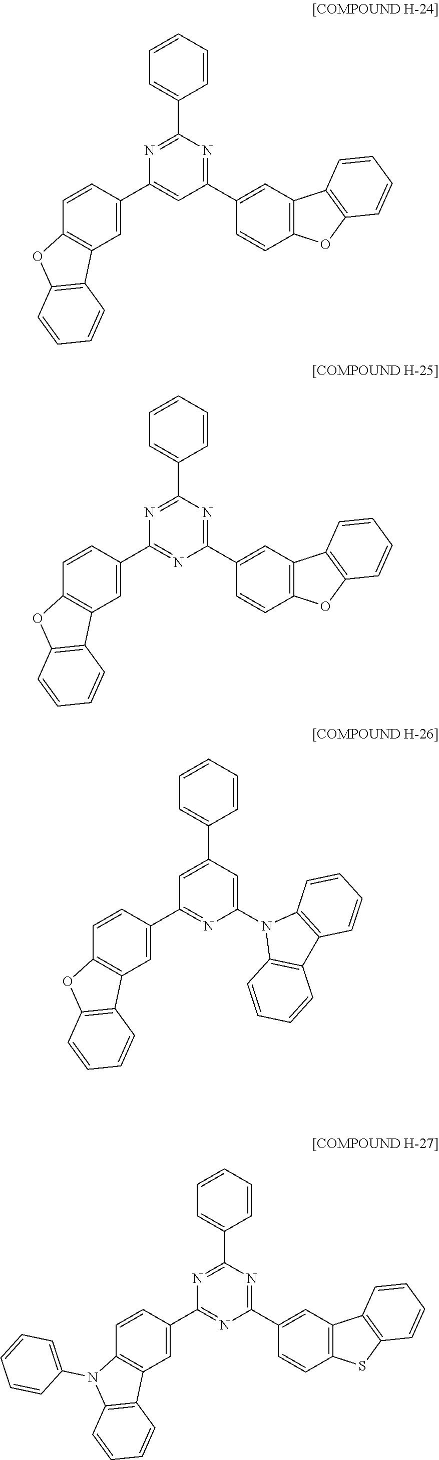 [SMILES: c1ccc(-c2nc(-c3ccc4oc5ccccc5c4c3)cc(-c3ccc4oc5ccccc5c4c3)n2)cc1 ; c1ccc(-c2nc(-c3ccc4oc5ccccc5c4c3)nc(-c3ccc4oc5ccccc5c4c3)n2)cc1 ; c1ccc(-c2cc(-c3ccc4oc5ccccc5c4c3)nc(-n3c4ccccc4c4ccccc43)c2)cc1 ; c1ccc(-c2nc(-c3ccc4sc5ccccc5c4c3)nc(-c3ccc4c(c3)c3ccccc3n4-c3ccccc3)n2)cc1]

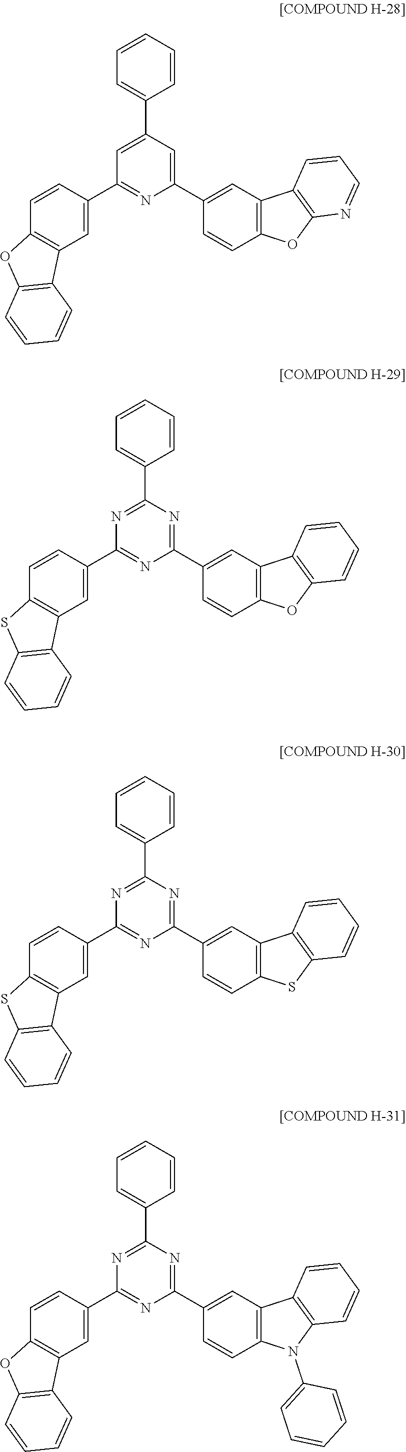 [SMILES: c1ccc(-c2cc(-c3ccc4oc5ccccc5c4c3)nc(-c3ccc4oc5ncccc5c4c3)c2)cc1 ; c1ccc(-c2nc(-c3ccc4oc5ccccc5c4c3)nc(-c3ccc4sc5ccccc5c4c3)n2)cc1 ; c1ccc(-c2nc(-c3ccc4sc5ccccc5c4c3)nc(-c3ccc4sc5ccccc5c4c3)n2)cc1 ; c1ccc(-c2nc(-c3ccc4oc5ccccc5c4c3)nc(-c3ccc4c(c3)c3ccccc3n4-c3ccccc3)n2)cc1]

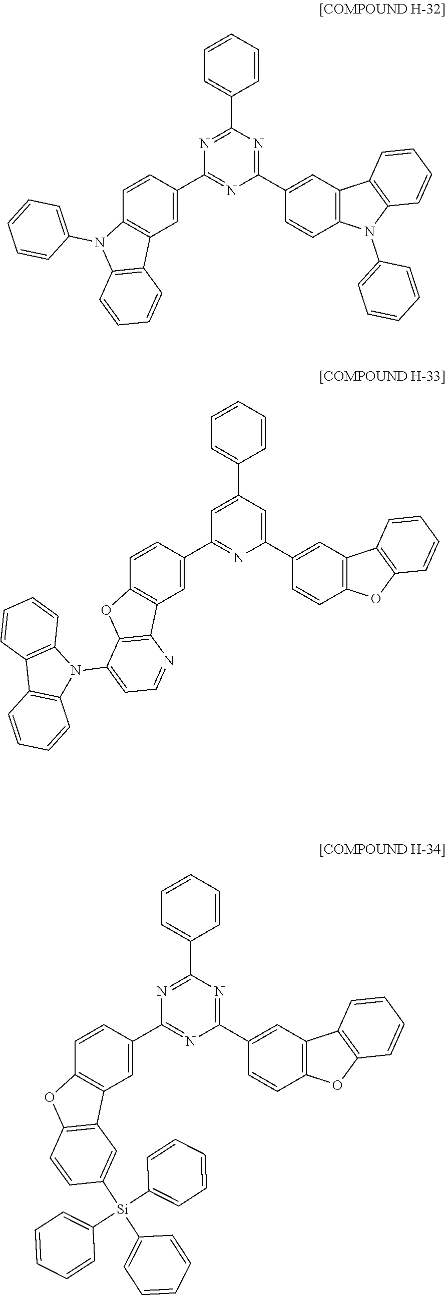 [SMILES: c1ccc(-c2nc(-c3ccc4c(c3)c3ccccc3n4-c3ccccc3)nc(-c3ccc4c(c3)c3ccccc3n4-c3ccccc3)n2)cc1 ; c1ccc(-c2cc(-c3ccc4oc5ccccc5c4c3)nc(-c3ccc4oc5c(-n6c7ccccc7c7ccccc76)ccnc5c4c3)c2)cc1 ; c1ccc(-c2nc(-c3ccc4oc5ccccc5c4c3)nc(-c3ccc4oc5ccc([Si](c6ccccc6)(c6ccccc6)c6ccccc6)cc5c4c3)n2)cc1]

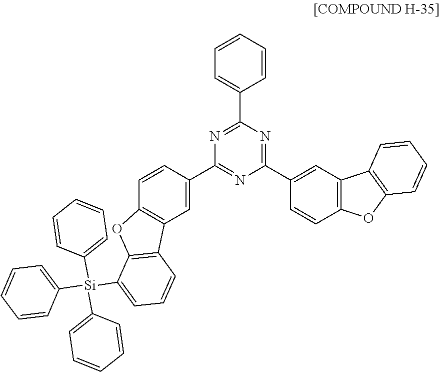 [SMILES: c1ccc(-c2nc(-c3ccc4oc5ccccc5c4c3)nc(-c3ccc4oc5c([Si](c6ccccc6)(c6ccccc6)c6ccccc6)cccc5c4c3)n2)cc1]

7. The organic light-emitting device according to claim 4, wherein the third compound has a structure of one of the following Compounds F-1 to F-51:

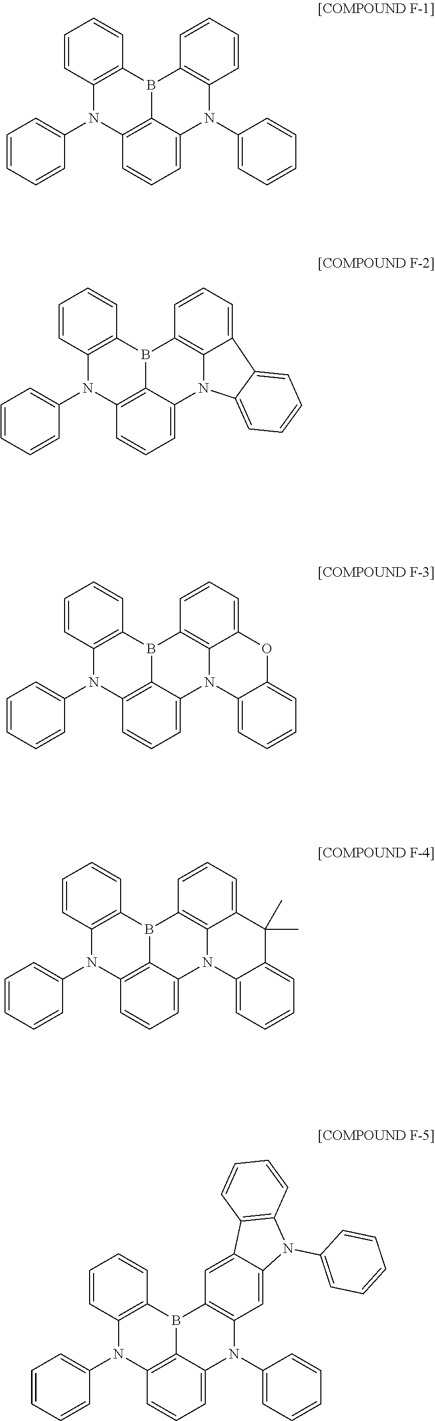 [SMILES: c1ccc(N2c3ccccc3B3c4ccccc4N(c4ccccc4)c4cccc2c43)cc1 ; c1ccc(N2c3ccccc3B3c4c2cccc4-n2c4ccccc4c4cccc3c42)cc1 ; c1ccc(N2c3ccccc3B3c4cccc5c4N(c4ccccc4O5)c4cccc2c43)cc1 ; CC1(C)c2ccccc2N2c3cccc4c3B(c3ccccc3N4c3ccccc3)c3cccc1c32 ; c1ccc(N2c3ccccc3B3c4cc5c6ccccc6n(-c6ccccc6)c5cc4N(c4ccccc4)c4cccc2c43)cc1]

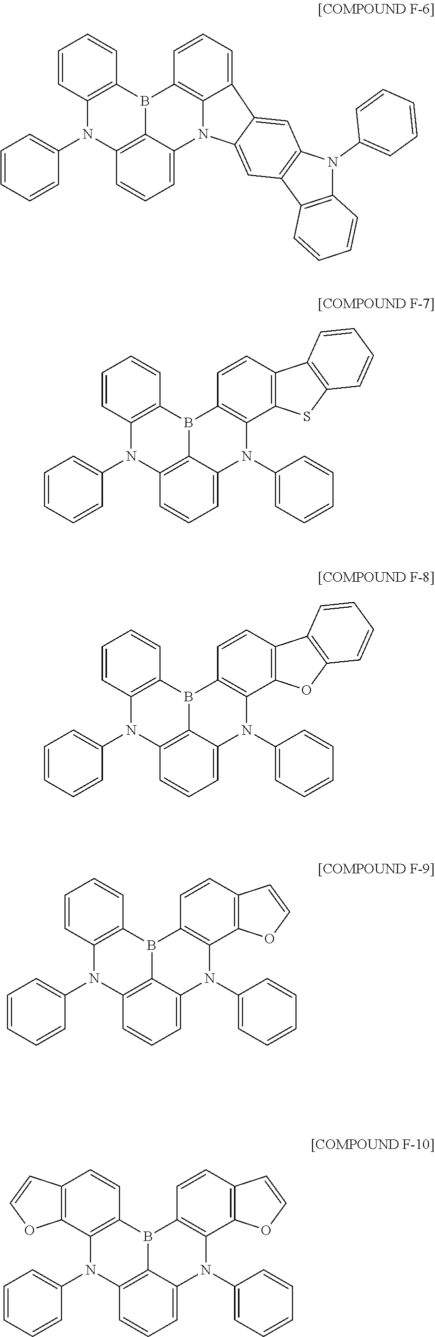 [SMILES: c1ccc(N2c3ccccc3B3c4c2cccc4-n2c4cc5c6ccccc6n(-c6ccccc6)c5cc4c4cccc3c42)cc1 ; c1ccc(N2c3ccccc3B3c4ccc5c(sc6ccccc65)c4N(c4ccccc4)c4cccc2c43)cc1 ; c1ccc(N2c3ccccc3B3c4ccc5c(oc6ccccc65)c4N(c4ccccc4)c4cccc2c43)cc1 ; c1ccc(N2c3ccccc3B3c4ccc5ccoc5c4N(c4ccccc4)c4cccc2c43)cc1 ; c1ccc(N2c3cccc4c3B(c3ccc5ccoc5c32)c2ccc3ccoc3c2N4c2ccccc2)cc1]

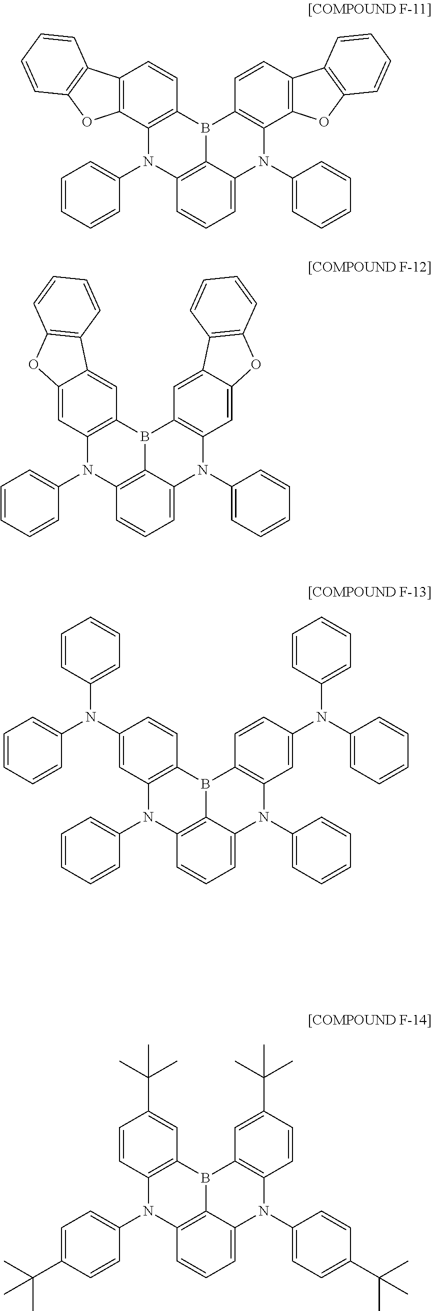 [SMILES: c1ccc(N2c3cccc4c3B(c3ccc5c(oc6ccccc65)c32)c2ccc3c(oc5ccccc53)c2N4c2ccccc2)cc1 ; c1ccc(N2c3cc4oc5ccccc5c4cc3B3c4cc5c(cc4N(c4ccccc4)c4cccc2c43)oc2ccccc25)cc1 ; c1ccc(N(c2ccccc2)c2ccc3c(c2)N(c2ccccc2)c2cccc4c2B3c2ccc(N(c3ccccc3)c3ccccc3)cc2N4c2ccccc2)cc1 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1]

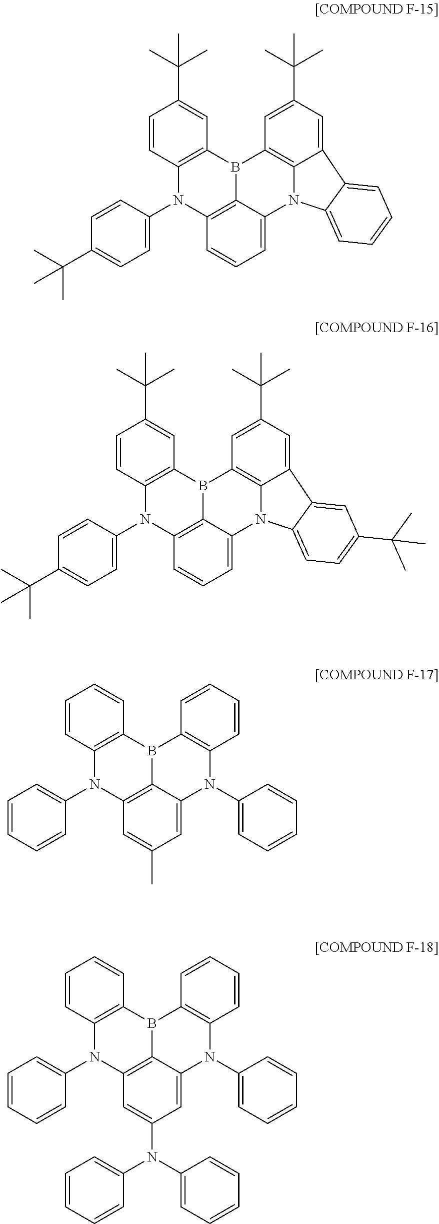 [SMILES: CC(C)(C)c1ccc(N2c3ccc(C(C)(C)C)cc3B3c4c2cccc4-n2c4ccccc4c4cc(C(C)(C)C)cc3c42)cc1 ; CC(C)(C)c1ccc(N2c3ccc(C(C)(C)C)cc3B3c4c2cccc4-n2c4ccc(C(C)(C)C)cc4c4cc(C(C)(C)C)cc3c42)cc1 ; Cc1cc2c3c(c1)N(c1ccccc1)c1ccccc1B3c1ccccc1N2c1ccccc1 ; c1ccc(N(c2ccccc2)c2cc3c4c(c2)N(c2ccccc2)c2ccccc2B4c2ccccc2N3c2ccccc2)cc1]

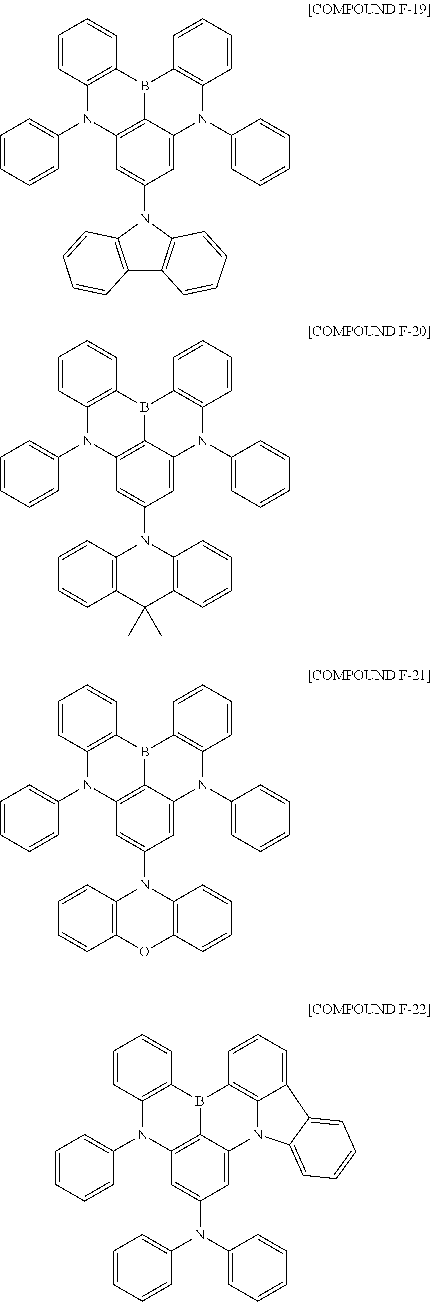 [SMILES: c1ccc(N2c3ccccc3B3c4ccccc4N(c4ccccc4)c4cc(-n5c6ccccc6c6ccccc65)cc2c43)cc1 ; CC1(C)c2ccccc2N(c2cc3c4c(c2)N(c2ccccc2)c2ccccc2B4c2ccccc2N3c2ccccc2)c2ccccc21 ; c1ccc(N2c3ccccc3B3c4ccccc4N(c4ccccc4)c4cc(N5c6ccccc6Oc6ccccc65)cc2c43)cc1 ; c1ccc(N(c2ccccc2)c2cc3c4c(c2)-n2c5ccccc5c5cccc(c52)B4c2ccccc2N3c2ccccc2)cc1]

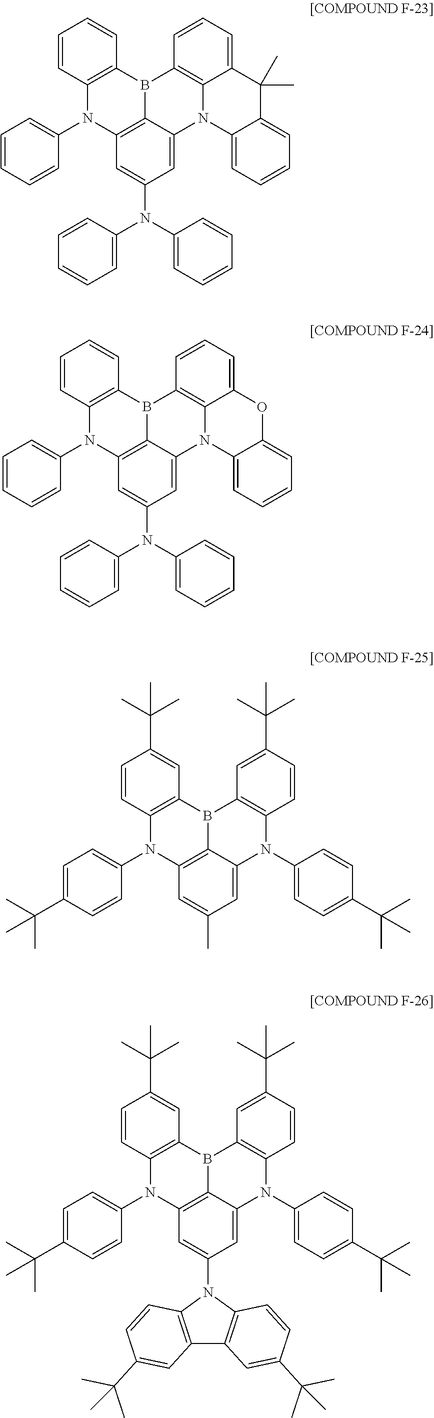

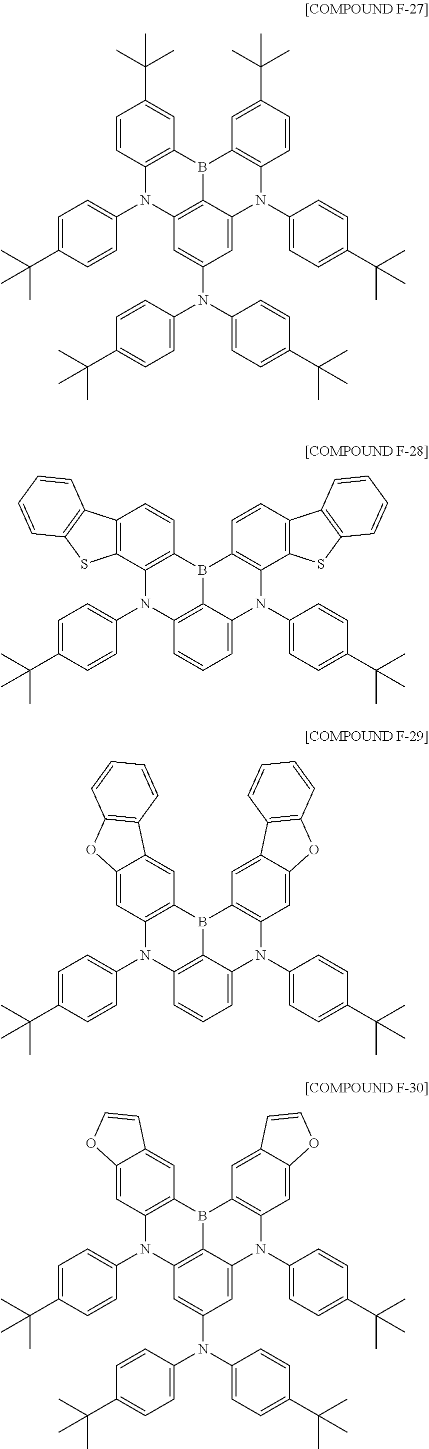

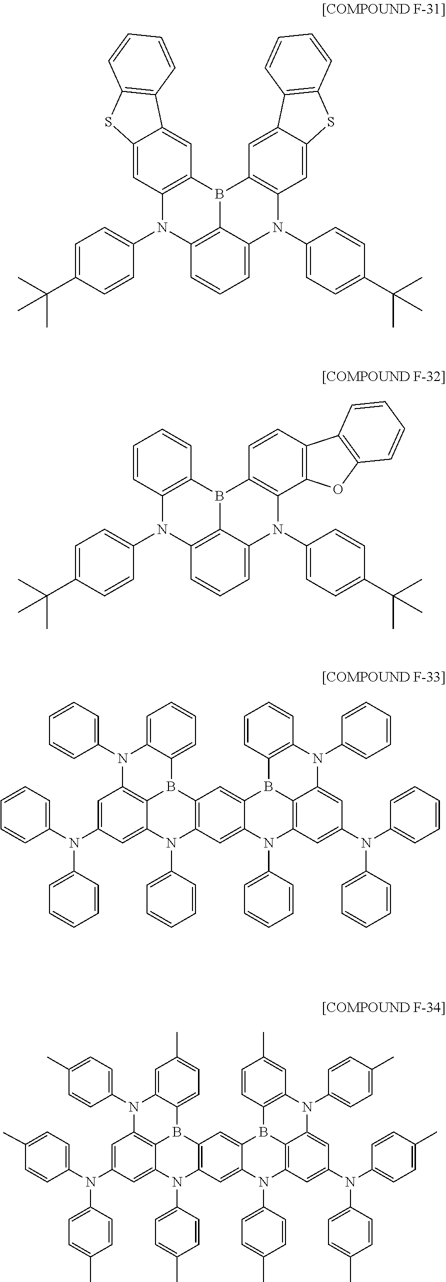

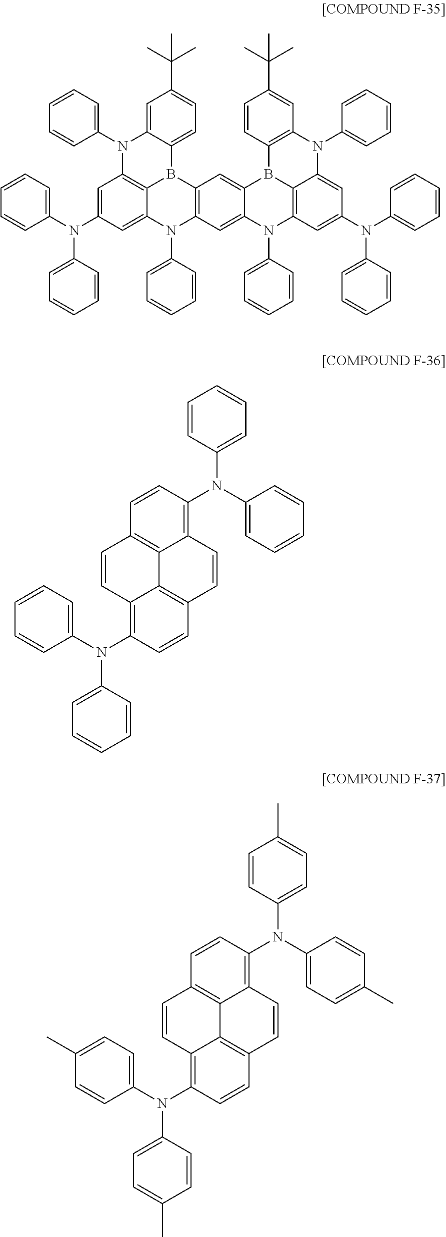

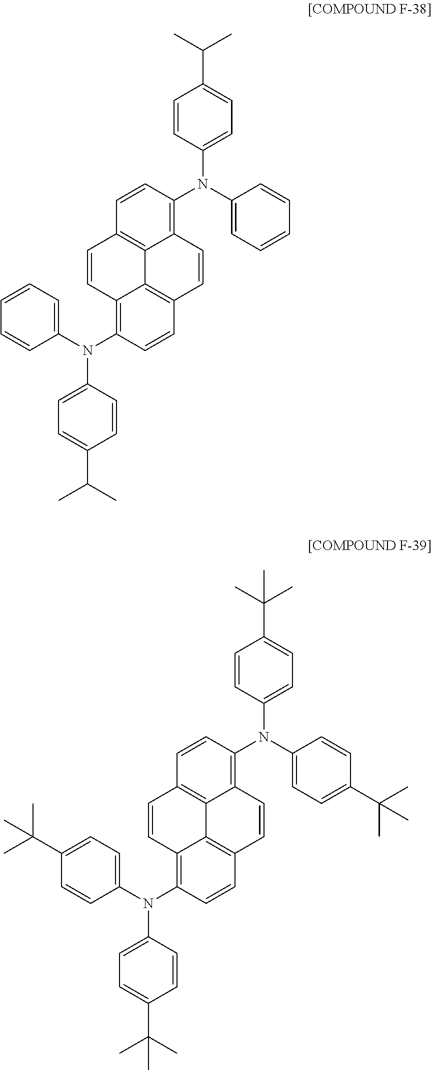 [SMILES: CC(C)c1ccc(N(c2ccccc2)c2ccc3ccc4c(N(c5ccccc5)c5ccc(C(C)C)cc5)ccc5ccc2c3c54)cc1 ; CC(C)(C)c1ccc(N(c2ccc(C(C)(C)C)cc2)c2ccc3ccc4c(N(c5ccc(C(C)(C)C)cc5)c5ccc(C(C)(C)C)cc5)ccc5ccc2c3c54)cc1]

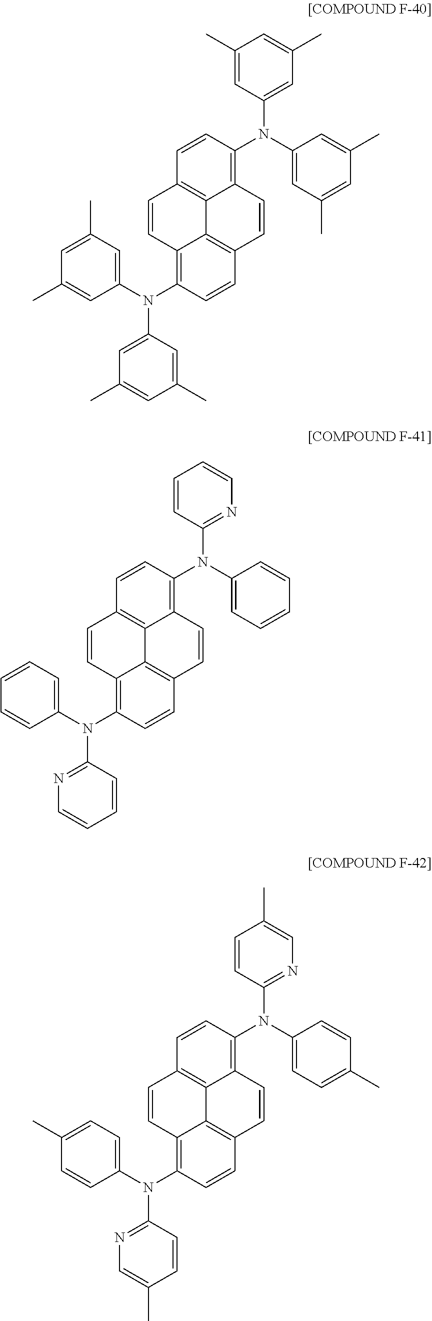

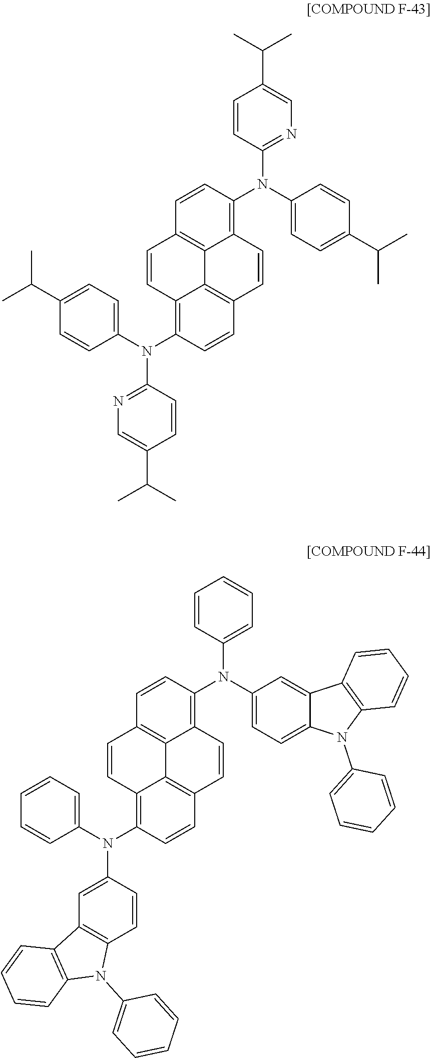 [SMILES: CC(C)c1ccc(N(c2ccc(C(C)C)cn2)c2ccc3ccc4c(N(c5ccc(C(C)C)cc5)c5ccc(C(C)C)cn5)ccc5ccc2c3c54)cc1 ; c1ccc(N(c2ccc3c(c2)c2ccccc2n3-c2ccccc2)c2ccc3ccc4c(N(c5ccccc5)c5ccc6c(c5)c5ccccc5n6-c5ccccc5)ccc5ccc2c3c54)cc1]

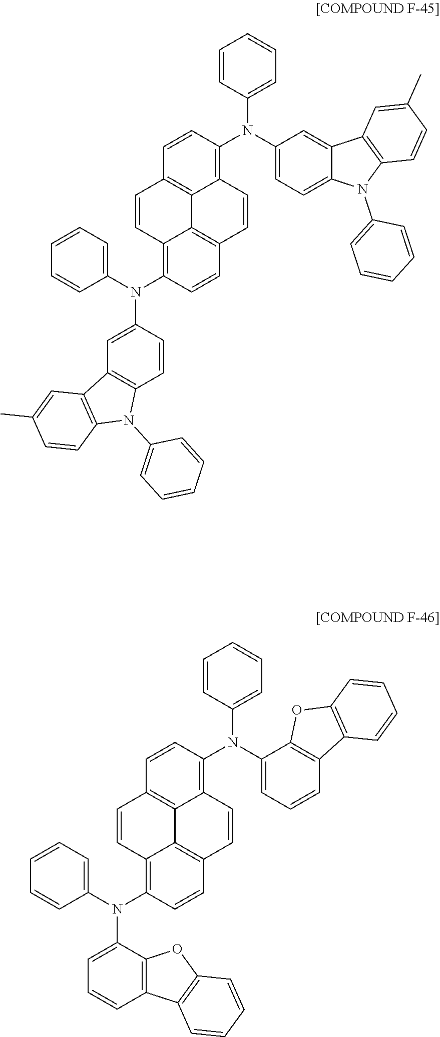 [SMILES: Cc1ccc2c(c1)c1cc(N(c3ccccc3)c3ccc4ccc5c(N(c6ccccc6)c6ccc7c(c6)c6cc(C)ccc6n7-c6ccccc6)ccc6ccc3c4c65)ccc1n2-c1ccccc1 ; c1ccc(N(c2ccc3ccc4c(N(c5ccccc5)c5cccc6c5oc5ccccc56)ccc5ccc2c3c54)c2cccc3c2oc2ccccc23)cc1]

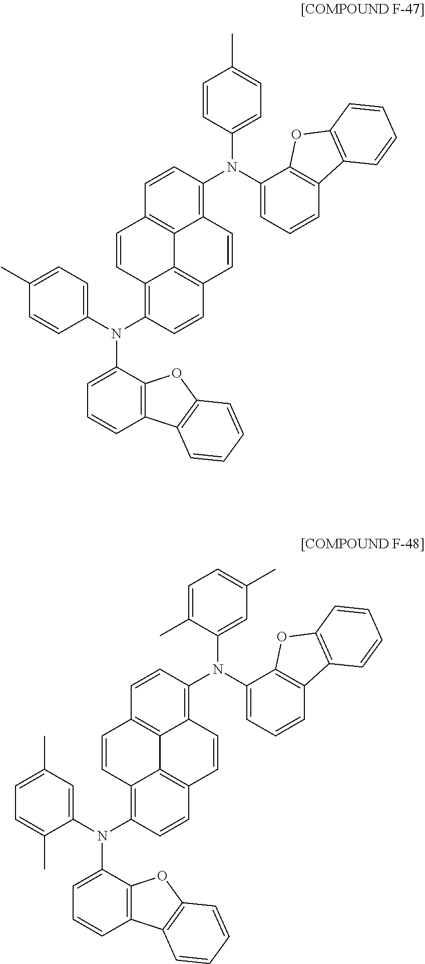 [SMILES: Cc1ccc(N(c2ccc3ccc4c(N(c5ccc(C)cc5)c5cccc6c5oc5ccccc56)ccc5ccc2c3c54)c2cccc3c2oc2ccccc23)cc1 ; Cc1ccc(C)c(N(c2ccc3ccc4c(N(c5cc(C)ccc5C)c5cccc6c5oc5ccccc56)ccc5ccc2c3c54)c2cccc3c2oc2ccccc23)c1]

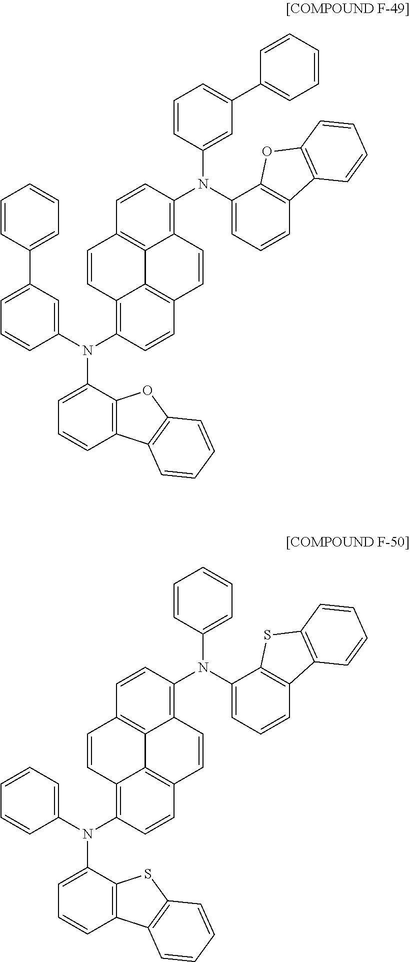 [SMILES: c1ccc(-c2cccc(N(c3ccc4ccc5c(N(c6cccc(-c7ccccc7)c6)c6cccc7c6oc6ccccc67)ccc6ccc3c4c65)c3cccc4c3oc3ccccc34)c2)cc1 ; c1ccc(N(c2ccc3ccc4c(N(c5ccccc5)c5cccc6c5sc5ccccc56)ccc5ccc2c3c54)c2cccc3c2sc2ccccc23)cc1]

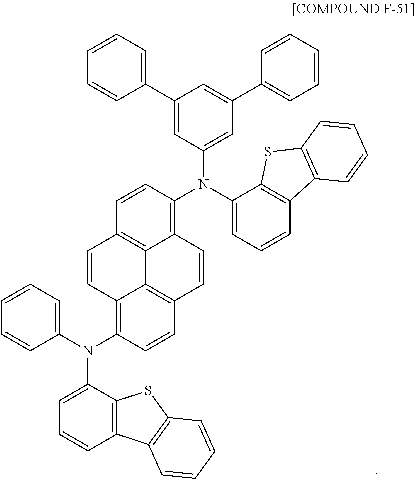 [SMILES: c1ccc(-c2cc(-c3ccccc3)cc(N(c3ccc4ccc5c(N(c6ccccc6)c6cccc7c6sc6ccccc67)ccc6ccc3c4c65)c3cccc4c3sc3ccccc34)c2)cc1]

8. The organic light-emitting device according to claim 1, comprising:
a first electrode and a second electrode facing each other; and
a layered structure located between the first electrode and the second electrode,
wherein the light-emitting layer is included in the layered structure.

9. The organic light-emitting device according to claim 8, wherein the layered structure includes at least one of a hole injection layer, a hole transport layer, an exciton blocking layer, an electron transport layer and an electron injection layer.

10. The organic light-emitting device according to claim 8, wherein the organic light-emitting device has an LT90 lifetime of 10 hours or more at 1,000 nits.

11. The organic light-emitting device according to claim 2, comprising:
a first electrode and a second electrode facing each other; and
a layered structure located between the first electrode and the second electrode,
wherein the light-emitting layer is included in the layered structure.

12. The organic light-emitting device according to claim 3, comprising:
a first electrode and a second electrode facing each other; and
a layered structure located between the first electrode and the second electrode,
wherein the light-emitting layer is included in the layered structure.

13. The organic light-emitting device according to claim 4, comprising:
a first electrode and a second electrode facing each other; and
a layered structure located between the first electrode and the second electrode,
wherein the light-emitting layer is included in the layered structure.

14. The organic light-emitting device according to claim 5, comprising:
a first electrode and a second electrode facing each other; and
a layered structure located between the first electrode and the second electrode,
wherein the light-emitting layer is included in the layered structure.

15. The organic light-emitting device according to claim 6, comprising:
a first electrode and a second electrode facing each other; and
a layered structure located between the first electrode and the second electrode,
wherein the light-emitting layer is included in the layered structure.

16. The organic light-emitting device according to claim 7, comprising:
a first electrode and a second electrode facing each other; and
a layered structure located between the first electrode and the second electrode,
wherein the light-emitting layer is included in the layered structure.
